(19) United States
(12) Patent Application Publication
(10) Pub. No.: US 2002/0011612 A1
(43) Pub. Date: Jan. 31, 2002

(54) Semiconductor device and method for manufacturing the same

(75) Inventor: Katsuhiko Hieda, Yokohama-shi (JP)

Correspondence Address: Finnegan, Henderson, Farabow, Garrett & Dunner, L.L.P., 1300 I Street, N.W., Washington, DC, 20005-3315, US

(73) Assignee: KABUSHIKI KAISHA TOSHIBA

(21) Appl. No.: 09/916,509

(22) Filed: Jul. 30, 2001

(30) Foreign Application Priority Data
Jul. 31, 2000 (JP) 2000-232165

(51) Int. Cl. H01L 29/80; H01L 31/112

(52) U.S. Cl. 257/262

(57) ABSTRACT

A semiconductor device comprises a convex semiconductor layer provided on a semiconductor substrate, a source region and a drain region provided in the convex semiconductor layer, and a gate electrode. The gate electrode has a side-wall gate portion provided over a side surface of the convex semiconductor layer in an insulated state with respect to the convex semiconductor layer.

### CROSS-REFERENCE TO RELATED APPLICATIONS

This application is based upon and claims the benefit of priority from the prior Japanese Patent Application No. 2000-232165, filed Jul. 31, 2000, the entire contents of which are incorporated herein by reference.

### BACKGROUND OF THE INVENTION

1. Field of the Invention

The present invention relates to a MOS transistor structure, and particularly to a MOS transistor structure having a gate electrode formed via a gate insulating film on a side surface on both sides on a semiconductor layer having a convex configuration approximately perpendicular to the substrate, and having a channel width determined with the dept of the source/drain region.

2. Description of the Related Art

In the semiconductor device having a MOS structure, a higher performance of the MOSFET is an important object. A higher performance in the MOSFET refers to

(1) an increase in the drive current

(2) a decrease in the dispersion in the threshold value

(3) a decrease in the parasitic resistance/parasitic capacity

(4) an improvement in the cut-off characteristics

An increase in the drive current is attained by shortening a gate size (also referred to as a channel size and a gate length). However, there is a problem that a short channel effect is increased when the channel is shortened.

In order to suppress the short channel effect, an effort has been made to decrease the thickness of a gate oxide film as much as possible and increase the concentration in a channel portion to about 10⁸ cm⁻³ to prevent a punch-through between the source and the drain. However, due to the limitation of the maximum allowed electric field (Emax), which can guarantee the reliability, the thickness of the gate oxide film cannot be reduced to a degree exceeding the maximum allowed electric field.

Furthermore, there has been conspicuous a problem such that an excessive increase in the impurity concentration of the channel brings about a saturation of a drain current by the high concentration impurity scattering of the channel such that the drain current does not increase even when the short channel is conducted.

Furthermore, along with the miniaturization, an increase in the resistance of the gate electrode and an increase in the parasitic resistance of the source/drain have become a problem. Still furthermore, a punch-through is likely to be generated between the source and the drain so that a leak current increases in the sub-threshold region and a cut-off characteristic has been deteriorated.

In order to settle such a problem, there is proposed a structure in which a convex type rectangular parallelepiped is formed approximately in a perpendicular to a Si substrate, and both side surfaces thereof are used as a channel region.

For example, as disclosed in IEDM Technical Digest pp.736-739 (1987) (K. Hieda et al), there is available a structure in which the side surface which is subjected to STI (Shallow Trench Isolation) is exposed a little, and the side surface is used as a channel region (FIG. 79).

This document describes characteristic such that when the channel width becomes smaller (<0.3 μm), a depletion layer of the channel region on both sides comes into contact with each other under the influence of the gate electrode on the side surface so that the influence of the side surface portion including a corner becomes larger than a planar portion and the cut-off characteristic is improved. However, there is no explanation on the suppression of the short channel effect.

Furthermore, for example, as disclosed in IEDM Technical Digest pp. 833-836 (1989) (D. Hisamoto et al), there is proposed a structure in which the Si substrate is subjected to RIE, a thin fence is formed and a lower portion thereof is subjected to oxidation to form a SOI structure thereby forming a gate electrode on both side surfaces (FIG. 80).

In this case as well, when the channel width becomes smaller (<0.2 μm), the depletion layer of the channel region on both sides comes into contact with each other under the influence of the gate electrode on the side surface and a completely depleted state is provided in the channel region. That is, the same state as the completely depleted state in the thin film SOI structure can be realized with the Si substrate. However, this structure becomes an SOI structure and a substrate bias cannot be applied thereto. There is no description on the position relationship between the source/drain and the gate electrode.

Furthermore, for example, as disclosed in IEDM Technical Digest pp. 1032-1034 (1998) (D. Hisamoto et al), there is proposed a fin-type structure in which the SOI substrate is used (FIG. 81).

In this document, it is shown that the short channel effect can be suppressed to a channel length on the order of 30 nm by the formation of the Si fin (Fin) on the order of 20 nm. However, because of the SOI structure, the structure is such that the substrate bias cannot be applied in the same manner as FIG. 80. Furthermore, the structure is such that dispersion in the thickness of the SOI layer directly affects dispersion in the MOSFET structure.

In the device disclosed in the document, the improvement in the cut-off characteristic and the suppression of the short channel effect can be realized. However, since the substrate bias cannot be applied, the deterioration of the source/drain pressure endurance under the influence of the accumulated hole (in the case of the N channel) becomes a problem in the same manner as the case of the thin film SOI transistor having completely depleted channel.

### BRIEF SUMMARY OF THE INVENTION

A semiconductor device according to a first aspect of the present invention comprises a convex semiconductor layer provided on a semiconductor substrate, a source region and a drain region provided in the convex semiconductor layer, a gate electrode has a side-wall gate portion provided over a side surface of the convex semiconductor layer, in an insulated state with respect to the convex semiconductor layer. The gate electrode applies an electric field effect to a channel region between the source and drain regions, via at least the side surface of the convex semiconductor layer. A distance between the source region and the drain region changes on the side surface of the convex semiconductor layer.

A semiconductor device according to a second aspect of the present invention comprises a convex semiconductor layer provided on a substrate, a source region and a drain region provided in the convex semiconductor layer, a gate electrode has a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer, and a side-wall insulating film provided on a side surface of the gate electrode and the side surface of the convex semiconductor layer.

A semiconductor device according to a third aspect of the present invention comprises a convex semiconductor layer provided on a substrate, a isolation film provided on a periphery of a lower portion region of the convex semiconductor layer, the position of the upper surface of the isolation film being lower than an upper surface of the convex semiconductor layer, a source region and a drain region provided in the convex semiconductor layer, the position of the deepest portion of the source region and the position of the deepest portion of the drain region is equal to or lower than the position of the upper surface of the isolation film, a gate electrode having a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer.

A semiconductor device according to a fourth aspect of the present invention comprises a first convex semiconductor layer provided on a substrate, the first convex semiconductor layer electrically connected to the substrate, a second convex semiconductor layer provided on the substrate, the second convex semiconductor layer electrically connected to the substrate, the second convex semiconductor layer having the same width as the first semiconductor layer, a first source region and a first drain region provided in the first convex semiconductor layer, a second source region and a second drain region provided in the second convex semiconductor layer, a gate electrode having a side-wall gate portion provided over a side surface of the first convex semiconductor layer and a side surface of the second convex semiconductor layer, in an insulated state with respect to the first and second convex semiconductor layers respectively, the gate electrode applies an electric field effect to a first channel region between the first source and drain regions and a second channel region between the second source and drain regions, via at least the side surfaces of the first and second convex semiconductor layer.

A semiconductor device according to a fifth aspect of the present invention comprises a first convex semiconductor layer provided on a substrate, the first convex semiconductor layer electrically connected to the substrate, a second convex semiconductor layer provided on the substrate, the second convex semiconductor layer electrically connected to the substrate, a first source region and a first drain region provided in the first convex semiconductor layer, a second source region and a second drain region provided in the second convex semiconductor layer, a first gate electrode having a first side-wall gate portion provided over a side surface of the first convex semiconductor layer, in an insulated state with respect to the first convex semiconductor layer, the first gate electrode applies an electric field effect to a first channel region between the first source and drain regions, via at least the side surface of the first convex semiconductor layer, a second gate electrode having a second side-wall gate portion provided over a side surface of the second convex semiconductor layer, in an insulated state with respect to the second convex semiconductor layer, the second gate electrode applies an electric field effect to a second channel region between the second source and drain regions, via at least the side surface of the second convex semiconductor layer, a first wiring electrically connected to the first source region and the second source region, a second wiring electrically connected to the first drain region and the second drain region and a third wiring electrically connected to the first gate electrode and the second gate electrode.

A semiconductor device according to a sixth aspect of the present invention comprises a first convex semiconductor layer provided on a substrate, a second convex semiconductor layer provided on the substrate;

a source region and a drain region provided in the first convex semiconductor layer, and a gate electrode having a side-wall gate portion provided over a side surface of the first convex semiconductor layer, in an insulated state with respect to the first convex semiconductor layer, and a gate contact portion provided over an upper surface of the second convex semiconductor layer, in an insulated state with respect to the second convex semiconductor layer, the gate electrode applies an electric field effect to a channel region between the source and drain regions, via at least the side surface of the first convex semiconductor layer.

A semiconductor device according to a seventh aspect of the present invention comprises a convex semiconductor layer provided on a substrate, a source region and a drain region provided in the convex semiconductor layer, and a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applies an electric field effect to a channel region between the source and drain regions, via at least the side surface of the convex semiconductor layer. A conductive material of the side-wall gate portion is different from a conductive material of the upper gate portion.

A semiconductor device according to an eighth aspect of the present invention comprises a convex semiconductor layer provided on a substrate, a source region and a drain region provided in the convex semiconductor layer, a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applies an electric field effect to a channel region between the source and drain regions, via at least the side surface of the convex semiconductor layer, and a wiring being electrically connected to the upper gate portion above the upper surface of the convex semiconductor layer.

A semiconductor device according to a ninth aspect of the present invention comprises a first convex semiconductor layer provided on a substrate, a second convex semiconductor layer provided on the substrate, a first source region and a first drain region provided in the first convex semiconductor layer, a second source region and a second drain region provided in the second convex semiconductor layer, a gate electrode having a side-wall gate portion provided over a side surface of the first convex semiconductor layer and a side surface of the second convex semiconductor layer, in an insulated state with respect to the first and second convex semiconductor layers respectively, the gate electrode applies an electric field effect to a first channel region between the first source and drain regions and a second channel region between the second source and drain regions, via at least the side surfaces of the first and second convex semiconductor layer, and at least one third convex semiconductor layer electrically connected to at least either the first and the second source regions, or the first and the second drain regions.

A semiconductor device according to a tenth aspect of the present invention comprises a first convex semiconductor layer provided on a substrate, a second semiconductor layer provided on the substrate, a first source region and a first drain region of a first conductive type provided in the first semiconductor layer, a second source region and a second drain region of a second conductive type provided in the second convex semiconductor layer, a depth of the second source region and a second drain region being deeper than the depth of the first source region and the second drain region, a first gate electrode having a first side-wall gate portion provided over a side surface of the first convex semiconductor layer, in an insulated state with respect to the first convex semiconductor layer, the first gate electrode applies an electric field effect to a first channel region between the first source and drain regions, via at least the side surface of the first convex semiconductor layer, a second gate electrode having a second side-wall gate portion provided over a side surface of the second convex semiconductor layer, in an insulated state with respect to the second convex semiconductor layer, the second gate electrode applies an electric field effect to a second channel region between the second source and drain regions, via at least the side surface of the second convex semiconductor layer.

A semiconductor device according to an eleventh aspect of the present invention comprises a first convex semiconductor layer provided on a substrate, a second convex semiconductor layer provided on the substrate, a first source region and a first drain region provided in the first convex semiconductor layer, a second source region and a second drain region having the same conductive type as the first source region and the first drain region provided in the second convex semiconductor layer, a depth of the first source region and a depth of the second drain region being deeper than the first source region and the second drain region, a first gate electrode having a first side-wall gate portion provided over a side surface of the first convex semiconductor layer, in an insulated state with respect to the first convex semiconductor layer, the first gate electrode applies an electric field effect to a first channel region between the first source and drain regions, via at least the side surface of the first convex semiconductor layer, and a second gate electrode having a second side-wall gate portion provided over a side surface of the second convex semiconductor layer, in an insulated state with respect to the second convex semiconductor layer, the second gate electrode applies an electric field effect to a second channel region between the second source and drain regions, via at least the side surface of the second convex semiconductor layer.

A semiconductor device according to a twelfth aspect of the present invention comprises a convex semiconductor layer provided on a substrate, a source region and a drain region provided in the convex semiconductor layer, and a gate electrode having a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer, the gate electrode including at least a first layer and a second layer. The gate electrode uses a word line of a semiconductor memory device.

A semiconductor device according to a thirteenth aspect of the present invention comprises a convex semiconductor layer provided on a substrate, a source region and a drain region provided in the convex semiconductor layer, and a gate electrode having a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer, the gate electrode including at least a first layer and a second layer. An upper surface of the first layer is planar and the second layer is provided on the upper surface of the first layer.

A semiconductor device according to a fourteenth aspect of the present invention comprises a convex semiconductor layer provided on a substrate, a source region and a drain region provided in the convex semiconductor layer, and a gate electrode having a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer, the gate electrode including at least a first layer and a second layer. An upper surface of the first layer has a step, the second layer is provided on the upper surface of the first layer, and an upper surface of the second layer is planar.

A semiconductor device according to a fifteenth aspect of the present invention comprises a convex semiconductor layer provided on a substrate, the convex semiconductor having a first side surface, a second side surface opposite to the first side surface, a third side surface located between the first and second side surface, a forth side surface opposite to the third surface, and a upper surface, a source region and a drain region provided in the convex semiconductor layer, the source region and the drain region including an electric contact portion respectively, the electric contact portion extending over a part of the first side surface, a part of the upper surface, a part of the second side surface and either of parts of the third and fourth side surfaces, a gate electrode having a side-wall gate portion provided over a side surface of the convex semiconductor layer, in an insulated state with respect to the convex semiconductor layer, the gate electrode applies an electric field effect to a channel region between the source and drain regions, via at least the side surface of the convex semiconductor layer.

A semiconductor device according to a sixteenth aspect of the present invention comprises a convex semiconductor layer provided on a substrate, a source region and a drain region provided in the convex semiconductor layer, and a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applies an electric field effect to a channel region between the source and drain regions, via at least the side surface of the convex semiconductor layer. A gate length of the side-wall gate portion is shorter than the gate length of the upper gate portion.

A method of manufacturing a semiconductor device according to a first aspect of the present invention comprising: etching a semiconductor substrate to form a convex semiconductor layer on the semiconductor substrate; forming a gate insulating film at least on a side surface of the convex semiconductor layer; forming a gate electrode on the gate insulating film; forming a side-wall insulating film on a side surface of the gate electrode and on the side surface of the convex semiconductor layer; and introducing impurity into the convex semiconductor layer by using at least the gate electrode and the side-wall insulating film as a mask to form a source region and a drain region in the convex semiconductor layer.

A method of manufacturing a semiconductor device according to a second aspect of the present invention comprising: forming an insulating film having an open hole on a semiconductor substrate; forming a convex semiconductor layer on a semiconductor substrate exposed from the open hole; forming a gate insulating film on at least a side surface of the convex semiconductor layer; forming a gate electrode on the gate insulating film; and introducing impurity into the convex semiconductor layer by using at least the gate electrode as a mask to form a source region and a drain region in the convex semiconductor layer.

A method of manufacturing a semiconductor device according to a third aspect of the present invention comprising: forming a convex semiconductor layer on a substrate; forming an insulator at a periphery of the convex semiconductor layer; forming a trench to form a side-wall gate portion in the insulator; forming a gate insulating film on a side surface of the convex semiconductor layer exposed at least from the trench; forming a gate electrode having a side-wall gate portion formed in the trench; and introducing impurity into the convex semiconductor layer by using at least the gate electrode as a mask to form a source region and a drain region in the convex semiconductor layer.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a perspective view showing a MOSFET according to a first embodiment of the present invention.

FIG. 2A is a plan view showing a MOSFET according to the first embodiment of the present invention;

FIG. 2B is a sectional view taken along the line 2B-2B of FIG. 2A;

FIG. 2C is a sectional view taken along the line 2C-2C of FIG. 2A; and

FIG. 2D is a sectional view taken along the line 2D-2D of FIG. 2A.

FIGS. 3A and 3B are sectional views showing a main manufacturing step of the MOSFET according to the first embodiment of the present invention, respectively.

FIGS. 4A and 4B are sectional views showing a main manufacturing step of the MOSFET according to the first embodiment of the present invention, respectively.

FIGS. 5A and 5B are sectional views showing a main manufacturing step of the MOSFET according to the first embodiment of the present invention, respectively.

FIGS. 6A and 6B are sectional views showing a main manufacturing step of the MOSFET according to the first embodiment of the present invention, respectively.

FIGS. 7A and 7B are sectional views showing a main manufacturing step of the MOSFET according to the first embodiment of the present invention, respectively.

FIGS. 8A and 8B are sectional views showing a main manufacturing step of the MOSFET according to the first embodiment of the present invention, respectively.

FIGS. 9A and 9B are sectional views showing a main manufacturing step of the MOSFET according to the first embodiment of the present invention, respectively.

FIGS. 10A and 10B are sectional views showing a main manufacturing step of the MOSFET according to the first embodiment of the present invention, respectively.

FIGS. 11A and 11B are sectional views showing a main manufacturing step of the MOSFET according to the first embodiment of the present invention, respectively.

FIG. 12 is a perspective view showing a MOSFET according to a second embodiment of the present invention.

FIGS. 13A and 13B are sectional views showing the MOSFET according to the second embodiment of the present invention, respectively.

FIGS. 14A and 14B are sectional views showing a MOSFET according to a third embodiment of the present invention, respectively.

FIGS. 15A and 15B are sectional views showing a MOSFET according to a fourth embodiment of the present invention, respectively.

FIG. 16A is a plan view showing a MOSFET according to a fifth embodiment of the present invention;

FIG. 16B is a sectional view taken along the line 16B-16B of FIG. 16A; and

FIG. 16C is a sectional view taken along the line 16C-16C of FIG. 16A.

FIG. 17A is a plan view showing a MOSFET according to a sixth embodiment of the present invention;

FIG. 17B is a sectional view taken along the line 17B-17B of FIG. 16A; and

FIG. 17C is a sectional view taken along the line 17C-17C of FIG. 17A.

FIGS. 18A and 18B are sectional views showing a MOSFET according to the sixth embodiment of the present invention, respectively.

FIGS. 19A and 19B are sectional views showing a MOSFET according to a seventh embodiment of the present invention, respectively.

FIG. 20 is a perspective view showing a MOSFET according to an eighth embodiment of the present invention.

FIG. 21A is a plan view showing a MOSFET according to the eighth embodiment of the present invention;

FIG. 21B is a sectional view taken along the line 21B-21B of FIG. 21A; and

FIG. 21C is a sectional view taken along the line 21C-21C of FIG. 21A.

FIG. 22 is a perspective view showing a MOSFET according to a ninth embodiment of the present invention.

FIG. 23A is a plan view showing the MOSFET according to a ninth embodiment of the present invention;

FIG. 23B is a sectional view taken along the line 23B-23B of FIG. 23A; and

FIG. 23C is a sectional view taken along the line 23C-23C of FIG. 23A.

FIG. 24 is a sectional view showing a variation of a gate insulating film of the MOSFET according to the present invention.

FIG. 25 is a sectional view showing a variation of a gate insulating film of the MOSFET according to the present invention.

FIG. 26 is a sectional view showing a MOSFET according to a tenth embodiment of the present invention.

FIG. 27 is a sectional view showing a MOSFET according to an eleventh embodiment of the present invention.

FIG. 28 is a sectional view showing a MOSFET according to a twelfth embodiment of the present invention.

FIG. 29 is a sectional view showing a variation of a source/drain region of the MOSFET according to the present invention.

FIG. 30 is a plan view showing a MOSFET according to a first example of a thirteenth embodiment of the present invention.

FIG. 31 is a plan view showing a MOSFET according to a second example of the thirteenth embodiment of the present invention.

FIG. 32 is a plan view showing a MOSFET according to a third example of the thirteenth embodiment of the present invention.

FIG. 33 is a perspective view showing a MOSFET according to a fourteenth embodiment of the present invention.

FIG. 34A is a plan view showing the MOSFET according to the fourteenth embodiment of the present invention;

FIG. 34B is a sectional view taken along the line 34B-34B of FIG. 34A; and

FIG. 34C is a sectional view taken along the line 34C-34C of FIG. 34A.

FIG. 35 is a perspective view showing a MOSFET according to a fifteenth embodiment of the present invention.

FIG. 36A is a plan view showing a MOSFET according to the fifteenth embodiment of the present invention;

FIG. 36B is a sectional view taken along the line 36B-36B of FIG. 36A; and

FIG. 36C is a sectional view taken along the line 36C-36C of FIG. 36A.

FIGS. 37A and 37B are sectional views showing a manufacturing step of the MOSFET according to a sixteenth embodiment of the present invention, respectively.

FIGS. 38A and 38B are sectional views showing a method for manufacturing the MOSFET according to the sixteenth embodiment of the present invention, respectively.

FIGS. 39A and 39B are sectional views showing a method for manufacturing the MOSFET according to the sixteenth embodiment of the present invention, respectively.

FIGS. 40A and 40B are sectional views showing a method for manufacturing the MOSFET according to the sixteenth embodiment of the present invention, respectively.

FIGS. 41A and 41B are sectional views showing a method for manufacturing the MOSFET according to the sixteenth embodiment of the present invention, respectively.

FIGS. 42A and 42B are sectional views showing a method for manufacturing the MOSFET according to the sixteenth embodiment of the present invention, respectively.

FIGS. 43A and 43B are sectional views showing a method for manufacturing the MOSFET according to a seventeenth embodiment of the present invention, respectively.

FIGS. 44A and 44B are sectional views showing a method for manufacturing the MOSFET according to the seventeenth embodiment of the present invention, respectively.

FIGS. 45A and 45B are sectional views showing a method for manufacturing the MOSFET according to the seventeenth embodiment of the present invention, respectively.

FIGS. 46A and 46B are sectional views showing a method for manufacturing the MOSFET according to the seventeenth embodiment of the present invention, respectively.

FIGS. 47A and 47B are sectional views showing a method for manufacturing the MOSFET according to the seventeenth embodiment of the present invention respectively.

FIG. 48A is a plan view showing a complementary MOSFET according to an eighteenth embodiment of the present invention;

FIG. 48B is a sectional view taken along the line 48B-48B of FIG. 48A;

FIG. 48C is a sectional view taken along the line 48C-48C of FIG. 48A; and

FIG. 48D is a sectional view taken along the line 48D-48D of FIG. 48A.

FIG. 49 is a sectional view showing a main manufacturing step of the MOSFET according to the eighteenth embodiment of the present invention.

FIG. 50 is a sectional view showing a main manufacturing step of the MOSFET according to the eighteenth embodiment of the present invention.

FIG. 51 is a sectional view showing a main manufacturing step of the MOSFET according to the eighteenth embodiment of the present invention.

FIG. 52 is a sectional view showing a main manufacturing step of the MOSFET according to the eighteenth embodiment of the present invention.

FIG. 53 is a sectional view showing a main manufacturing step of the MOSFET according to the eighteenth embodiment of the present invention.

FIG. 54 is a sectional view showing a main manufacturing step of the MOSFET according to the eighteenth embodiment of the present invention.

FIG. 55A is a plan view showing a complementary MOSFET according to a nineteenth embodiment of the present invention;

FIG. 55B is a sectional view taken along the line 55B-55B in FIG. 55A; and

FIG. 55C is a sectional view taken along the line 55C-55C in FIG. 55A.

FIG. 56 is a sectional view showing a DRAM memory cell having a trench capacitor structure according to a twentieth embodiment of the present invention.

FIG. 57 is a sectional view showing a DRAM memory cell having a stacked-type capacitor structure according to a twenty-first embodiment of the present invention.

FIG. 58 is a perspective view showing a MOSFET according to a twenty-second embodiment of the present invention.

FIG. 59A is a plan view showing the MOSFET according to the twenty-second embodiment of the present invention;

FIG. 59B is a sectional view taken along the line 59B-59B of FIG. 59A;

FIG. 59C is a sectional view taken along the line 59C-59C of FIG. 59A; and

FIG. 59D is a sectional view taken along the line 59D-59D of FIG. 59A.

FIG. 60 is a perspective view showing a MOSFET according to a twenty-third embodiment of the present invention.

FIG. 61 is a sectional view showing the MOSFET according to the twenty-third embodiment of the present invention.

FIG. 62 is a perspective view showing a contact portion of the MOSFET according to the present invention.

FIG. 63A is a plan view showing the contact portion of the MOSFET according to the present invention;

FIG. 63B is a side view as seen from a direction of an arrow B shown in FIG. 63A; and

FIG. 63C is a side view as seen from the direction of an arrow C shown in FIG. 63A.

FIG. 64 is a perspective view showing a MOSFET according to a twenty-fourth embodiment of the present invention.

FIG. 65A is a plan view showing the MOSFET according to the twenty-fourth embodiment of the present invention;

FIG. 65B is a side view as seen from a direction of an arrow B shown in FIG. 65A; and

FIG. 65C is a side view as seen from a direction of an arrow C shown in FIG. 65A.

FIG. 66 is a sectional view showing a MOSFET according to a twenty-fifth embodiment of the present invention.

FIG. 67 is a sectional view showing a MOSFET according to a twenty-sixth embodiment of the present invention.

FIG. 68A is a perspective view showing a MOSFET according to a twentieth-seventh embodiment of the present invention; and

FIG. 68B is a perspective view thereof.

FIG. 69A is a plan view showing a main manufacturing step of the MOSFET according to the twenty-seventh embodiment of the present invention;

FIG. 69B is a sectional view taken along the line B-B of FIG. 69A; and

FIG. 69C is a sectional view taken along the line C-C of FIG. 69A.

FIG. 70A is a plan view showing a main manufacturing step of the MOSFET according to the twenty-seventh embodiment of the present invention;

FIG. 70B is a sectional view taken along the line B-B of FIG. 70A; and

FIG. 70C is a sectional view taken along the line C-C in FIG. 70A.

FIG. 71A is a plan view showing a main manufacturing step of the MOSFET according to the twenty-seventh embodiment of the present invention;

FIG. 71B is a sectional view taken along the line B-B of FIG. 71A; and

FIG. 71C is a sectional view taken along the line C-C of FIG. 71A.

FIG. 72A is a plan view showing a main manufacturing step of the MOSFET according to the twenty-seventh embodiment of the present invention;

FIG. 72B is a sectional view taken along the line B-B of FIG. 72A; and

FIG. 72C is a sectional view taken along the line C-C of FIG. 72A.

FIG. 73A is a plan view showing a main manufacturing step of the MOSFET according to the twenty-seventh embodiment of the present invention;

FIG. 73B is a sectional view taken along the line B-B of FIG. 73A; and

FIG. 73C is a sectional view taken along the line C-C of FIG. 73A.

FIG. 74A is a plan view showing a main manufacturing step of the MOSFET according to the twenty-seventh embodiment of the present invention;

FIG. 74B is a sectional view taken along the line B-B of FIG. 74A; and

FIG. 74C is a sectional view taken along the line C-C of FIG. 74A.

FIG. 75A is a plan view showing a main manufacturing step of the MOSFET according to the twenty-seventh embodiment of the present invention;

FIG. 75B is a sectional view taken along the line B-B of FIG. 75A; and

FIG. 75C is a sectional view taken along the line C-C of FIG. 75A.

FIG. 76A is a plan view showing a main manufacturing step of the MOSFET according to the twenty-seventh embodiment of the present invention;

FIG. 76B is a sectional view taken along the line B-B of FIG. 76A; and

FIG. 76C is a sectional view taken along the line C-C of FIG. 76A.

FIG. 77A is a plan view showing a main manufacturing step of the MOSFET according to the twenty-seventh embodiment of the present invention;

FIG. 77B is a sectional view taken along the line B-B of FIG. 77A; and

FIG. 77C is a sectional view taken along the line C-C of FIG. 77A.

FIG. 78A is a plan view showing a main manufacturing step of the MOSFET according to the twenty-seventh embodiment of the present invention;

FIG. 78B is a sectional view taken along the line B-B of FIG. 78A; and

FIG. 78C is a sectional view taken along the line C-C of FIG. 78A.

FIG. 79 is a perspective view showing a conventional MOSFET.

FIG. 80 is a perspective view showing the conventional MOSFET.

FIG. 81 is a detail view showing the conventional MOSFET.

### DETAILED DESCRIPTION OF THE INVENTION

Hereinafter, embodiments of the present invention will be explained by referring to the drawings. In this explanation, common portions are denoted by common reference numerals over the whole drawings.

(First Embodiment)

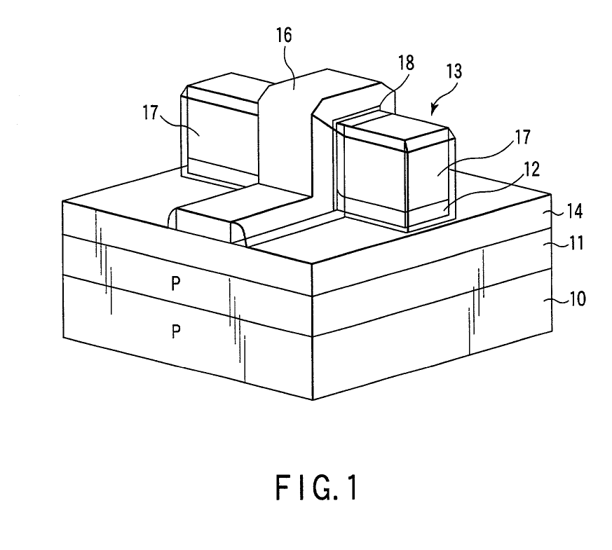

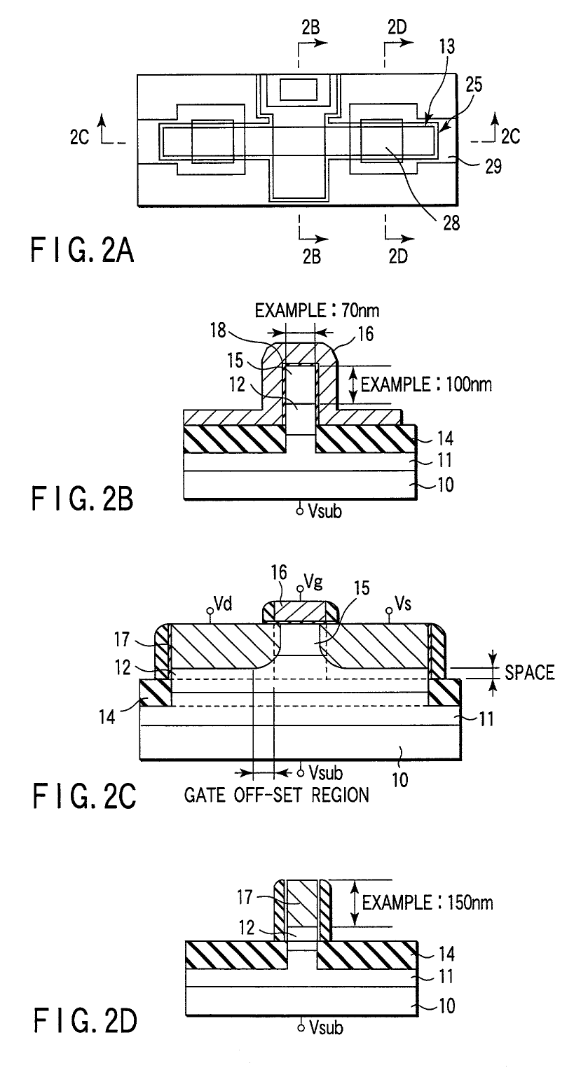

FIG. 1 is a perspective view showing a MOSFET according to a first embodiment of the present invention. FIG. 2A is a plan view thereof. FIG. 2B is a sectional view taken along the line 2B-2B in FIG. 2A. FIG. 2C is a sectional view taken along the line 2C-2C in FIG. 2A. FIG. 2D is a sectional view taken along the line 2D-2D in FIG. 2A. Incidentally, in FIG. 1, FIGS. 2B to 2D, an interlayer insulating film, a contact, and a wiring shown in FIG. 2A are omitted, respectively.

As shown in FIG. 1 and FIGS. 2A to 2D, a P-type well 11 is formed on a transistor formation region of a P-type Si (silicon) substrate 10. The P-type Si substrate 10 has, for example, an impurity concentration of 5×10¹⁵ cm⁻³ and a plane direction of a main surface is (100). On the transistor channel formation region in the P-type well 11, for example, a P-type high concentration impurity layer (hereinafter referred to as a punch-through stopper layer) 12 having an impurity concentration on the order of 5×10¹⁷ cm⁻³ is formed. This punch-through stopper layer 12 is formed when needed, and can be omitted.

On the Si substrate 10, a convex thin film Si (silicon) layer 13 is formed (hereinafter referred to as a fence 13). In one design example of the fence 13, a height is set to about 250 nm, a width is set to about 70 nm, and a length is set to about 440 nm. A lower portion region of the fence 13 according to the embodiment includes, for example, an upper portion of the P-type well 11, and a punch-through stopper layer 12. Then, on a periphery of this lower portion region, an isolation insulating film (silicon oxide film) 14 for isolation is formed.

On the punch-through stopper layer 12 in the fence 13, a channel impurity layer (channel region) 15 is formed. An impurity is doped into the channel impurity layer 15 so that the threshold voltage of the MOSFET is set to a desired value.

In the direction of a long side (length direction) of the fence 13, a source/drain region 17 is formed sandwiching the gate electrode 16. The gate electrode 16 is formed on both side surfaces of the fence 13 so as to ride over a step of the fence 13 via the gate insulating film 18. The channel width (Wg) is determined with the width in the direction of a short side of the fence 13. Furthermore, the gate length (Lg) is primarily determined with the length of the gate electrode 16. However, the effective channel length is determined with a distance of the source/drain region 17 on the side surface of the fence 13 of the gate electrode 16.

Furthermore, the gate electrode 16 is formed on the isolation insolating film 14, both sides and an upper surface of the fence 13. On these sides and the upper surface thereof, the gate electrode 16 is formed so as to cover a part of the source/drain region 17, the channel region 15 and a part of the punch-through stopper layer 12.

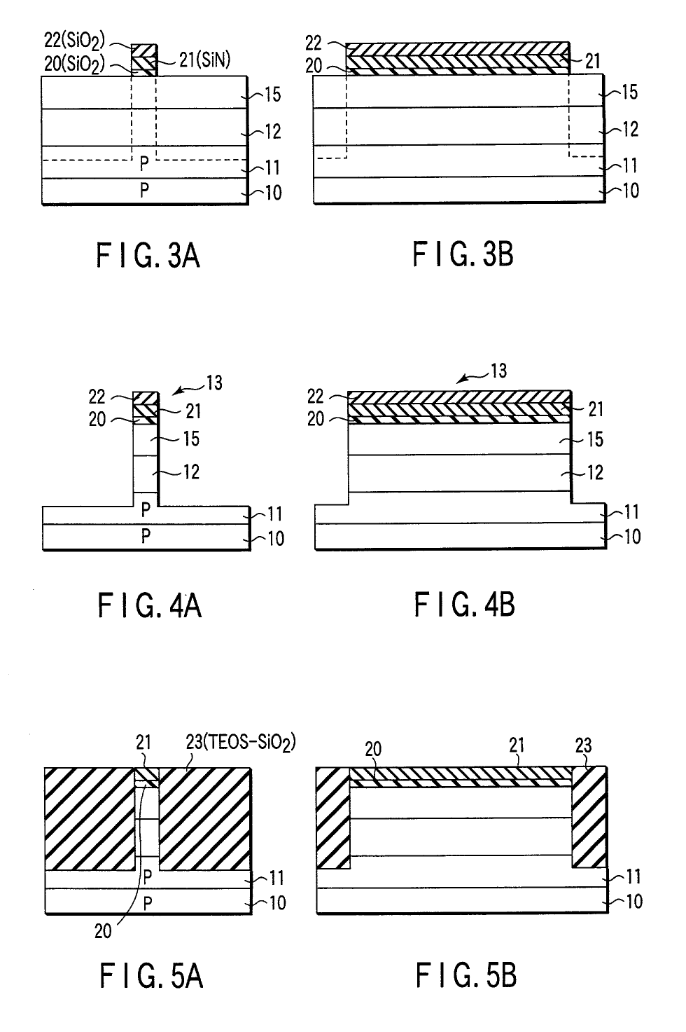

Next, one example of the method for manufacturing the MOSFET according to the first embodiment will be explained by using sectional views from FIGS. 3 to 11. Incidentally, the cross sections shown in FIGS. 3A to 11A correspond to a cross section shown in FIG. 2B. The cross sections shown in FIGS. 3B to 11B correspond to the cross section shown in FIG. 2C.

In the beginning, as shown in FIGS. 3A and 3B, the P-type Si substrate 10 is prepared. This P-type Si substrate 10 has, for example, an impurity concentration of about 5×10¹⁵ cm⁻³. The plane direction of the main surface thereof is, for example, (100).

In the case where the N-channel type MOSFET (hereinafter referred to as NMOS) is formed on the P-type Si substrate, for example, boron ions (B⁺) are implanted into the transistor channel formation region of the P-type Si substrate 10 under the condition of an acceleration voltage of 260 KeV and a dose amount of about 2×10¹³ cm⁻². As a consequence, the P-type well 11 having a peak concentration of about, for example, 4×10¹⁷ cm⁻³ is formed in the P-type Si substrate 10.

Besides, in the case where the P-channel type MOSFET (hereinafter PMOS) is formed on the P-type Si substrate 10, the N-type well (not shown) is formed on the transistor channel formation region of the P-type Si substrate 10.

Next, for example, boron ions (B⁺) are implanted into the P-type well 11 by using a resist film (not shown) as a mask. As a consequence, for example, a high concentration impurity layer 12 having, for example, a peak concentration of about 2×10¹⁸ cm⁻³ is formed in the P-type well 11. The high impurity concentration layer 12 serves as a punch-through stopper layer.

Incidentally, at the time of the step of ion implantation, preferably, an oxide film (not shown) having, for example, a thickness of about 8 nm is formed on the surface of the P-type Si substrate 10. The contamination of the P-type Si substrate from the resist film (not shown), for example, the metal contamination can be prevented by the formation of the oxide film.

Furthermore, for the activation of the implanted ions, RTA (Rapid Thermal Anneal) is used for about 5 minutes, for example at 900° C. and in the atmosphere of nitrogen (N₂). As a consequence, a P-type high concentration impurity layer 12 having a steep profile can be formed.

Next, another resist film (not shown) is used as a mask to implant impurity ions having a desired conductive type into a region including a transistor channel formation region of the P-type Si substrate. As a consequence, the channel impurity layer 15 is formed in the transistor channel formation region. At this time, the channel impurity layer 15 may be formed by selectively implanting ions into only the transistor channel formation region. When the MOSFET to be formed is NMOS and the threshold voltage (Vth) of this NMOS is desired to be set to, for example, about 0.7V, for example, boron ions (B⁺) on the order of 5×10¹² cm⁻² are implanted into the transistor channel formation region at an acceleration voltage of 20 KeV. These ions are implanted through the oxide film (not shown). As a consequence, the P-type channel impurity layer 15 is formed in the transistor channel formation region. Furthermore, the P-type channel impurity layer 15 is formed in such a manner that a selectively uniform profile is provided on the region, which forms a channel. For the activation of this P-type channel impurity layer 15, for example, RTA may be used. One example of the RTA condition may be about 10 seconds at a temperature of 750° C.

Next, after the oxide film (not shown) is removed, a SiO₂ layer 20 having a thickness of about 5 nm, a mask layer (SiN) 21 having a thickness of about 20 nm and a mask layer (SiO₂) 22 having a thickness of about 20 nm are subsequently formed again on the surface of the P-type Si substrate 10. Thereafter, the lithography and the RIE are used to process the SiO₂ layer 20, the mask layer 21, and the mask layer 22 into a desired configuration, for example, a configuration which constitutes an active area of the MOSFET.

Next, as shown in FIGS. 4A and 4B, in the structure shown in FIGS. 3A and 3B, the Si substrate 10 is etched by using, for example, RIE until the midst of the P-type well 11 is reached while using the mask layer 22 as a mask for etching. As a consequence, for example, a trench having a depth of about 250 nm and a fence 13 is formed in the Si substrate 10. The fence 13 is a region where the source, the drain and the channel of the MOSFET are formed respectively. One example of the height of the fence 13 is about 250 nm, which is the same, for example, as the depth of the trench.

Next, the side surface of the fence 13 and the bottom of the trench are cleaned by using ashing and wet processing or the like while the portion which is damaged with the RIE in the Si substrate 10 is removed. As a consequence, on the side surface of the fence 13 and on the bottom of the trench, the Si surface which is not damaged so much is exposed. Next, on the side surface of the fence 13 and on the bottom of the trench, an oxide film (not shown) having a thickness of about 7 nm is formed. One object of forming this oxide film is to make the interface characteristic favorable. Furthermore, it is desirable that this oxide film is formed with the radical oxidation method using oxygen radical. That is because, in the radical oxidation method, a good quality oxide film can be formed, for example, at about 700° C.

Next, as shown in FIGS. 5A and 5B, the trench having the oxide film (not shown) formed thereon is filled with the insulator 23. As a consequence, the trench is filled with the insulator 23 so that so-called Shallow Trench Isolation is formed in the Si substrate 10. One example of the insulator 23 is SiO₂. Furthermore, one preferable example of the SiO₂ is TEOS-SiO₂ which is formed by using TEOS as a reaction gas.

One example of a concrete method for manufacturing STI will be described hereinafter.

In the beginning, TEOS-SiO₂ is deposited to about 500 nm on the structure shown in FIGS. 4A and 4B by using the CVD method in which TEOS is used as reaction gas and film forming temperature is set to about 650° C. As a consequence, the TEOS-SiO₂ layer (insulator) 23 is formed. Next, the TEOS-SiO₂ layer 23 is densified in the atmosphere of radical oxidation at a temperature of about 700° C. Thereafter, the surface of the TEOS-SiO₂ layer 23 is planarized by using the CMP (Chemical Mechanical Polishing). At this time, the TEOS-SiO₂ layer 23 is embedded in a planar manner in the trench with a difference between the CMP rate of the mask layer (SiN) 21 and the CMP rate of the TEOS-SiO₂ layer 23.

Furthermore, as a preferable example of the insulator 23, in addition to the TEPS-SiO₂, TEOS-O₃—SiO₂ which is formed by using the TEOS-O₃ CVD method and HDP-SiO₂ which is formed by using the HDP (High Density Plasma) CVD method or the like can be given.

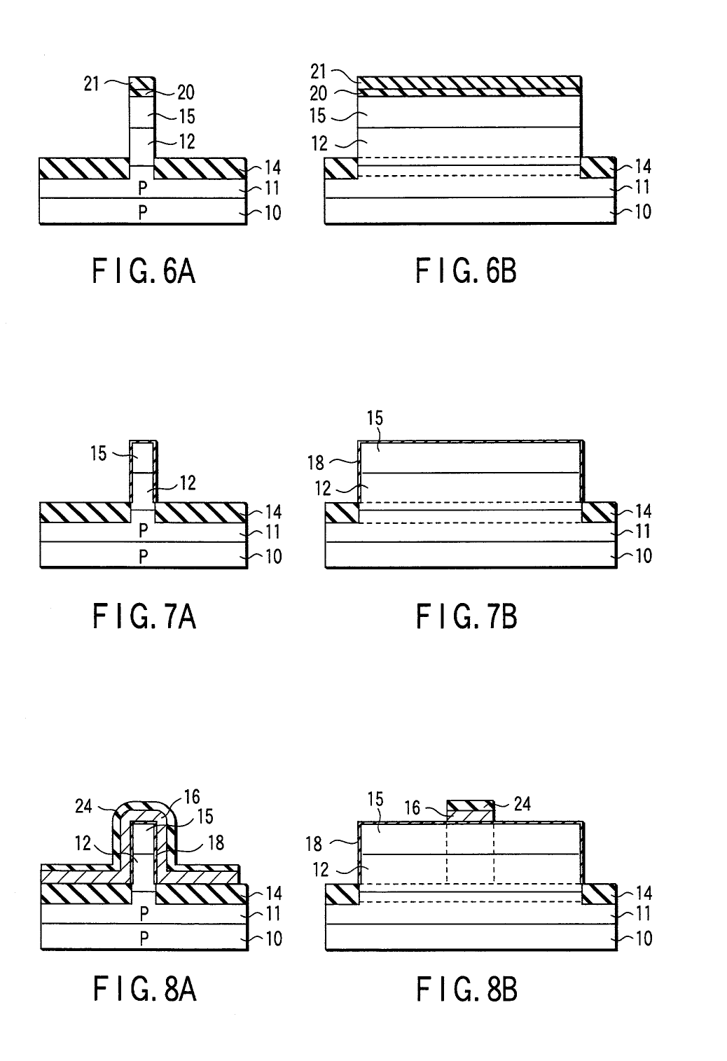

Next, as shown in FIGS. 6A and 6B, by using, for example, RIE method or the like, the TEOS-SiO₂ layer 23 is etched back. As a consequence, on the bottom portion of the trench, an isolation insulating film 14 for isolation having, for example, a thickness of about 100 nm is formed.

Next, as shown in FIGS. 7A and 7B, the mask layer (SiN) 21 is removed by using, for example, a hot phosphoric acid or the like. Next, the oxide film (not shown) formed on the side surface of the fence 13 and the SiO₂ layer 20 formed on the side surface of the fence 13 are removed by using a hydrofluoric acid solution. As a consequence, Si is exposed from the side surface of the fence 13 and the upper surface thereof. Next, on the exposed Si surface, a gate insulating film 18 is formed. A preferable example of the gate insulating film 18 is such that the exposed Si surface is subjected to oxidation of about 2.5 nm by using the radical oxidation method of about 700° C.

This radical oxidation method hardly depends upon the plane direction of the fence 13. As a consequence, a gate insulating having small unevenness can be realized. The MOSFET having the gate insulating film 18 with small unevenness is small in the reduction in the channel mobility, for example, by the scattering of the channel interface, and the performance is good.

Furthermore, the radical oxidation method is characterized in that only the SiO₂ film having a definite thickness can be formed at a certain temperature. As a consequence, there is provided an advantage that dispersion in the film thickness in the wafer surface of the gate insulating film 18 and a dispersion between chips of the gate insulating film 18 can be decreased respectively.

Needless to say, as the gate insulating film 18, a SiO₂ film, a so-called oxynitride film may be used in addition to the SiO₂ film formed by the radical oxidation method. The oxynitride film can be formed, for example, by forming a normal thermal oxide film by means of the thermal oxidation and nitrization the surface with gas including nitrogen.

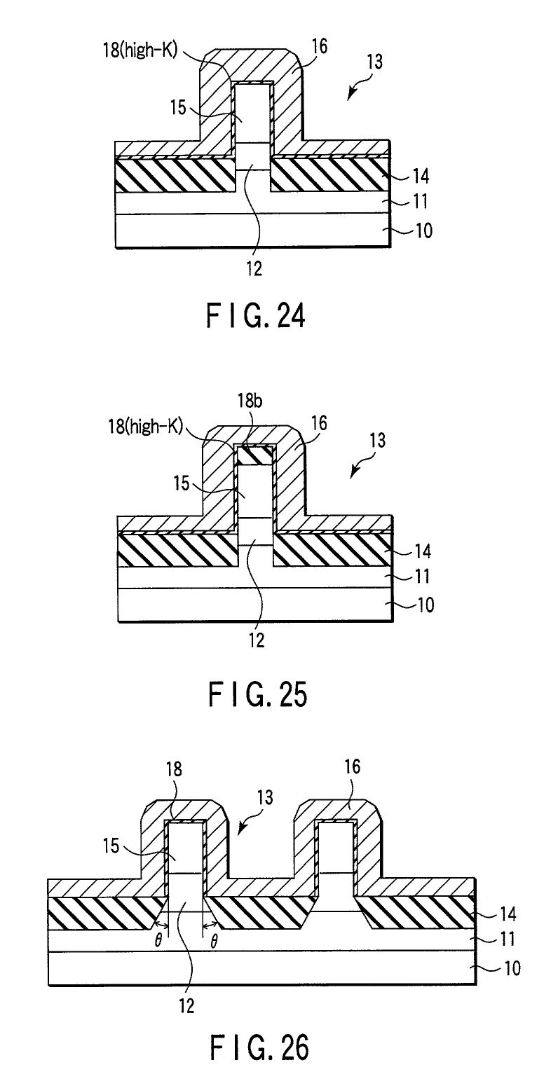

Furthermore, as the gate insulating film 18, not only the SiO₂ film and the SiON film, but also the so-called high dielectric insulating film (high-k film) may be used. One example of the MOSFET in which high-k film is used as the gate insulating film 18 is shown in FIG. 24.

As an example of the high-k film, a Ta₂O₅ film (so-called tartan oxide), an Al₂O₃ film, a La₂O₃ film, a HfO₂ film, ZrO₂ film and the like can be given.

In particular, a specific dielectric ratio E r of the Ta₂O₅ film is about 20 to 27, and is larger than a specific dielectric ratio ε r=3.9 of the SiO₂ film. As a consequence, the Ta₂O₅ film is a film which has a possibility in that the equivalent film thickness when the thickness is calculated in terms of the SiO₂ film can be set to 2 nm or less.

Furthermore, in the case where the Ta₂O₅ film is used as the gate insulating film 18, a so-called laminating gate insulating film structure may be provided in which the Si oxide film having a thickness of about 1 nm is formed on the Si interface surface, and the Ta₂O₅ film is formed thereon. In such laminated gate insulating film structure, the interface level density between the gate insulating film and the Si interface can be decreased.

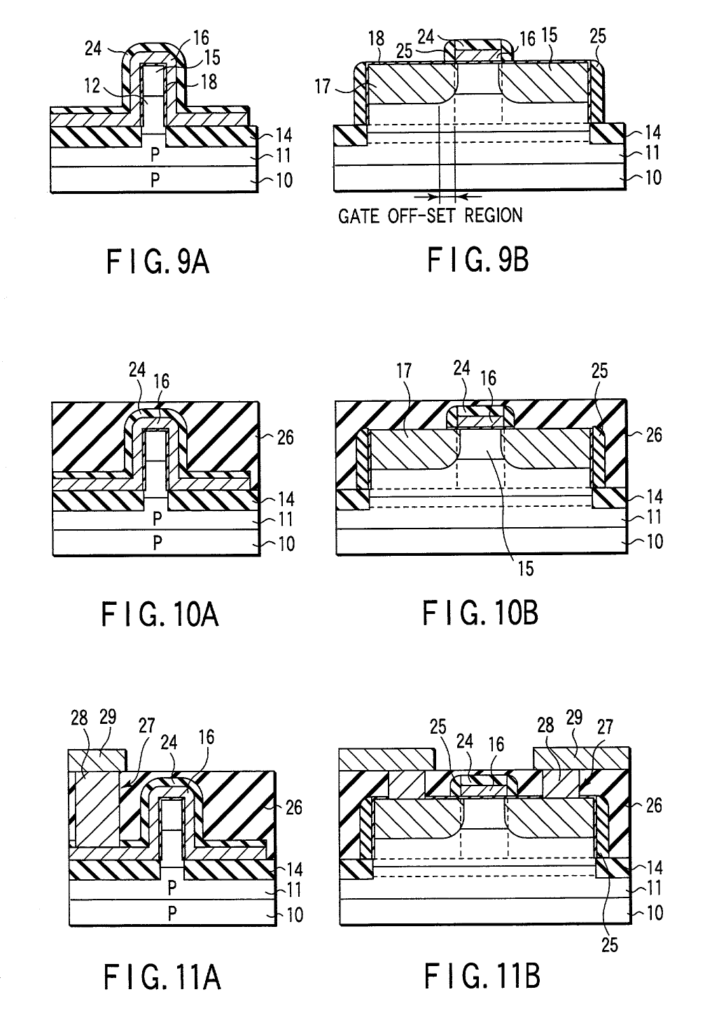

Next, as shown in FIGS. 8A and 8B, on a structure shown in FIGS. 7A and 7B, for example, a polycrystalline Si doped with the N-type impurity is deposited, for example, to about 100 nm, so that the doped polycrystalline Si film is formed. The doped polycrystalline Si film constitutes later a gate electrode 16. Next, for example, the SiN film is deposited to a thickness of about 100 nm on the doped polycrystalline Si film. This SiN film constitutes later a gate cap insulating film 24. Next, the resist film (not shown) is used as a mask to etch, in the beginning, the gate cap insulating film (SiN) 24, followed by using the gate cap insulating film 24 as a mask to etch the doped polycrystalline Si film. As a consequence, the gate electrode 16 is formed. At this time, the gate electrode 16 is processed extending over the fence 13. As a consequence, it is important that the doped polycrystalline Si film is etched by using a condition that the ratio (selective ratio) of the etching rate of this doped polycrystalline Si film and the etching rate of the gate insulating film 18 can be sufficiently taken, for example, a condition of about 400. By using such a condition, damage by the etching is prevented from being caused on the fence 13.

Furthermore, on the gate electrode 16, a metal film, a laminated gate structure formed of a metal film and a metal film, a laminated gate structure (so-called polymetal structure) formed of a polycrystalline Si film and a metal film, or a laminated gate structure (so-called polycide structure) formed of a polycrystalline Si film and a silicide film can be used. In the gate electrode 16 in which the metal structure, the laminated gate structure formed of the metal film and the metal film, the polymetal structure and the polycide structure are used, the resistance of the gate electrode 16 can be lowered as compared with the gate electrode using only the doped polycrystalline Si film.

As an example of the metal film, a TiN film, a W film, a WN film, a Ru film, an Ir film, an Al film or the like can be given.

As an example of the silicide film, the CoSi₂ film, the TiSi₂ film or the like can be given.

Furthermore, there is provided a characteristic that when the gate electrode 16 is constituted by using, for example, a TiN film, the work function of the gate electrode 16 can be changed by adjusting the arrangement or the like of the TiN film. As a consequence, the threshold voltage of the MOSFET can be adjusted by changing the work function of the gate electrode 16.

Besides, the length of the gate electrode (so-called gate length) can be set, for example, to about 70 nm. In this invention, though described in detail, since the short channel effect of the PMOSFET can be suppressed, both the NMOS and the PMOS may be designed so that the same channel length may be used.

Next, on the structure shown in FIGS. 8A and 8B, an insulator, for example, SiO₂, SiN or the like can be deposited by using the CVD method. Next, the deposited insulator is subjected to RIE so that this insulator is allowed to remain on the side-wall of the gate electrode 16, and on the side-wall of the fence 13. As a consequence, on the side-wall of the gate electrode 16 and on the side-wall of the fence 13, a side-wall insulating film 25 having a thickness of about 20 nm can be formed.

Next, the gate cap insulating film 24, the gate electrode 16 and the side-wall insulating film 25 are used as a mask, so that, for example, arsenic ions (As⁺) are implanted into the fence 13 under a condition of an acceleration voltage of 20 KeV, and a dose amount of about 5×10¹⁵ cm⁻². As a consequence, the N-type source/drain region 17 is formed in the fence 13.

Furthermore, before the side-wall insulating film 25 is formed, the gate electrode 16 is subjected to oxidation, for example, by means of the radical oxidation method, a low temperature RTO method or the like. For example, an oxide film (not shown) having, for example, a thickness of about 2 nm may be formed. One object of this oxide film is to alleviate the concentration of the electric field in the side-wall of the gate electrode 16 and the bottom corner.

Furthermore, in this example, a single source/drain structure has been described. It is possible to use a so-called extension structure in which the source/drain region 17 is constituted of a N⁻ type diffusion layer 17a and a N⁺ type diffusion layer 17b. One example of the MOSFET using an extension structure is shown in FIG. 29.

As shown in FIG. 29, the gate cap insulating film 24, the gate electrode 16, and the side-wall insulating film 25 are used as a mask, so that, for example, phosphorus ions (P⁺) are implanted into the fence 13 under the condition of an acceleration voltage of 40 KeV, and a dose amount of 4×10¹³ cm⁻². As a consequence, the N⁻ type diffusion layer 17a is formed in the fence 13. Needless to say, N⁻ type diffusion layer 17a may be formed by implanting arsenic ions or the like in place of phosphorus ions into the fence 13.

By the way, the control of the depth (Xj) of the N-type source/drain region is an important step. This is because the control is a step for determining the channel width of the transistor. In particular, attention should be paid to the setting of the temperature of thermal processing including the activation of impurities in the N-type source/drain region 17.

The depth (Xj) of the N-type source/drain region 17 is controlled with the thermal activation and thermal processing conditions after the final formation of the ion implantation layer. For example, the depth is realized by controlling the ion implantation condition (acceleration voltage and dose amount) and thermal activation conditions so that the depth of the PN junction depth (Xj) is set to about 0.12 μm.

In this example, out of the N-type source/drain region 17 which is exposed to the side surface of the fence 13, an offset region which becomes offset with the gate electrode 16 is present in a lower portion. This results from the fact that the N-type source/drain region 17 is formed with the ion implantation to the surface, in particular, the upper surface of the fence 13, and thermal diffusion. In the N-type source/drain region 17 having such an offset region, it is possible to suppress the generation of a punch-through, in particular, in the region of a lower portion of the N-type source/drain region. Furthermore, when a punch-through stopper layer 12 is further provided in the lower portion region of the N-type source/drain region 17 like the present example, it is possible to further effectively suppress the generation of the punch-through in the lower portion region of the N-type source/drain region 17.

Incidentally, in this example, there is provided a structure in which since the side surface of the fence 13 is covered with the side-wall insulating film 25, the ion implantation to the upper surface of the fence 13 becomes main at the time of the ion implantation for the formation of the N-type source/drain region 17 so that ion implantation of the impurities to the side surface can be prevented. However, the side-wall insulating film 25 is not necessarily required.

Furthermore, when it is required to decrease the specific resistance of the N-type source/drain region 17, a silicide layer (not shown) may be formed on the surface of the N-type source/drain region 17 in the case where, for example, it is desired that the specific resistance is set to about 50 μΩ·cm or less.

As an example of the silicide layer, TiSi₂, CoSi₂, PtSi, Pd₂Si, IrSi₃, RhSi or the like can be given. In particular, in the case where the source/drain region 17 is of P-type, Pd₂Si is effective in order to lower the contact resistance of this P-type source/drain region 17.

Next, as shown in FIGS. 10A and 10B, SiO₂ is deposited, for example, to 500 nm on the structure shown in FIGS. 9A and 9B by the CVD method.

As a consequence, the interlayer insulating film 26 is formed. After this, the interlayer insulating film 26 is densified for about 30 minutes in the atmosphere of the radical oxidation, at a temperature of about 700° C. This thermal step may be conducted also for the activation of the ion implantation layer of the N-type source/drain region 17. When it is desired that the depth (Xj) of the N-type source/drain region 17 is controlled, the densify temperature is lowered. Alternatively, RTA on the order of msec may be conducted at about 850° C. Furthermore, by using the two methods together, the ion implantation layer of the N-type source/drain region 17 may be activated. After this, the interlayer insulating film 26 is planarized by means of the CVD method.

Next, as shown in FIGS. 11A and 11B, a contact hole 27 is formed in the interlayer insulating film 26 by using the lithography and RIE. Next, a W (tungsten) film, an Al (aluminum) film, a TiN (titanium nitride) film/Ti (titanium) film and a laminated layer thereof are filled in the contact hole 27. As a consequence, a contact plug 28 is formed in the contact hole 27. Next, on the interlayer insulating film 26, a wiring layer 29 is formed which comes into an electric contact with the contact plug 28. The wiring layer 29 comprises a conductor having, for example, aluminum as a main component. Next, a passivation film (not shown) is deposited on the interlayer insulating film 26 and the wiring layer, so that a basic structure of the MOSFET according to the first embodiment of this invention is completed.

Out of the effects obtained from the MOSFET according to the first embodiment, representative effects will be described below.

(1) The source/drain region 17 formed in the fence 13 is separated from the isolation insulating film 14 formed on a lower region of the fence 13. As a consequence, the channel width of the MOSFET can be controlled with the depth of the source/drain region 17. As a consequence, there is realized a structure in which a dispersion in the etching depth of the trench which is generated at the time of the formation of the fence 13 does not affect a dispersion in the channel width.

(2) The width (Wg) of the fence 13 is made narrower than, for example, 0.20 μm. As a consequence, the channel impurity layer 15 can be completely depleted with the gate electrode 16 formed on two side surfaces of the fence 13 which are located opposite to each other. For example, the short channel effect can be suppressed by completely depleting the channel region 15.

(3) A high concentration impurity layer (punch-through stopper layer) 12 is provided between the channel region 15 of the fence 13 and a well 11 (or Si substrate 10). As a consequence, a punch-through between the source/drain can be prevented.

(4) A distance between the source and drain regions 17 exposed to the side surface of the fence 13 is formed in a configuration such that the distance is narrow in the upper portion of the side surface and the distance is widened toward the lower portion of the side surface. As a consequence, a punch-through between the source/drain can be prevented.

(5) In addition to (4), a configuration extremely different from the conventional one is provided wherein a part of the source/drain region 17 exposed to the side surface of the fence 13 is set to the outside of the gate electrode 16 in a self-aligning manner. As a consequence, a part of the source/drain region 17, for example, a part of the lower portion of the source/drain region is offset from the gate electrode 16. In this manner, a punch-through between the source/drain, in particular, a punch-through in the lower portion region between the source/drain can be prevented by causing the source/drain region 17 to have an offset region.

(6) A part of the MOSFET channel region 15 is a structure which is obtained in the side surface of the fence 13. However, a contact to the source/drain region 17, a contact to the gate electrode 16 and a wiring are formed on a plane which is completely planarized, for example, in the interlayer insulating film 26, or on the interlayer insulating film 26. As a consequence, a process technique of the conventional planar MOSFET can be used as it is.

(Second Embodiment)

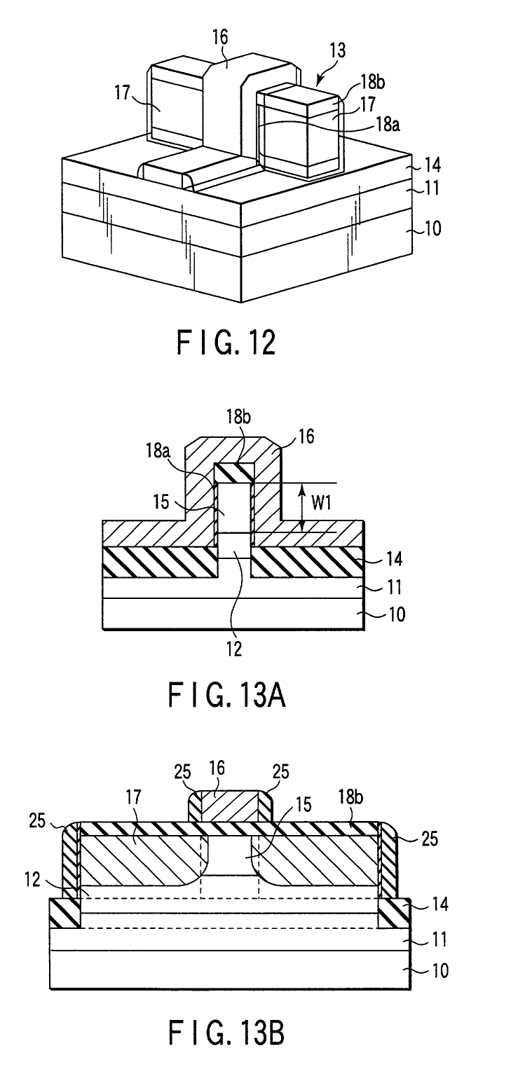

FIG. 12 is a perspective view showing a MOSFET according to a second embodiment of the present invention. FIGS. 13A and 13B are sectional views thereof, respectively. Incidentally, the cross section shown in FIG. 13A corresponds to the cross section shown in FIG. 2B. The cross section shown in FIG. 13B corresponds to the cross section shown in FIG. 2C. Furthermore, in FIG. 12, FIGS. 13A and 13B, the contact and the wiring layer shown in FIG. 2A are omitted respectively.

In the first embodiment, there is shown a structure in which the gate insulating film 18 is used which has approximately the same thickness on the upper surface and both side surfaces of the fence 13.

In the second embodiment, as shown in FIG. 12 and in FIGS. 13A and 13B, there is shown a structure in which the gate insulating film (TOP insulating film) 18b is present which has a thick thickness on the upper surface of the fence 13 as compared with the gate insulating film 18a on both side surfaces.

By using such a structure, the concentration of the gate electric field in the above corner can be alleviated, and the influence can be alleviated in the channel region 15 of the fence 13. Since the influence of the concentration of the gate electric field can be decreased, a change in the threshold voltage resulting from the concentration in the gate electric field, a change in the bias characteristic of the substrate, namely, a change in the threshold voltage at the time of the application of the substrate bias can be suppressed.

In order to obtain such a structure, at the step explained by referring to FIGS. 6A and 6B according to the first embodiment, the SiO₂ layer 20 formed on the upper surface of the fence 13 is allowed to remain without being removed. Thereafter, a gate insulating film 18a is formed on the side surface of the fence 13. As a consequence, a gate insulating film structure is realized which has two kinds of thickness; a thick gate insulating film 18b on the upper surface of the fence 13 and a thin gate insulating film on both side surfaces of the fence 13.

Incidentally, in particular, the gate insulating film 18a in the second embodiment is not restricted to SiO₂ film. As shown in FIG. 25, it is possible to use a so-called high dielectric insulating film (high-k film) such as a Ta₂O₅ film, a HfO₂ film, a ZrO₂ film or the like.

Incidentally, in the case where the Ta₂O₅ film is used as the gate insulating film 18a, a so-called laminated layer gate insulating film structure may be provided in which an Si oxide film having, for example, a thickness of 1 nm is formed on the Si interface in order to decrease the interface level density with the Si interface and the Ta₂O₅ film is then formed thereon.

Incidentally, it goes without saying that a variation in which the high dielectric insulating film (high-k film) is used as the gate insulating film 18a can be applied to all the embodiments which are described in this specification.

(Third Embodiment)

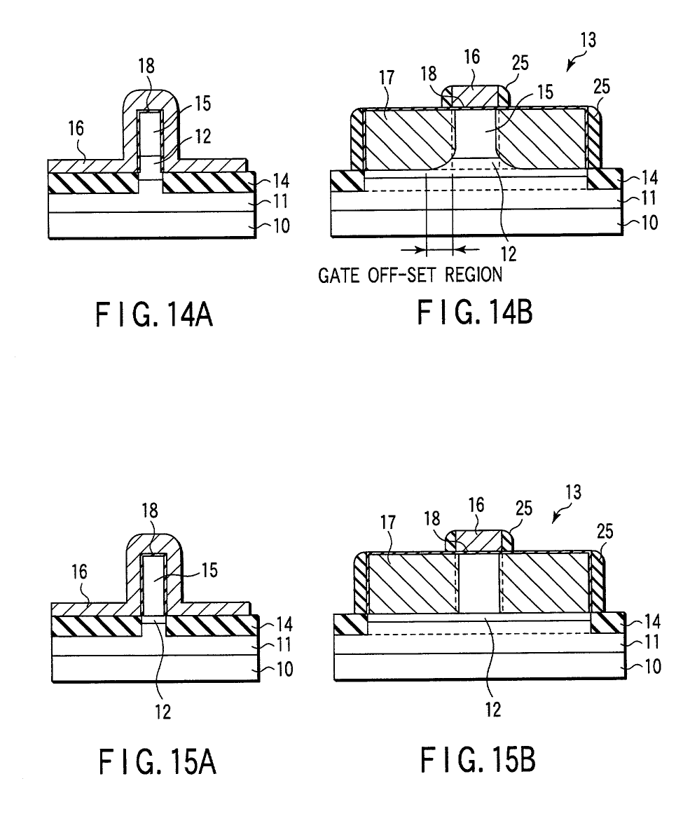

FIGS. 14A and 14B are sectional views showing a MOSFET according to a third embodiment of the present invention. Incidentally, the cross section shown in FIG. 14A corresponds to the cross section shown in FIG. 2B. The cross section shown in FIG. 14B corresponds to the cross section shown in FIG. 2C. Furthermore, in FIGS. 14A and 14B, the contact and the wiring shown in FIG. 2A are omitted, respectively.

In the first embodiment, there is shown a structure example in which a punch-through stopper layer 12 is present between the source and drain regions 17 formed in the fence 13 and the well 11 (or the Si substrate 10).

In the third embodiment, as shown in FIGS. 14A and 14B, the depth of the source/drain region 17 is deeper than that of the fist embodiment. For example, in this example, there is shown a case in which the bottom portion of the source/drain region 17 is approximately equal to the upper surface of the isolation surface 14 formed on the periphery of the fence 13, or deeper than the surface. In this case, the position of the bottom portion of the source/drain region 17 and the position of the gate electrode 16 approximately coincide with each other because the gate electrode 16 is formed from the upper surface of the isolation insulating film 14 along the side surface of the fence 13.

In such a structure, the channel width can be widened since the depth of the source/drain region 17 can be increased. Consequently, there can be provided an advantage that the height of the fence 13 can be lowered and the processing of the gate electrode 16 is easy.

(Fourth Embodiment)

FIGS. 15A and 15B are sectional views showing a MOSFET according to a fourth embodiment of the present invention, respectively. Incidentally, the cross section shown in FIG. 15A corresponds to the cross section shown in FIG. 2B. The cross section shown in FIG. 15B corresponds to the cross section shown in FIG. 2C. Furthermore, in FIGS. 15A and 15B, the contact and the wiring shown in FIG. 2A are omitted respectively.

In the first embodiment, there is shown a structure example in which a punch-through stopper layer 12 is present between the source/drain region 17 formed on the fence 13 and the well 11 (or the Si substrate 10), and the source/drain region 17 is offset with the gate electrode 16 on the side surface of the fence 13.

In the fourth embodiment, as shown in FIGS. 15A and 15B, there is shown a structure in which the depth of the source/drain region 17 is deeper than that of the first embodiment and an offset region does not exist. Specifically, for example, in this embodiment, the bottom portion of the source/drain region 17 is approximately equal to the upper surface of the isolation insulating film 14 formed on the periphery of the fence 13, or is deeper than the surface while the source/drain region is completely overlapped with the gate electrode 16 at the side surface of the fence 13. In order to obtain such a structure, for example, the gate electrode 16 and the side-wall insulating film 25 thereof are used as a mask, so that the source/drain region 17 may be formed by the solid phase diffusion from the film doped with impurity.

In such a structure, like the third embodiment, there is provided an advantage that the source/drain region 17 can be formed to a deep region, and a large channel width can be realized, so that the height of the fence 13 can be lowered and the process of the gate electrode 16 becomes easy.

(Fifth Embodiment)

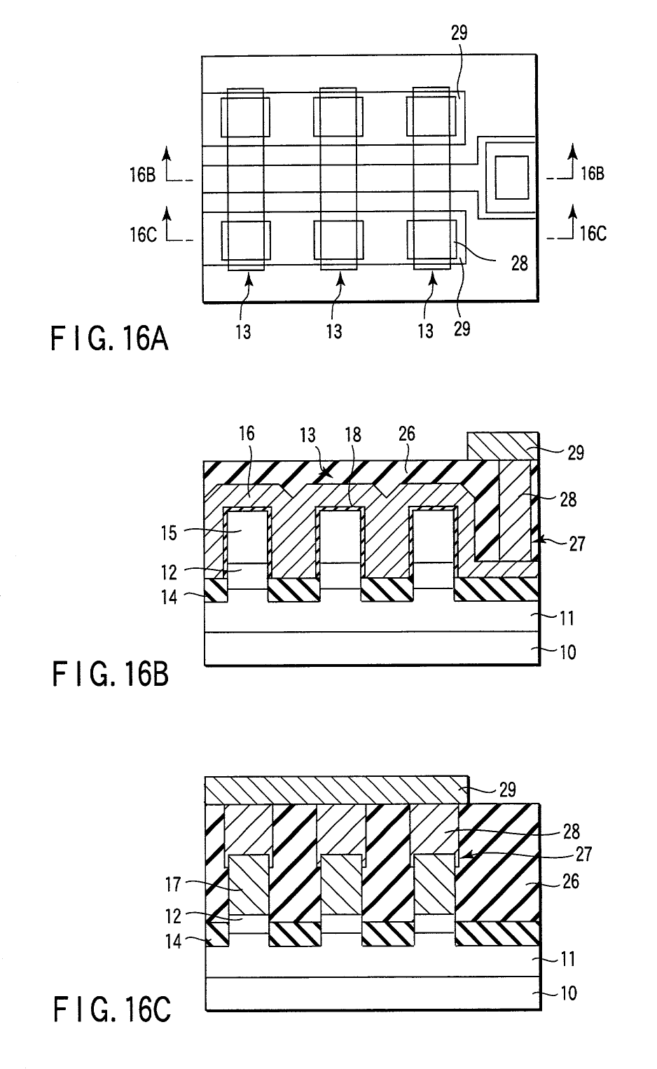

FIG. 16A is a plan view showing a MOSFET according to a fifth embodiment of the present invention. FIG. 16B is a sectional view taken along the line 16B-16B in FIG. 16A. FIG. 16C is a sectional view taken along the line 16C-16C in FIG. 16A.

In the first embodiment, there has been described a case in which the fence 13 is one.

In this fifth embodiment, there is described a case in which one MOSFET is formed by collecting a plurality of fences 13 in order to realize larger channel width.

As shown in FIGS. 16A to 16C, the fences 13 are arranged in parallel, a contact to the source/drain region 17 is shared and the gate electrode 16 is also shared. As a consequence, a large channel width can be realized.

Since the side surface of the fence 13 can be used as a channel width, a planar area can be reduced as compared with the MOSFET having a planar structure.

Furthermore, at this time, the contact to the gate electrode 16 can be formed on a portion arranged on the isolation insulating film 14 out of the gate electrode 16.

In the structure according to the fifth embodiment of the present invention, a plurality of fences 13 are arranged, and the source, the drain and the gate are operated as one transistor so that a larger channel width can be realized with a smaller planar area. As a consequence, there is provided a characteristic such that a higher density of the semiconductor integrated circuit can be realized. At this time, it is desirable that the width of a plurality of fences 13 are set to be approximately equal size and are mutually arranged. That is, when the width is the same, the respective MOSFET characteristics can be made equal.

Furthermore, from the viewpoint to the effect that the plurality of fences 13 are set to be approximately equal and mutually arranged so that the respective MOSFET characteristics can be set to be the same, the width of the fences 13 may be aligned to be the same in all the plurality of MOSFET's formed in one chip or a part thereof.

When the width of the plurality of fence 13 is aligned in this manner, there is provided an advantage that, for example, a plurality of fence 13 can be finely formed with ease.

That is because when the fence 13 is aligned, the fence 13 can be processed with ease and embedding becomes easy. As a consequence, a yield in the manufacture of the device is improved. This advantage is very useful for the miniaturization of the MOSFET which is expected to make a further progress and for a high integration of the semiconductor integrated circuit device.

Furthermore, in a plurality of MOSFETs which are accumulated on the semiconductor integrated circuit device, there is a difference in a drive performance which is required in the circuit structure.

Conventionally, an adjustment of the drive performance is made by the change in the channel width. The change in the channel width refers to a change in the width of the device region on which the MOSFET is formed. As a consequence, in the conventional semiconductor integrated circuit, a device region having various width is integrated in one chip. Such structure is finely formed with great difficulty, which is not so favorable for the miniaturization of the MOSFET which is expected to make a further progress and for a higher integration of the semiconductor integrated circuit device.

However, in the semiconductor integrated circuit device formed by using the MOSFET according to the present invention, it is possible to align the width of the fence 13 corresponding to the conventional device region and to completely align the whole layer. Ultimately, it is possible to align the width of all the fences 13.

That is because in the MOSFET, like the fifth embodiment, the channel width can be changed by allowing the gate electrode 16 to be shared with a plurality of fences 13, so that the drive performance can be adjusted.

(Sixth Embodiment)

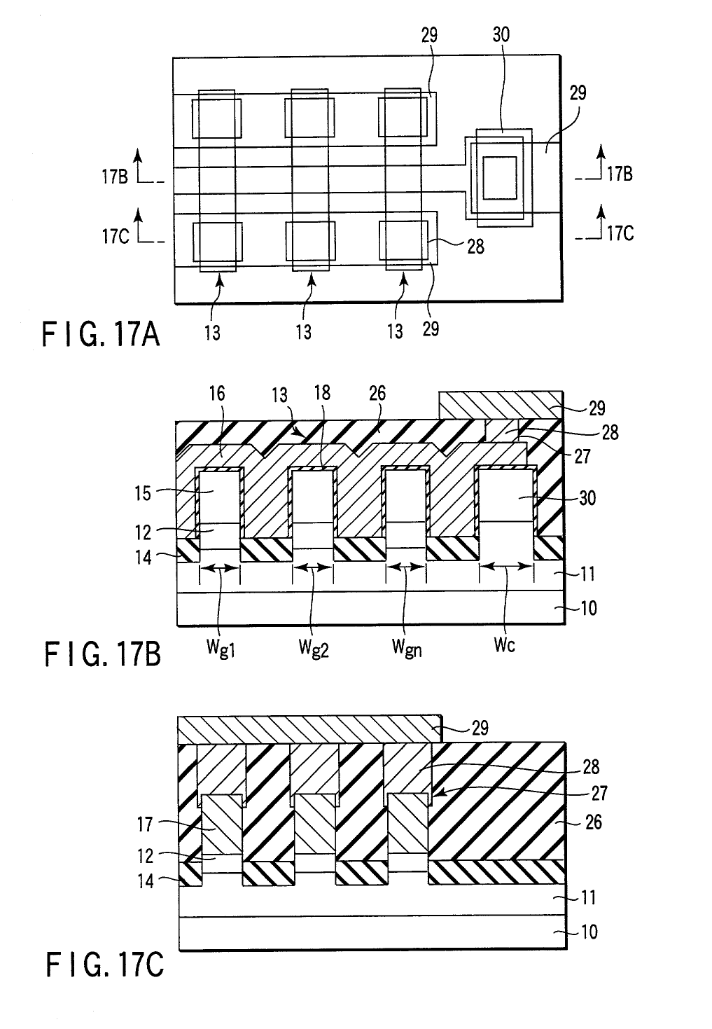

FIG. 17A is a plan view showing a MOSFET according to a sixth embodiment of the present invention. FIG. 17B is a sectional view taken along the line 17B-17B of FIG. 17A. FIG. 17C is a sectional view taken along the line 17C-17C of FIG. 17A.

In the fifth embodiment, there has been described a case in which one MOSFET is formed by collecting a plurality of fences 13 in order to realize larger channel width. Furthermore, there has been described a case in which a contact to the gate electrode 16 is formed on a portion of the gate electrode 16 which portion is arranged on the isolation insulating film 14.

The sixth embodiment is different from the fifth embodiment in a structure in which a contact to the gate electrode 16 is taken.

As shown in FIGS. 17A to 17C, for example, apart from the fence 13, a convex thin film Si layer 30 for taking a contact is formed, and the gate electrode 16 is extended up to the upper surface of the convex thin film Si layer 30. Then, a contact to the gate electrode 16 is taken above the upper surface of the convex thin film Si layer 30.

The size of the convex thin film Si layer 30 for this gate contact may be of a size such that a contact can be taken. Then, the object of the convex thin film Si layer 30 is to shrink a difference between the contact depth to the source/drain region 17 of the MOSFET and the contact depth to the gate electrode 16 of the MOSFET. With a structure having such convex thin film Si layer 30, a stable contact can be taken so that the manufacturing yield can be improved.

According to a structure according to the sixth embodiment of the present invention, the convex thin film Si layer 30 for the gate contact formation is formed so that a contact to the gate electrode 16 can be taken above the upper surface thereof. Therefore, a deep contact can be avoided and a stable manufacture of the wiring step is enabled.

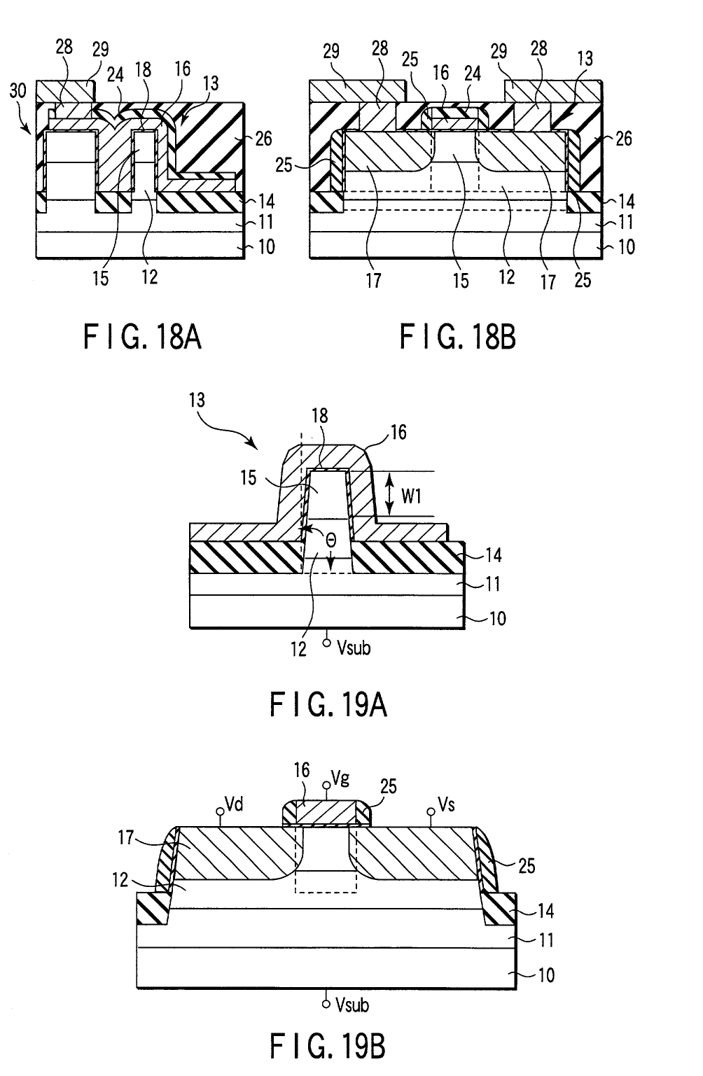

FIGS. 18A and 18B are sectional views showing a MOSFET according to another example of the sixth embodiment of the present invention. Incidentally, the cross section shown in FIG. 18A corresponds to the cross section shown in FIG. 2B. The cross section shown in FIG. 18B corresponds to the cross section shown in FIG. 2C.

As shown in FIGS. 18A and 18B, a structure according to the sixth embodiment is not restricted to a structure having a plurality of MOSFETs like the fifth embodiment. Like the first embodiment, the structure of the sixth embodiment can be applied to a structure having one MOSFET.

In this case as well, above the upper surface of the convex thin film Si layer 30 for the gate contact formation, formation of a deep contact can be avoided by taking a contact on the gate electrode 16 so that stable manufacture at the contact and wiring step is enabled.

(Seventh Embodiment)

FIGS. 19A and 19B are sectional views showing a MOSFET according to a seventh embodiment of the present invention respectively.

In the first embodiment, there has been described a case in which the fence 13 is formed so as to provide an angle approximately perpendicular to the Si substrate 10.

In the seventh embodiment, as shown in FIGS. 19A and 19B, a forward taper angle θ is provided with respect to the fence 13 in order to facilitate the process of the gate electrode striding over the fence 13 which constitute a step. For example, as compared with a perpendicular case, the process of the gate electrode 16 is extremely facilitated only by providing the fence 13 with a forward taper angle θ on the order of one to three degrees.

Furthermore, the formation of the fence 13 so as to have this taper angle θ has been explained by referring to FIGS. 4A and 4B showing the first embodiment. The etching condition may be adjusted at the time of etching the Si substrate 10 by using the mask layer 22 as an etching mask. It is relatively easy to provide a forward taper angle θ of one to three degrees.

In this manner, there is provided an advantage that the process of the gate electrode 16 can be facilitated by constituting the fence 13 into a forward taper structure so that the process of the gate electrode 16 can be facilitated, and a difference in the size conversion at the time of processing can be reduced.

(Eighth Embodiment)

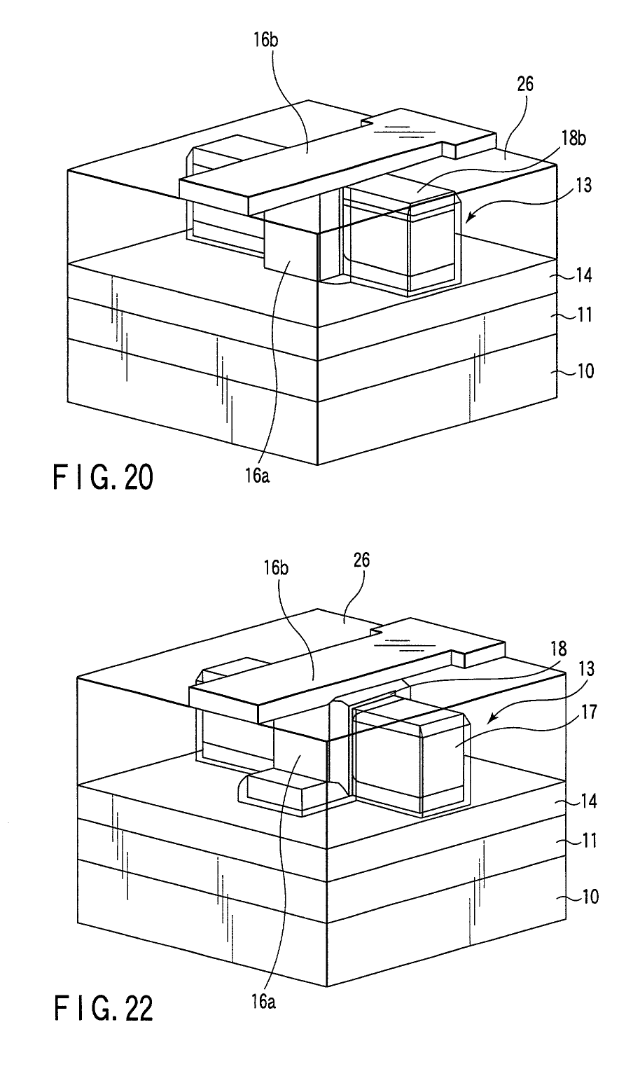

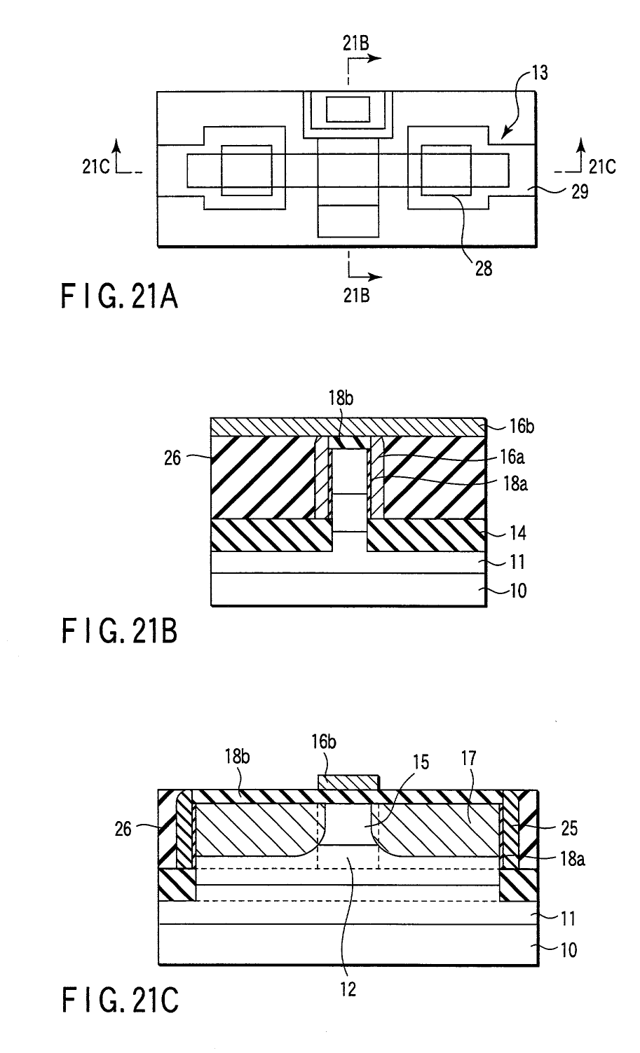

FIG. 20 is a perspective view showing a MOSFET according to an eighth embodiment of the present invention. FIG. 21A is a plan view thereof. FIG. 21B is a sectional view taken along the line 21B-21B of FIG. 21A. FIG. 21C is a sectional view taken along the line 21C-21C of FIG. 21A.

In the first embodiment, there is shown an example in which the gate electrode 16 comprising one pattern is formed along both side surfaces striding over the upper surface of the fence 13.

In a similar manner, in the fifth embodiment, there is shown an example in which the gate electrode 16 comprising one pattern strides over the plurality of fences 13 respectively, and is formed along both side surfaces thereof.

In the eighth embodiment, as shown in FIG. 20, and FIGS. 21A to 21C, the gate electrode 16 is configured of a plurality of patterns of a first gate electrode 16a which comes into contact with the gate insulating film 18a formed on the side surface of the fence 13, and a second gate electrode 16b which comes into contact with the gate insulating film (TOP insulating film) 18b formed on the upper surface of the fence 13. Incidentally, in this example, like the second embodiment, the gate insulating film (TOP insulating film) 18b is thicker than the gate insulating film 18a.

The first gate electrode 16a is individually formed on the first side surface of the fence 13, and the second side surface located opposite to the first side surface. Then, these first gate electrodes 16a are connected to the metal layer for connection to provide the second gate electrode 16b. Here, the gate electrode 16b can be also allowed to function as the gate electrode of the MOSFET. The second gate electrode (TOP insulating film) 18b is made sufficiently thicker and can be allowed to function as a wiring. In the case where the gate electrode is allowed to function simply as a wiring, it is possible to say that the structure is such that the gate electrode of the first MOSFET formed on the first side surface and the gate electrode of the second MOSFET formed on the second side surface opposite to the first side surface are mutually connected with the wiring, so that these MOSFETs are allowed to be operated as one MOSFET.

In order to form a structure according to the eighth embodiment of the present invention, the gate insulating film (TOP insulating film) 18b is used as a mask, a conductor which forms a first gate electrode 16a is allowed to remain on the side-wall of the fence 13a by the side-wall retention method using the RIE method, followed by later using a resist film as a mask to process the structure into a configuration of the gate electrode 16a. At this time, the gate insulating film (TOP insulating film) 18b formed on the upper surface of the fence 13 can be used as a mask for etching at the time of RIE and prevents the etching damage at the time of RIE from entering the fence 13. In this manner, the gate insulating film (TOP insulating film) 18b plays a particularly important role in a structure according to the eighth embodiment.

Furthermore, there is a possibility that a misalignment is generated between the first gate electrode 16a and the second gate electrode 16b. However, the electric characteristic of the MOSFET is not affected at all.

By taking an electrode structure according to the eighth embodiment, a material of the first gate electrode 16a, a poly Si layer, for example, doped with impurity can be formed only on the side-wall of the fence 13. As a consequence, there is a characteristic that the material of the gate electrode can be changed in accordance with the electric characteristic of the MOSFET.

Furthermore, even when the thickness of the first gate electrode 16a is reduced to about 50 nm, an increase in the wiring resistance can be suppressed by forming the metal layer which constitutes a second gate electrode 16b of a laminated layer or the like of the W film/TiN film/Ti film having, for example, a thickness of about 100 nm.

(Ninth Embodiment)

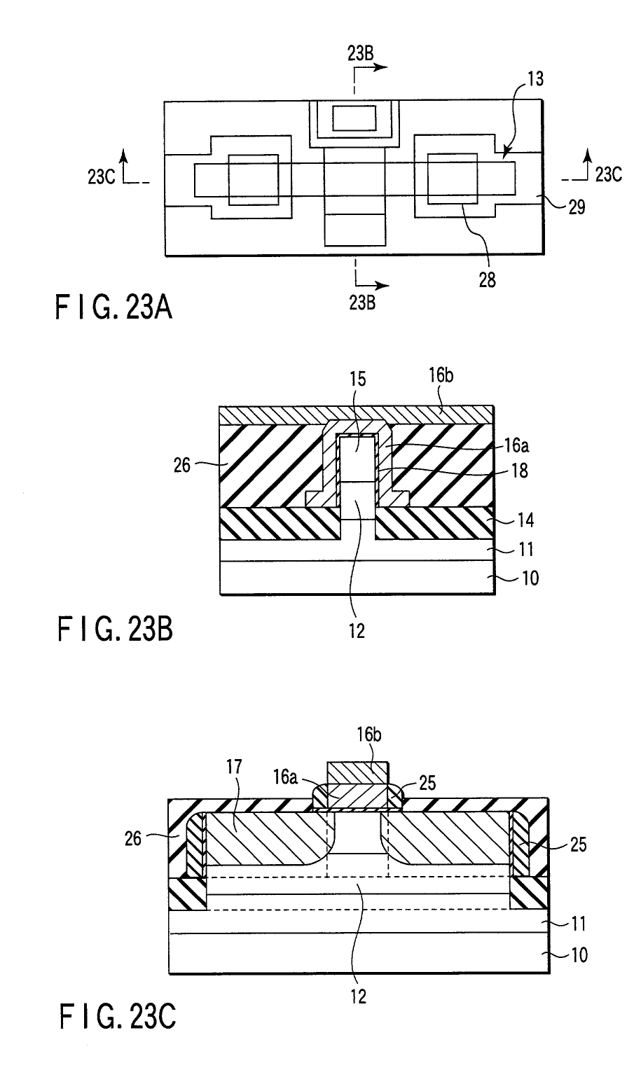

FIG. 22 is a perspective view showing a MOSFET according to a ninth embodiment of the present invention. FIG. 23A is a plan view thereof. FIG. 23B is a sectional view taken along the line 23B-23B of FIG. 23A. FIG. 23C is a sectional view taken along the line 23C-23C of FIG. 23A.

In the eighth embodiment, there is explained a structure in which the first gate electrode 16a is formed on the gate insulating film 18a formed on two sides of the fence 13 located opposite to each other, these first gate electrodes 16a are connected to each other by using the second gate electrode 16b formed on the gate insulating film (TOP insulating film) 18b formed on the upper surface of the fence 13.

The ninth embodiment, as shown in FIG. 22, and FIGS. 23A and 23B, has a laminated gate electrode comprising a gate electrode 16 formed on the gate insulating film 18 having the first gate electrode 16a formed on three surfaces; two side surfaces of the fence 13 located opposite to each other and an upper surface thereof; and a second gate electrode (metal) 16b electrically connected to the gate electrode 18.

In order to form such a structure, according to the first embodiment, at steps shown in FIGS. 8A and 8B, after processing the gate electrode 16 into a desired configuration, the side-wall insulating film 25 is formed on the side-wall of the gate electrode 16 and the source/drain region 17 is formed (FIGS. 9A and 9B). Thereafter, an interlayer insulating film 26 is formed and planarized (FIGS. 10A and 10B). When this interlayer insulating film 26 is planarized, an attempt is made to selectively expose the surface of the gate electrode 16. Thereafter, a metal laminated layer (for example, W film/TiN film/Ti film) which constitutes the second gate electrode 16b is deposited and a resist film (not shown) is used to be patterned into a desired configuration to form the second gate electrode 16b.

In the ninth embodiment, like the eighth embodiment, there is a possibility that a misalignment is generated between the gate electrode 16 and the second gate electrode 16b. However, there is no influence exerted upon the electric characteristic of the MOSFET.

With the electrode structure according to the ninth embodiment, the gate electrode 16 can be formed which is made of a first gate electrode material, for example, a poly Si layer doped with impurities on three surfaces, that is, two side surfaces and an upper surface of the fence 13. Furthermore, the second gate electrode 16b can be formed which is electrically connected to the gate electrode 16, and is formed of, for example, a second gate electrode material having a lower resistance value such as a metal or a metal laminated layer. As a consequence, there is provided a characteristic that the gate electrode material can be changed in accordance with the electric characteristic of the MOSFET.

Furthermore, it is possible to suppress an increase in the wiring resistance at the laminated metal connection layer which constitutes the second gate electrode even when the gate electrode 16 is thinned down to a thickness of, for example, about 50 nm.

(Tenth Embodiment)

FIG. 26 is a sectional view showing a MOSFET according to a tenth embodiment of the present invention. Incidentally, the cross section shown in FIG. 26 corresponds to the cross section shown in FIG. 1B.

In the first embodiment, in the case where the isolation insulating film 14 is embedded and formed in the lower portion periphery region of the fence 13, as shown in FIGS. 6A and 6B, a isolation insulating film 14 is formed on the extended surface of the fence 13.

The tenth embodiment is an example in which in the case where the isolation insulating film 14 is embedded and formed, the isolation insulating film having a forward taper angle θ of, for example, about 10 degrees is formed on the lower region of the fence 13 so that the embedded configuration of the isolation insulating film 14 is not deteriorated.

As shown in FIG. 26, the embedded characteristic of the insulating film 23 shown in FIGS. 5A and 5B, particularly, in the lower portion region of the fence 13 can be remarkably improved by providing a forward taper angle θ of about 10 degrees as compared with, for example, a perpendicular case.

Furthermore, in order to process to have a taper angle θ in the lower portion region of the fence 13, the etching condition may be changed to provide the forward taper angle θ at the final stage at the etching time of the fence 13. In the lower portion region of the fence 13, the forward taper angle θ of about 10 degrees can be relatively easily realized with the change of the etching condition.

In this manner, there is provided a characteristic that the embedded characteristic of the isolation insulating film 14 can be improved and a stable isolation region can be formed by providing a convex Si structure in which the lower portion region of the fence 13 has a forward taper angle θ of about 10 degrees and an approximately perpendicular side surface which constitutes a MOSFET channel of the upper portion region.

(Eleventh Embodiment)

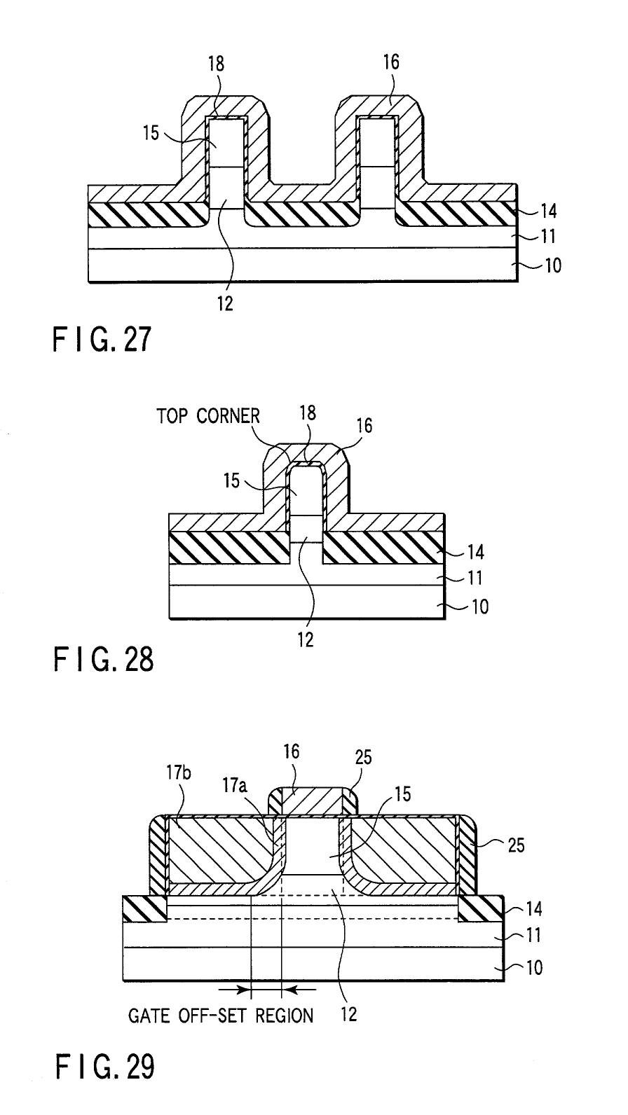

FIG. 27 is a sectional view showing a MOSFET according to an eleventh embodiment of the present invention. Incidentally, the cross section shown in FIG. 27 corresponds to the cross section of FIG. 1B.

In the first embodiment and the tenth embodiment, there have been explained, as shown in FIGS. 6A and 6B, an example in which the upper surface of the isolation insulating film 14 is formed to be approximately horizontal with respect to the surface of the Si substrate in the case where a isolation insulating film 14 is embedded and formed in the lower region of the fence 13, and an example in which the bottom portion of the isolation film 14 becomes approximately perpendicular.

In the eleventh embodiment, with respect to the case where the isolation insulation film 14 is embedded and formed, there has been described an example in which, for example, a bottom corner of the fence 13 has a round with a radius on the order of about 50 nm so that the embedded configuration of the isolation insulating film 14 is not deteriorated, and an example in which the surface of the isolation insulating film 14 is formed in such a manner that the thickness of the film 14 becomes thin toward the central portion of the isolation insulating film 14 from the peripheral portion of the fence 13 instead of being set to be horizontal with respect to the surface of the Si substrate 10.

As shown in FIG. 27, the embedded characteristic of the isolation insulating film 14 shown in FIGS. 5A and 5B, in particular, in the lower portion region of the fence 13 can be remarkably improved by forming a round of a radius of about 50 nm in the bottom corner of the fence 13.

Furthermore, in order to process the bottom corner of the fence 13 to have a round, the etching condition of the fence 13 may be changed so that the bottom corner has a round.

Furthermore, for example, when the isolation insulating film 14 in the lower portion region of the fence 13 is formed in such a manner that the thickness of the isolation insulating film 14 becomes thick at the lower portion region of the fence 13 and becomes thinner toward the central portion of the isolation insulating film 14, the residual of the gate electrode 16 can be prevented on the surface of the isolation insulating film 14 on the periphery of the fence 13 when the gate electrode 16 is processed. Thus, the short circuit of the gate electrodes 16 can be prevented and an yield of the product can be improved.

Furthermore, in order to process the isolation insulating film 14 to have the above configuration, for example, a thermal oxide film with a thickness of about 10 nm is formed so that the CVD insulating film such as the HDP (High Density Plasma), O₃ (ozone)-TEOS oxide film or the like may be embedded on the side face of the fence 13 via the thermal oxide film. By using the CMP method, or the RIE method, as shown in FIGS. 6A and 6B, the CVD insulating film is embedded and formed. Finally, the wet etching condition is adjusted so that the thermal oxide film is etched by selecting a condition (a temperature of the etching liquid, and a concentration of fluoric acid or the like) such that the wet etching rate is slower with the CVD insulating film so that the insulating film may be formed. Thus, the thickness of the film becomes thick only in the vicinity of the fence 13.

The embedded characteristic of the isolation insulating film 14 in the lower portion region of the fence 13 can be remarkably improved by forming a round having a radius of about 50 nm on the bottom corner of the fence 13 in this manner.

Furthermore, for example, when the thickness of the isolation insulating film 14 is formed in such a manner that the thickness of the isolation insulating film 14 is thick in the vicinity of the lower portion region of the fence 13, and becomes thinner toward the central portion of the isolation insulating film 14, the residual of the gate electrode 16 can be prevented on the surface of the isolation insulating film 14 of the lower portion of the fence 13, the short circuit of the gate electrodes 16 can be prevented and the yield of the product can be improved when the gate electrode 16 is processed.

(Twelfth Embodiment)

FIG. 28 is a sectional view showing a MOSFET according to the twelfth embodiment of the present invention. Incidentally, the cross section of FIG. 28 corresponds to the cross section of FIG. 1B.

In the first embodiment, there has been explained an example in which a top corner on which the upper surface and the planar surface of the fence 13 contact with each other is processed approximately at a right angle.

In the twelfth embodiment, a round of the top corner will be described.

As shown in FIG. 28, the influence of the electric field from the gate electrode 16 of the MOSFET can be remarkably decreased as compared with the case in which the top corner is set approximately at a right angle by providing a round having a radius of about 30 nm, for example, on the top corner. As a consequence, pressure endurance of the gate insulating film 18 can be improved, and the influence of the parasitic channel in the gate electric field can be lowered.

Various methods are available for forming a round having a radius of about 30 nm on the top corner of the fence 13. For example, in the first embodiment, the side-wall surface of the fence 13 is subjected to thermal oxidation while retaining the mask SiN film 15 in the state shown in FIGS. 6A and 6B. As a consequence, on the upper portion of the fence 13, a dent having a radius of 30 nm can be formed at the top corner by carrying out the LOCOS (Local Oxidation of Silicon)-like selective oxidation. Thereafter, the mask SiN film 15 is removed and the gate insulating film 18 is formed so that a round having a radius of about 30 nm can be provided on the top corner. The amount of the round changes somewhat depending upon the selective oxidation amount.

The influence of the electric field from the gate electrode of the MOSFET can be remarkably decreased by providing a round having a radius of 30 nm on the edge portion corner (top portion corner) of the upper surface of the fence 13 in this manner so that the pressure endurance of the gate insulating film 18 can be improved. Furthermore, there is a characteristic that the influence of the parasitic channel in the concentration of the gate electric field can be decreased.

The similar advantage as in the twelfth embodiment can be obtained, the top corner has an angle larger than 90 degrees as shown, for example, FIG. 19.

(Thirteenth Embodiment)

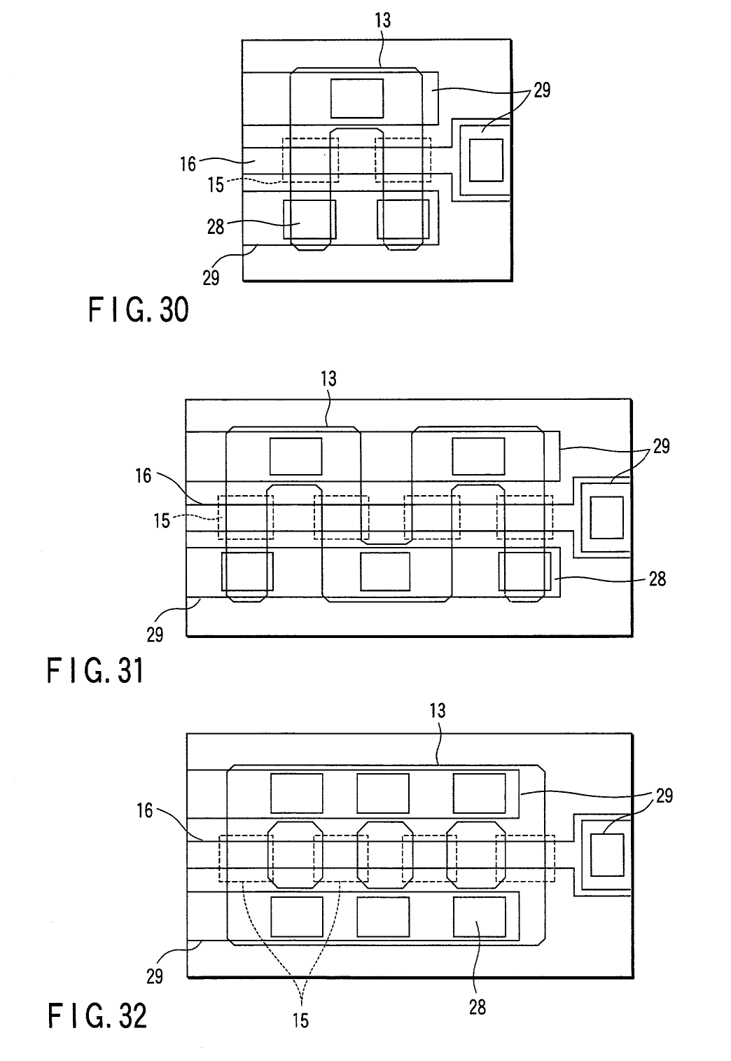

FIG. 30 is a plan view showing a MOSFET according to a first example of the thirteenth embodiment of the present invention. FIG. 31 is a plan view showing the MOSFET according to a second example of the embodiment. FIG. 32 is a plan view showing a MOSFET according to third example of the embodiment.

In the fifth embodiment, there has been described a case in which one MOSFET is formed by collecting a plurality of fences 13 in order to realize large channel width.

In the thirteenth embodiment of the present invention, there will be described a source/drain structure in the case where a structure is used which has one source/drain region 17, and the gate electrode 16.

FIG. 30 is a view showing as a first example a joint structure of the source/drain region 17 in the case where two fences 13 are provided.

As shown in FIG. 30, the fences 13 are arranged in parallel and one of the source/drain region 17 is shared by using the fence 13 itself. As a consequence, the fence 13 is bent in a planar manner so that a U-shaped structure is provided as seen from a planar surface. The number of contacts can be decreased by taking such structure.

FIG. 31 is a view showing, as a second example, a joint structure of the source/drain region 17 in the case where four fences 13 are provided.

As shown in FIG. 31, the fences 13 are arranged in parallel, one of the source/drain region 17 is shared in a pair by using the fence 13 itself.

As a consequence, the fence 13 has a configuration in which several U-shaped structures as seen from a planar surface are combined. By assuming such a structure, like the case as shown in FIG. 30, the number of contacts can be decreased. Furthermore, the density in the device arrangement can be improved by changing the structure of the fence 13.

FIG. 32 is a view showing, as a third example, a joint structure of the source/drain region 17 in the case where four fences 13 are provided.

As shown in FIG. 32, there is provided a structure in which the fences 13 are arranged in parallel and the fences on both sides which constitute the source/drain region 17 is connected by using this fence itself. By assuming such a structure, the number of contacts can be decreased in the same manner as FIGS. 30 and 31. Furthermore, the density of the device arrangement can be improved by changing the structure of the fence 13.

(Fourteenth Embodiment)

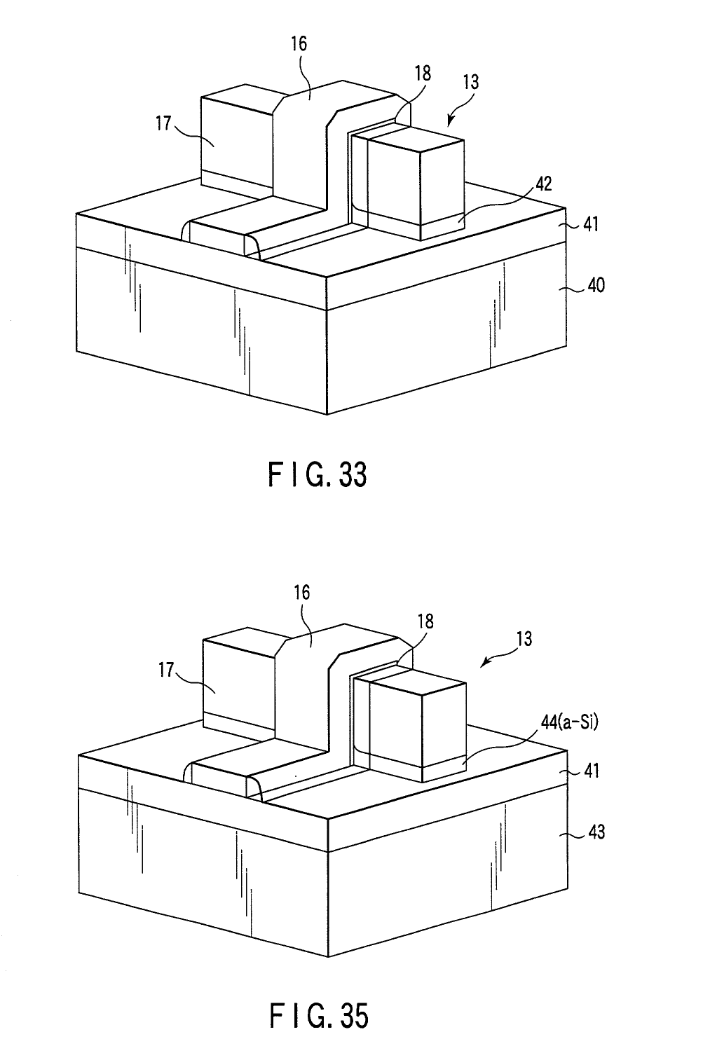

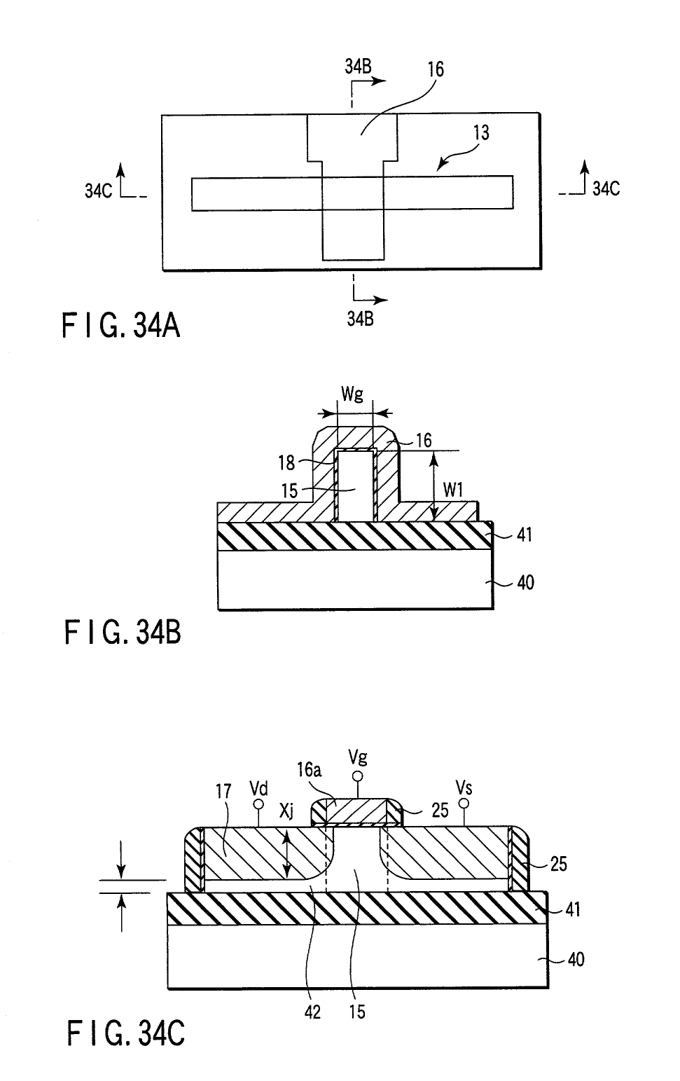

FIG. 33 is a perspective view showing a MOSFET according to a fourteenth embodiment of the present invention. FIG. 34A is a plan view thereof. FIG. 34B is a sectional view taken along the line 34B-34B in FIG. 34A. FIG. 34C is a sectional view taken along the line 34C-34C in FIG. 34A. Furthermore, in FIG. 33 and FIGS. 34A to 34C, the contact and the wiring shown in FIG. 2A are omitted respectively.

In the first embodiment, there has been shown a structure in which the isolation insulating film 14 is arranged on the periphery of the lower portion region of the fence 13, and moreover the channel region 15 of the fence 13 is electrically connected to the Si substrate 10 so that a substrate bias can be applied to the channel region 15.

In the fourteenth embodiment, as shown in FIG. 33 and FIGS. 34A to 34C, for example, the SOI substrate 40 is used, the thin film Si layer having a thickness of about 200 nm is formed on the insulating film 41 of this SOI substrate 40, so that the layer is processed to form the fence 13. Furthermore, there is provided a structure in which an Si layer 42 having the same conductive type as the channel region 15 is present between the bottom portion of the source/drain region 17 of the MOSFET, the insulating film 41, for example, an embedded oxide film.

Since this structure is the SOI structure, the substrate bias cannot be applied. However, the influence of the accumulated charge (hole in the case of the N-type channel) accumulated in the channel region can be expanded up to the bottom of the source/drain region 17 at the time of the operation of the MOSFET, so that the influence such as the deterioration of the pressure endurance of the source/drain can be decreased.

In order to realize such a structure, the structure as shown in the first embodiment may be manufactured by using the SOI substrate 40. Then, it is important to form the Si layer 42 having the same conductive type as the channel region 15 between the bottom portion of the source/drain region 17 and the insulating film 40.

(Fifteenth Embodiment)

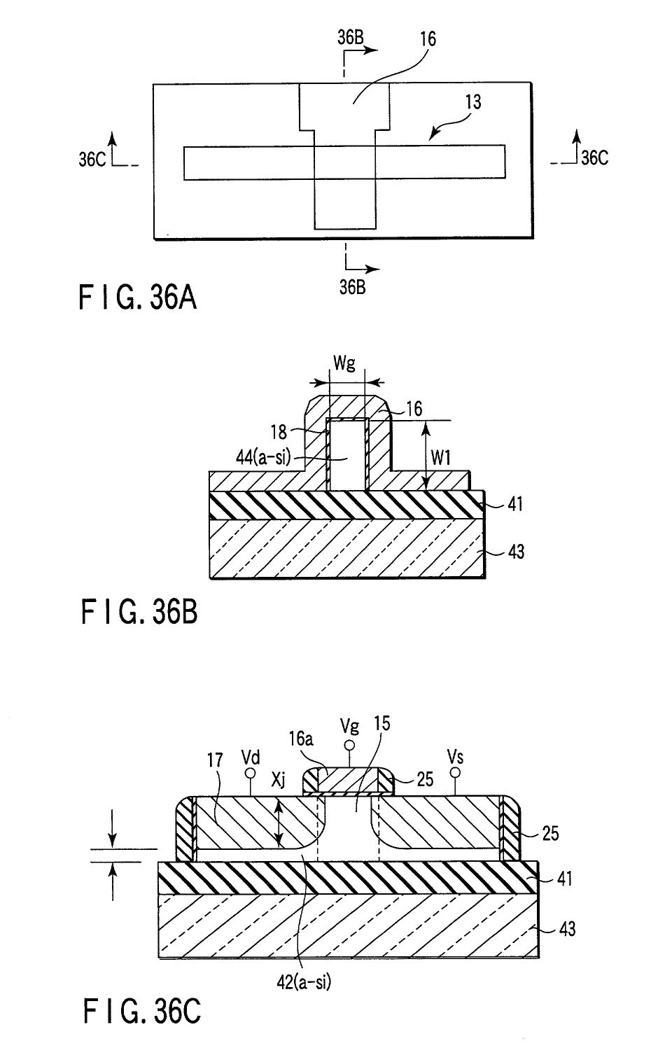

FIG. 35 is a perspective view showing a MOSFET according to a fifteenth embodiment of the present invention. FIG. 36A is a plan view thereof. FIG. 36B is a sectional view taken along the line 36B-36B of FIG. 36A. FIG. 36C is a sectional view taken along the line 36C-36C of FIG. 36A. Furthermore, in FIG. 35, FIGS. 36A to 36C, the contact and wiring shown in FIG. 2A are omitted, respectively.

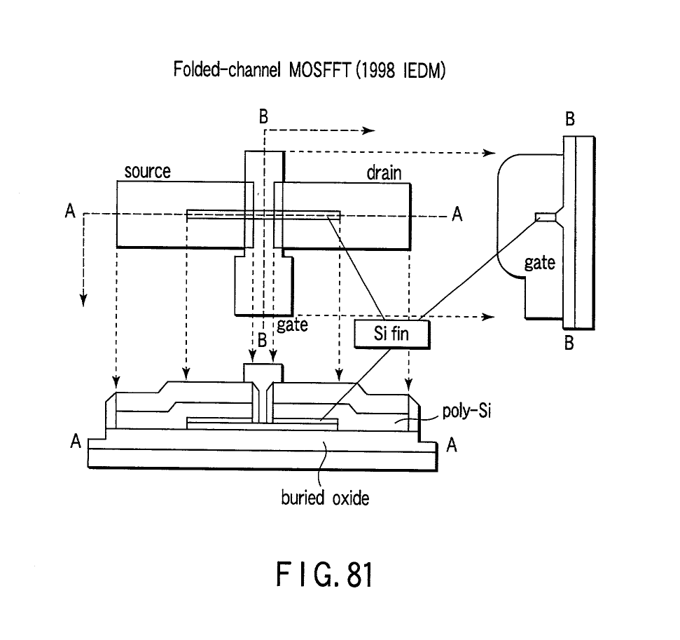

In the fourteenth embodiment, there has been described a structure in which the channel is formed on both sides of the fence 13 by using the SOI substrate 40, and preferably, the channel is completely depleted at the time of the operation so that the short channel effect of the MOSFET structure is improved. At this time, a difference from the conventional thin film SOI Fin structure MOSFET (FIG. 81) is that a Si layer 42 having the same conductive type as the channel is provided between the bottom portion of the source/drain region 17 and the insulating film 41. As a consequence, the substrate floating effect which is the problem with the MOSFET using the conventional thin film SOI can be prevented.

The fifteenth embodiment of the present invention is, as shown in FIG. 35 and FIGS. 36A to 36C, such that an amorphous Si layer is processed which has a thickness of about 200 nm on a glass substrate 43 by using, for example, the glass substrate 43 and the amorphous Si layer is processed to form a MOSFET having the fence 13 which is the same as in the fourteenth embodiment. A structure in which an Si layer having the same conductive type as the channel region 15, an amorphous layer 44 in this example is present between the bottom portion of the source/drain region 17 of the MOSFET and the glass substrate 43 is the same as in the fourteenth embodiment.

By using such a structure, a completely depleted channel can be realized with a double gate structure even with the amorphous Si layer MOSFET using the glass substrate 43. Consequently, the characteristic of the amorphous Si-MOSFET can be improved.

In order to realize such a structure, the manufacturing method as shown in the first embodiment may be realized by using the amorphous Si layer formed on the glass substrate 43. Needless to say, also in the fifteenth embodiment, like the fourteenth embodiment, it is important that the amorphous Si layer 44 having the same conductive type as the channel region 15 is formed between the bottom portion of the source/drain region 17 and the glass substrate 43.

(Sixteenth Embodiment)

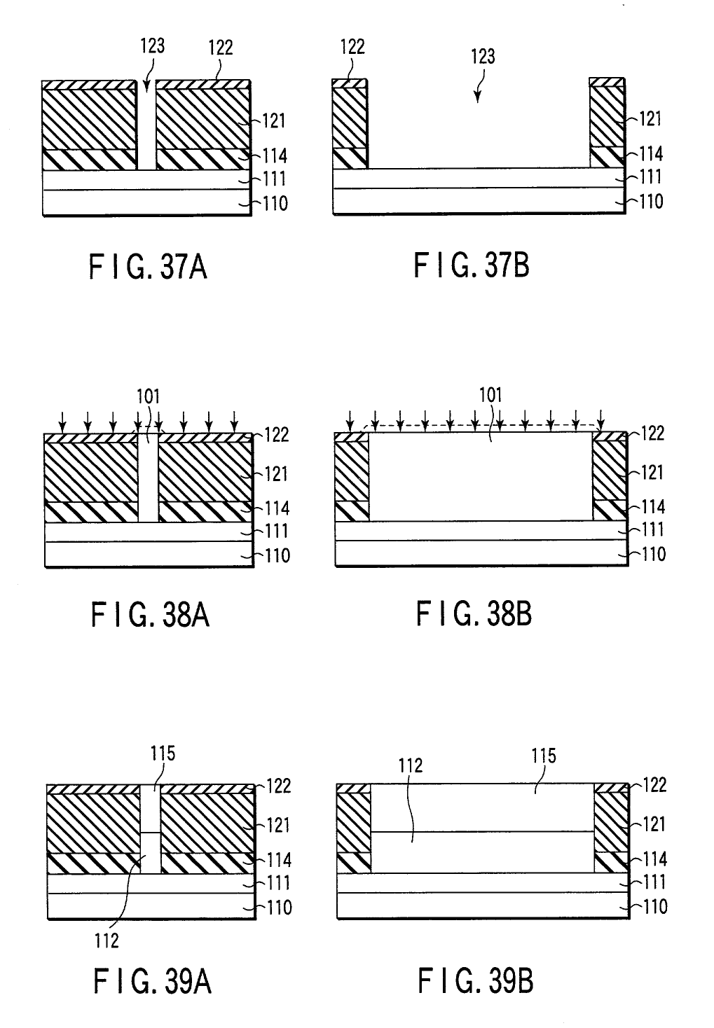

FIGS. 37A to 42A, FIGS. 37B to 42B are sectional views showing a manufacturing method of the MOSFET according to the sixteenth embodiment of the present invention. Incidentally, the cross sections shown in FIGS. 37A to 42A correspond to the cross section shown in FIG. 2B. The cross sections shown in FIGS. 37B to 42B correspond to the cross section shown in FIG. 2C.

In the first embodiment, there has been described an example in which the fence 13 is formed by etching the Si substrate 10 by using the mask layer 22.

In the sixteenth embodiment, there is shown a method for forming a double-gate type MOSFET structure having a completely depleted channel by using an epitaxial Si layer to form the fence 13. Hereinafter, the method will be explained by referring to the sectional views shown in FIGS. 37 to 42.

In the beginning, as shown in FIGS. 37A and 37B, in the case where the NMOSFET is formed in the transistor channel region of the P-type Si substrate 110 of the plane direction (100) having an impurity concentration of about 5×10¹⁵ cm⁻³, the P-type well 111 (for example, about 4×10¹⁷ cm⁻³ at the peak impurity concentration) is formed by implanting, for example, boron ions (B⁺) at the acceleration voltage of 260 KeV, and a dose amount of 2×10¹³ cm⁻². Furthermore, in the case where the PMOSFET is formed, the N well (not shown) is formed. Next, the SiO₂ film 114 which constitutes a isolation insulating film is formed to, for example, about 100 nm on the entire surface above the Si substrate 110. Next, the mask layer (SiN) 121 which becomes a main material in the case where the epitaxial Si layer is grown is formed to, for example, about 200 nm. Next, the mask layer (SiO₂) 122 is formed to, for, example, about 50 nm which becomes a protect layer when the epitaxial Si layer is subjected to the CMP. Next, a desired pattern is formed on these laminated layer by using, for example, resist film (not shown) and the RIE method. In this example, a trench pattern 123 is formed in order to form the fence 13 comprising the epitaxial Si layer. After this, etching damage at the time of RIE or organic contamination layer is removed from the surface of the Si substrate 10 exposed from the trench pattern 123. The damage and the contamination layer are removed in consideration of the epitaxial growth of Si which is conducted at the next step and the epitaxial growth thereof may be conducted when needed.

Next, as shown in FIGS. 38A and 38B, after a natural oxide film or the like is removed from the surface of the Si substrate 110 exposed from the trench pattern 123, Si is epitaxially grown to form an epitaxial Si layer 101. The thickness thereof is set to a size such that the inside of the trench pattern 123 can be completely embedded. One concrete example of the thickness is about 400 nm. Next, the surface of the epitaxial Si layer 101 is subjected to the CMP by using the mask layer (SiO₂) 122 as a mask, so that the epitaxial Si layer 101 protruded above the mask layer 122 is removed from the trench pattern 123. As a consequence, the unevenness on the surface of the epitaxial Si layer 101 is removed. By doing so, a facet or the like of the epitaxial Si layer 101 formed in the trench pattern 123 can be removed, and the epitaxial Si layer 101 can be precisely formed in the trench pattern 123. It is important that an attention should be paid to a growth temperature, an atmosphere at the time of the epitaxial growth, and preprocessing, so that no crystal defect is formed at an interface between the epitaxial Si layer 101 and the Si substrate 110.

Furthermore, in this example, the mask layer (SiO₂) 122 is used as a mask to subject the epitaxial Si layer to the CMP. However, the mask layer (SiO₂) 122 can be omitted by adjusting the CMP conditions or the like.

Next, as shown in FIGS. 39A and 39B, a resist film (not shown) is used as a mask in a region including at least a transistor channel formation region of the epitaxial Si layer 101 so that, for example, boron ions (B⁺) are implanted to form a high concentration impurity layer 112 having an impurity concentration of about 2×10¹⁸ cm⁻³ at the peak concentration. This high concentration impurity layer 112 functions as a punch-through stopper layer. At the time of this step, on the surface of the epitaxial Si layer 101, an oxide film (not shown) having a thickness of about 8 nm is formed with the result that a contamination of the epitaxial Si layer 101 from the resist layer, for example, the contamination of the metal or the like is prevented. Furthermore, for the activation of the implanted ions, the RTA processing is used for about five minutes, for example, at 900° C. in the atmosphere of nitrogen (N₂). As a consequence, a P-type high concentration impurity layer 112 having a steep profile can be formed. Furthermore, the resist film (not shown) is used as a mask in the region including, for example, a transistor channel formation region, and impurity ions are implanted having a desired conductive type to form a channel impurity layer 115. At this time, the channel impurity layer 115 may be formed by selectively implanting impurity ions into only the transistor channel region. In the case where the formed MOSFET is of N-channel type, and it is desired that the threshold voltage (Vth) is set to, for example, about 0.7V, for example, boron ions (B⁺) on the order of 5×10¹² cm⁻² are implanted at an acceleration voltage of 20 KeV, and P-type channel impurity layer 115 is formed so as to form a selectively uniform profile on a region which constitutes a channel. At this step, ions are implanted through the oxide film (not shown). For the activation of the channel impurity layer 115, for example, the RTA processing is then used so that a thermal processing may be conducted for about ten seconds, for example, at 750° C.

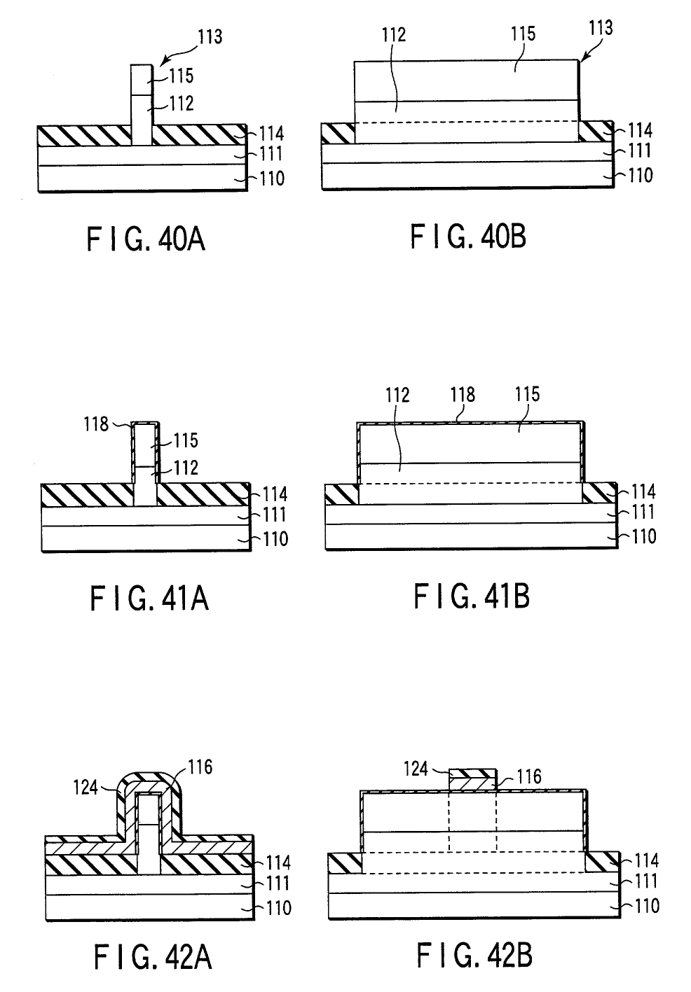

Next, as shown in FIGS. 40A and 40B, the mask layer (SiO₂) 122, and the above oxide film (not shown) are removed, and the mask layer (SiN) 121 is completely removed by using, for example, hot phosphoric acid solution. By doing so, the isolation insulating film (SiO₂) 114 can be allowed to remain on the entire surface of the wafer with a uniform thickness only on the periphery of the lower portion region of the epitaxial Si layer 101.

Next, as shown in FIGS. 41A and 41B, on the upper surface of the fence 113 comprising an epitaxial Si layer and on the surface of the Si layer exposed to the side surface, a gate insulating film 118 is formed. The gate insulating film 118 is formed by subjecting the exposed Si surface to oxidation to about 2.5 nm by using the radical oxidation method at 700° C., for example. The formation of the gate insulating film 118 using this radical oxidation method hardly depends, particularly, on the plane direction of the side surface so that the oxide film having small unevenness on the Si surface can be realized. Thus a MOS transistor having a small reduction in the channel mobility by the scattering of the channel interface can be realized. Furthermore, there is provided a characteristic that only a definite thickness can be formed at a certain temperature by the radical oxidation, so that a dispersion in the thickness of the oxide film can be decreased in the wafer surface of the oxide film and between chips. Needless to say, a so-called “oxinitride film” gate film may be provided in which a normal thermal oxide film is formed by using a heat oxidation method and the surface thereof is subjected to nitrization with gas including nitrogen to provide a SiON film.

Furthermore, as described above by referring to FIG. 25, a so-called high dielectric insulating film such as a Ta₂O₅ (tartan oxide film) film, an Al₂O₃ film, an La₂O₃ film, an HfO₂ film, a ZrO₂ film or the like may be used for the gate insulating film 118. For example, the Si oxide film having a thickness of, about 1 nm is formed on the Si interface, so that the film may be used in a so-called laminated layer gate insulating film structure in which the Ta₂O₅ film is formed thereon.

Next, as shown in FIGS. 42A and 42B, for example, the doped polycrystalline Si film (having a thickness of 50 nm) doped with, for example, N-type impurity which constitutes a gate electrode 116 is deposited and formed on a structure shown in FIGS. 41A and 41B, and for example SiN film which constitutes a gate cap film 124 is deposited and formed thereon to about 50 nm. Next, the resist film (not shown) is used as a mask to etch the gate cap insulating film (SiN) 124. Next, the gate cap insulating film (SiN) 124 is used as a mask to pattern the doped polycrystalline Si film. As a consequence, the gate electrode 116 is formed. At this time, the gate electrode 116 is processed so as to stride over a step of the fence 113. As a consequence, it is important to pattern the doped polycrystalline Si film by using the condition that a ratio (selection ratio) of the etching rate of the gate electrode 116 and the etching rate of the gate insulating film 118 or the isolation film 114 can be set, for example, on the order of 400. An etching damage to the fence 113 can be prevented by using such an etching condition.

Furthermore, in order to lower the resistance of the gate electrode 116, it is possible to use a metal film (a TiN film, a W film, an Al film or the like, or a laminated film thereof), or a laminated gate electrode structure with a metal film such as a polycrystalline Si film, a W film, a TiN film, an Al film, a Cu film or the like or with a silicide film such as a TiSi₂ film instead of the doped polycrystalline Si film.

Furthermore, in the case where TiN or the like is used as a material of the gate electrode 116, it is also possible to adjust the threshold voltage of the MOSFET by using a change in work function of the gate electrode 116 with the adjustment of the orientation or the like.

Besides, the length of the gate electrode 110 (so-called gate length) is set to, for example, about 70 nm. In the present invention, since the short channel effect of the PMOSFET can be suppressed, a design may be made so as to use the same channel length for both the N-channel and PMOSFET.

The following step is not particularly shown. As shown in FIGS. 9A, 9B and thereafter of the first embodiment, the basic structure of the MOSFET is completed with the formation of the source/drain region, the planarization by the CMP after the deposition of the CVD-SiO₂ film on the overall surface thereof, the formation of the contact hole, and furthermore, the formation of the Al wiring layer, and the deposition of the passivation film on the entire surface.

With the double-gate type MOSFET structure in which the fence 113 is formed by using such epitaxial Si layer 101, and preferably a completely depleted channel is provided on both side surfaces of the fence 113, the following effects can be obtained:

(1) Since the width of the fence 113 can be determined with the width of the trench pattern 123, as compared with the case in which the fence 113 is formed by etching, no etching damage is done to the side surface and an yield of the gate insulating film of the side surface is favorable.

(2) A yield in the isolation is improved because the thickness of the isolation insulating film can be formed to have a definite thickness on the periphery of the lower portion region of the fence 113.

(3) A channel width of the MOSFET can be controlled with a depth of the source/drain by separating the source/drain region formed in the fence 113 and the isolation insulating film 114 formed in the lower portion region of the fence.

(4) The channel region 115 can be completely depleted with the gate electrode 116 formed on both sides by narrowing down the width (Wg) of the fence 113 to 0.20 μm or less. The channel region 115 can be completely depleted so that the impurity concentration of the channel region 115 can be lowered as compared with the case of the planar type channel. As a consequence, a reduction in the carrier mobility in the channel region 115 can be suppressed. Furthermore, the channel region is hardly affected by the fluctuation in the impurity concentration. Besides, a structure which is also against the dispersion in thickness of the gate insulating film 118 can be realized.

(5) A punch-through in the MOSFET can be prevented by providing a high concentration impurity layer (punch-through stopper layer) 112 between the channel region 115 of the fence 113 and a well 111 (or the Si substrate 110).

(6) A punch-through between source and drain can be prevented by realizing a configuration such that a distance between the source and drain is short in an upper portion region of the fence 113 and becomes wider toward a lower portion region in the side surface of the fence 113.

(7) In the lower portion region of the fence 113, a configuration extremely different from the prior art is formed in such a manner that a part of the source/drain region 117 is located outside of the gate electrode in s self-aligning manner. A punch-through can be effectively prevented in a lower portion region of the fence 113 by providing an offset structure in which a part of the source/drain region 117 and the gate electrode 116 are offset to each other.

(8) In a transistor structure having the fence 113, a so-called high dielectric insulating film such as a Ta₂O₅ film can be used for the gate insulating film 118. Then, since the transistor has the fence 113 and the gate electrode 116 on both side surfaces of the fence 113 so that the cut-off characteristic of the transistor can be more effectively improved.

(Seventeenth Embodiment)

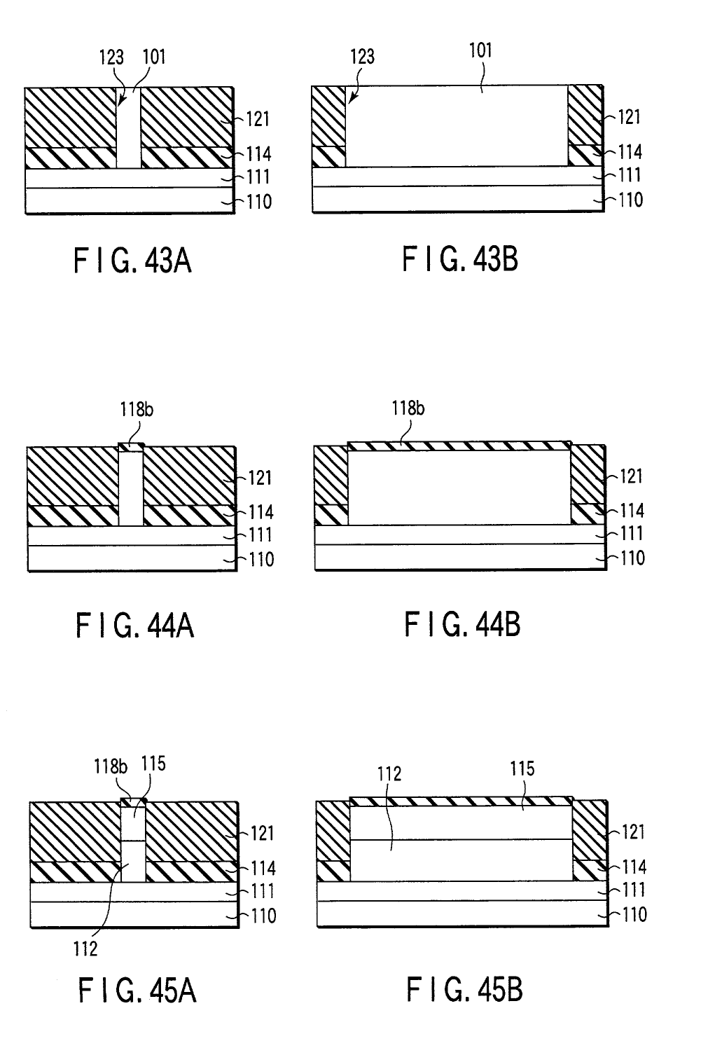

FIGS. 43A through 47A and FIGS. 43B through 47B are sectional views showing a method for manufacturing a MOSFET according to a seventeenth embodiment of the present invention. Incidentally, the cross sections shown in FIGS. 43A through 47A correspond to the cross section shown in FIG. 2B. The cross sections shown in FIGS. 43B through 47B correspond to the cross section shown in FIG. 2C.

In the sixteenth embodiment, there is explained a manufacturing method in which a fence 113 is formed and a double-gate type MOSFET having a completely depleted channel is formed by using the epitaxial Si layer 101.

In the seventeenth embodiment, the epitaxial Si layer 101 is used to form the fence 113. There will be explained a method for forming a gate insulating film 118b having a thickness different from the side surface on the upper surface of the fence 113.

In the beginning, as shown in FIGS. 43A and 43B, in the case where the NMOSFET is formed on a transistor channel region of the P-type Si substrate 110 in the plane direction (100) having an impurity concentration of 5×10¹⁵ cm⁻³, the P-type well 111 (having a peak impurity concentration of, for example, about 4×10¹³ cm⁻²) is formed by implanting ions at an acceleration voltage of 260 KeV and a dose amount of 2×10¹⁷ cm⁻³. Furthermore, in the case where the P-type MOSFET is formed, an N well (not shown) is formed. Next, a SiO2 film 114 which later becomes a isolation film is formed to a thickness of, for example, about 100 nm on the entire surface above the Si substrate 110. Next, a mask layer (SiN) 121 which becomes a main material in the case where the epitaxial Si layer is grown is formed to a thickness of, for example, about 250 nm. Next, for example, a normal resist film (not shown) and the RIE method are used to form a desired pattern on these laminated layers. In this example, a trench pattern 123 is formed for forming the fence 113 formed of an epitaxial layer. After this, in consideration of the epitaxial growth of Si which is conducted at the next step, a step may be conducted for removing the etching damage at the time of RIE, the organic contamination layer and the like from the surface of the Si substrate 110 exposed from the trench pattern 123. Next, after the natural oxide film or the like is removed from the surface of the Si substrate 110 exposed from the trench pattern 123, Si is epitaxially grown to form the epitaxial Si layer 101. The thickness thereof is set so that the inside of the trench pattern is completely embedded. One concrete example of the thickness is about 400 nm. Next, the surface of the epitaxial Si layer is subjected to CMP to remove the epitaxial Si layer which is protruded out of the trench. As a consequence, the unevenness on the surface of the epitaxial Si layer 101 is removed. By doing so, a facet or the like of the epitaxial Si layer 101 formed in the trench pattern 123 can be removed with the result that the epitaxial Si layer can be precisely formed. Attention is paid to the growth temperature, the atmosphere, the pretreatment or the like at the epitaxial growth. It is important to prevent the formation of the crystal defect or the like on an interface between the epitaxial Si layer 101 and the Si substrate 110.

Next, as shown in FIGS. 44A and 44B, on the surface of the exposed epitaxial Si layer 110, the gate insulating film (TOP insulating film) 118b is formed, for example, to about 20 nm. At this time, when the heat oxidation method is used, the gate insulating film (TOP insulating film) 118b can be selectively formed only on the surface of the exposed epitaxial Si layer 101 because the mask layer (SiN) 121 is present.

Next, as shown in FIGS. 45A and 45B, the resist film (not shown) is used as a mask to implant, for example, boron ions (B⁺) into a region including at least a transistor channel formation region in the epitaxial Si layer 101, thus a high concentration impurity layer 112 having an impurity concentration of about 8×10¹⁷ cm⁻³ at the peak concentration is formed. This high concentration impurity layer 112 functions as a punch-through stopper layer. For the activation of ions implanted at this time, the RTA treatment is used for five minutes, for example, at 900° C. in the atmosphere of nitrogen (N₂). As a consequence, a P-type high concentration impurity layer 112 which has a steep profile is formed. Furthermore, for example, in a region including a transistor channel region, the resist film (not shown) is used as a mask to implant impurity ions having a desired conductive type so that the channel impurity layer 115 is formed. At this time, the channel impurity layer 115 may be formed by selectively implanting impurity ions into only the transistor channel region. In the case where the MOSFET to be formed is of N-type channel, and it is desired that the threshold voltage (Vth) thereof is set to, for example, about 0.4V, for example, boron ions (B⁺) are implanted at an acceleration voltage of 20 KeV and to about 3×10¹² cm⁻² so that the P-type channel impurity layer 115 is selectively formed so that a selectively uniform profile can be provided. The activation of the channel impurity layer 115 may be conducted with heat treatment at, for example, 750° C. and for ten seconds by using, for example, the RTA treatment.

Incidentally, in this example, there is shown a case in which ion implantation for obtaining the P-type channel impurity layer 115 is conducted through the gate insulating film (TOP insulating film) 118b. However, in the beginning, sacrificed oxide film having a thickness of about 8 nm is formed on the surface of the epitaxial Si layer 101. After ions are implanted through this sacrificed oxide film, the sacrificed oxide film is pealed off and a gate insulating film (TOP insulating film) 118b may be formed newly on the epitaxial Si layer 101. In this manner, by conducting the ion implantation through the sacrificed oxide film, it is possible to prevent the metal contamination or the like to the epitaxial Si layer 101 from the resist film at the time of ion implantation by using the resist film as a mask.

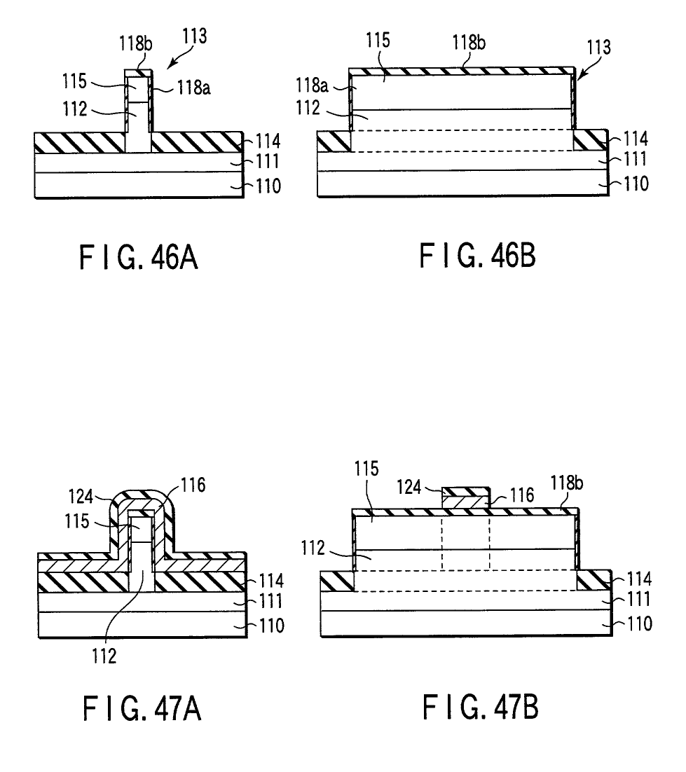

Next, as shown in FIGS. 46A and 46B, the mask layer (SiN) 121 is completely removed by using, for example, hot fluoric acid solution. By doing so, the isolation insulating film (SiO₂) 114 can be allowed to remain on the entire surface of the wafer in a uniform thickness only on the periphery of the lower portion region of the epitaxial Si layer 101. Next, a gate insulating film 118 is formed on an upper surface of the fence 113 comprising the epitaxial Si layer and the surface of the Si layer exposed to the side surface thereof. The gate insulating film 118 is formed by the oxidation of, for example, the exposed Si surface to about 2.5 nm by means of the radical oxide method at, for example, about 700° C. Since the formation of the gate insulating film 118 using this radical oxide film, hardly depends, in particular, on the plane direction of the side surface so that the oxide film having a small unevenness on the Si surface can be realized. Thus, a MOS transistor with a small reduction in the channel mobility by the scattering of the channel interface. Furthermore, there is a characteristic that in the radical oxidation, the thickness of the oxide film can be formed only to a definite thickness at a certain temperature, so that a dispersion in the thickness of the oxide film can be decreased in the wafer surface of the oxide film and between chips. Needless to say, the “oxinitride film” gate insulating film may be used in which a normal heat oxide film is formed by using the heat oxide method and the surface thereof is subjected to nitrization with gas including nitrogen.

Furthermore, as described above by referring to FIG. 25, so-called high dielectric insulating film such as Ta₂O₅ (tartan oxide film) film, a HfO₂ film, and a ZrO₂ film may be used for the gate insulating film. For example, a so-called laminated layer gate insulating film structure may be used for forming a Si oxide film having a thickness of about 1 nm, and then forming a Ta₂O₅ film thereon.

Next, as shown in FIGS. 47A and 47B, a doped polycrystalline Si film (having a thickness of about 80 nm) doped with, for example, the N-type impurity which becomes the gate electrode 116 is deposited and formed on a structure shown in FIGS. 41A and 41B, so that, for example, an SiN film which constitutes a gate cap film 124 thereon is deposited and formed to about 50 nm. Next, the resist film (not shown) is used as a mask to etch the gate cap insulating film (SiN). Next, the gate cap insulating film (SiN) 124 is used as a mask to pattern the doped polycrystalline Si film. As a consequence, the gate electrode film 116 is formed. At this time, the gate electrode 116 is processed so as to stride over the step of the fence 113. Consequently, it is important to pattern the doped polycrystalline Si film by using a condition such that a ratio (selection ratio) of the etching rate of the gate electrode 116 and the etching rate of the gate insulating film 118 or the isolation film 114 can be sufficiently taken, for example, about 400. By using such a condition, it is possible to prevent the etching damage caused to the fence 113.

Furthermore, in order to lower the resistance of the gate electrode 116, it is possible to use a metal film (a TiN film, a W film, an Al film and a laminated layer thereof), or a laminated gate electrode structure of a polycrystalline Si film and a metal film such as a W film, a TiN film, an Al film and a Cu film, or a silicide film such as a TiSi₂ film instead of the doped polycrystalline Si film.

Furthermore, in the case where the gate electrode is made of TiN or the like, it is possible to adjust the threshold voltage of the MOSFET by using a change in the work function of the gate electrode 16 by adjusting the orientation thereof.

In addition, the length of the gate electrode (so-called gate length) is set to, for example, about 50 to 70 nm. In the present invention, though described in detail, since the short channel effect of the PMOSFET can be suppressed so that design can be made in such a manner that the same length may be used both for the N-channel and the PMOSFET.

With such a structure, in the channel region 115 of the three surfaces (an upper surface, and both side surfaces) of the fence 113, since the thickness of the gate insulating film (TOP film) 118b formed on an upper surface is larger than the thickness of the gate insulating film 118a formed on both side surfaces, the influence of the concentration of the gate electric field at the top corner can be decreased. Consequently, the threshold voltage can be set in a high precision, and a change in the threshold voltage at the time of the application of the substrate bias characteristic, namely the substrate bias can be suppressed.

(Eighteenth Embodiment)

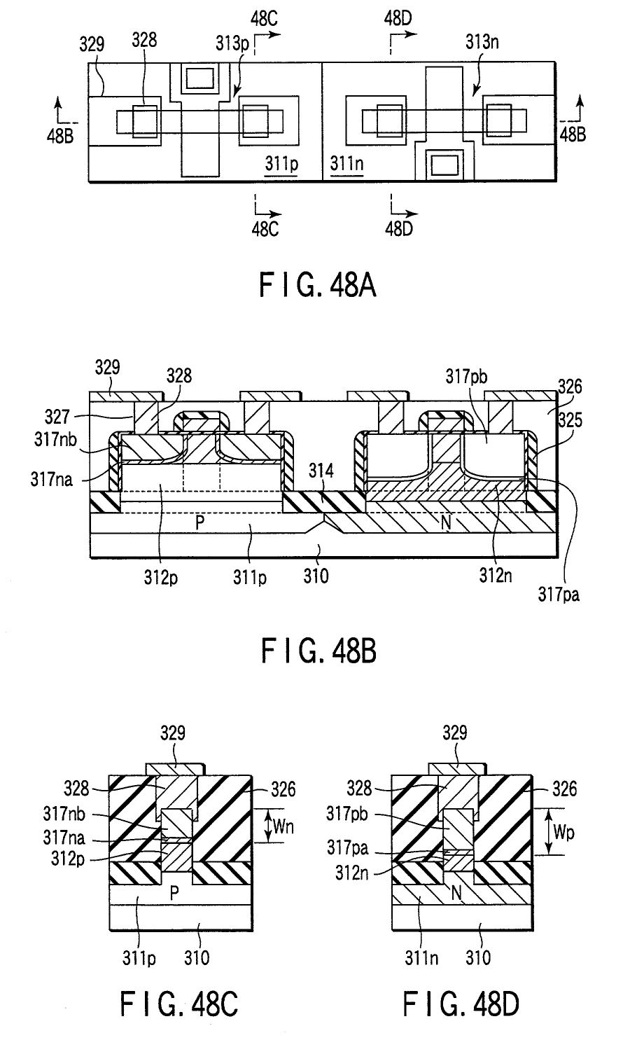

FIG. 48A is a plan view showing a complementary MOSFET according to an eighteenth embodiment of the present invention. FIG. 48B is a sectional view taken along the line 48B-48B of FIG. 48A. FIG. 48C is a sectional view taken along the line 48C-48C. FIG. 48D is a sectional view taken along the line 48D-48D of FIG. 48A.

Hereinafter, the eighteenth embodiment will be explained along with a method for manufacturing the same.

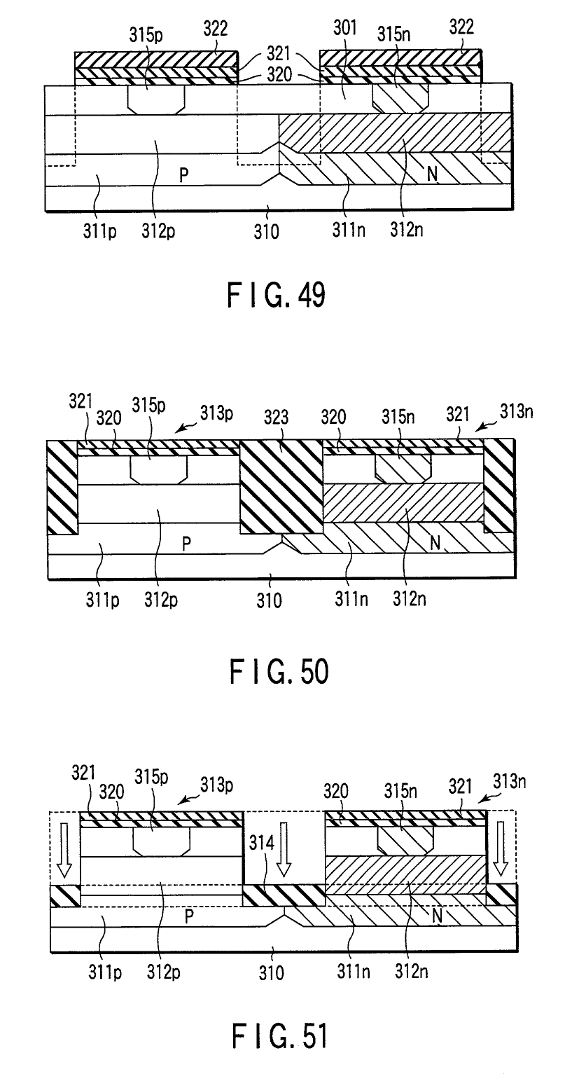

FIGS. 49 to 54 are sectional views showing the complementary MOSFET according to the eighteenth embodiment for each step of the main manufacturing process. Incidentally, the cross sections shown in FIGS. 49 to 54 corresponds to the cross section shown in FIG. 48.

In the beginning, as shown in FIG. 49, a resist film (not shown) is used as a mask in the NMOSFET formation region of the P-type Si substrate 310 on the plane direction (100) having an impurity concentration of 5×10¹⁵ cm⁻³ to implant, for example, boron ions (B⁺) at an acceleration voltage of 200 KeV and a dose amount of 2×10¹³ cm⁻² to form a P-type well 311p (for example, 4×10¹⁷ cm⁻³ at the peak impurity concentration).

Next, a resist film (not shown) is used as a mask to implant, for example, boron ions (B⁺) to a region including at least N-channel transistor channel formation region in the P-type well 311p thereby forming a P-type high concentration impurity layer 312p having an impurity concentration of about 8×10¹⁷ cm⁻³ at the peak concentration. The P-type high concentration impurity layer 312p functions as a punch-through stopper layer.

Next, a resist film (not shown) is used as a mask to implant, for example, phosphorus ions (P⁺) at an acceleration voltage of 600 KeV, and in a dose amount of 2.5×10¹³ cm⁻³ to a PMOSFET formation region (PMOSFET region) of the P-type Si substrate 310 thereby forming an N-type well 311n (on the order of, for example, 5×10¹⁷ cm⁻³ at the peak impurity concentration).

Next, a resist film (not shown) is used as a mask to implant, for example, phosphorus ions (P⁺) at an acceleration voltage of about 130 KeV and in a dose amount of 2×10¹³ cm⁻² to a region including at least P-channel transistor channel formation region in the N-type well 311n thereby forming an N-type high concentration impurity layer 312n having an impurity concentration of 9×10¹⁷ cm⁻³ at the peak concentration. The N-type high concentration impurity layer 312n functions as a punch-through stopper layer.

At the time of implantation of these ions, an oxide film having a thickness of about 8 nm is formed on the surface of the P-type Si substrate 310. By doing so, the contamination of the P-type Si substrate 310 from the resist film (not shown), for example, the metal contamination can be prevented. Furthermore, for the activation of the implanted ions, the RTA treatment is used for about five minutes at 900° C. in the atmosphere of nitrogen (N₂). As a consequence, high concentration layers 312p and 312n having a steep profile can be formed.

Furthermore, on the entire surface, a P-type of an epitaxial Si layer 301 having an impurity concentration on the order of 10¹⁵ cm⁻³ is formed to a thickness of about 200 nm.

Furthermore, for example, the resist film (not shown) is used as a mask to implant impurity ions having a desired conductive type to, for example, a region including a transistor P-type channel formation region, and an N-type channel formation region to form an N-type channel impurity layer 315n and a P-type channel impurity layer 315p. At this time, the channel impurity layer 315n, and the P-type channel impurity layer 315p may be formed by selectively implanting impurity ions into the transistor P-type channel formation region and the N-type channel. In this example, the latter structure is adopted. In the cross section shown in FIG. 49, the LOCAL channel region (a P-type layer) 315p and the LOCAL channel region (N-type layer) 315n which are respectively selectively formed are shown.

In the case where the MOSFET to be formed is of an N-type channel and it is desired to set the threshold voltage (Vth) to, for example, about 0.4V, for example, boron fluoride ions (BF₂⁺) are implanted at an acceleration voltage of 15 KeV and in a dose amount of 3×10¹² cm⁻² so that the P-type LOCAL channel region 3115p is formed so that a uniform profile is selectively provided in a region which constitutes a channel.

In the same manner, in the case where the MOSFET to be formed is of P-channel type, and it is desired to set the threshold voltage (Vth) to, for example, −0.4V, for example, phosphorus ions (P⁺) are implanted at an acceleration voltage of 100 KeV and in a dose amount of 2×10¹³ cm⁻² to form the N-type LOCAL channel region 315n on a region which constitutes a channel to selectively provide a uniform profile. At these steps, ions are implanted through an oxide film (not shown). These channel regions 315p and 315n may be activated by using, for example, the RTA treatment in heat treatment, for example, at 750° C. for about 10 seconds.

Next, the above oxide film (not shown) is removed, a SiO2 layer 320 having a thickness of about 5 nm, a mask layer (SiN) film 321 having a thickness of about 20 nm, and a mask layer (SiO₂) layer 322 having a thickness of about 20 nm are formed again on the entire surface, and are processed to a desired configuration, for example, a configuration which constitutes a device region of the NMOSFET and PMOSFET respectively. A dot line in FIG. 49 shows a region which is etched and removed at the subsequent steps.

Next, as shown in FIG. 50, a structure shown in FIG. 49 is used in which the mask layer 322 is used as an etching mask to etch, and fences 313p and 313n which constitute a source, a drain, and a channel, respectively are formed. The height of these fences 313p and 313n are on the order of, for example, 250 nm. In this manner, a structure shown in FIG. 49 is etched until a part of the P-type well 311p in the Si substrate 310 and a part of the N-type well 311n are attained so that a trench having a depth on the order of 250 nm is formed. As a consequence, the fences 313p and 313n are respectively formed. Next, the side surfaces of the fences 313p and 313n or the bottom of the trench are cleaned by using the ashing, the wet processing or the like while removing the Si layer damaged with the RIE. As a consequence, an Si surface which is damaged a little is exposed on the side surfaces of the fences 313p and 313n or the bottom of the trench. Next, an oxide film (not shown) is formed on the side surfaces of the fences 313p and 313 n or the bottom of the trench for the purpose of making the interface characteristic better. For the formation of this oxide film, an oxide film with good quality can be formed at a low temperature (for example, about 700° C.). It is desirable to use the radical oxidation method using oxygen radical. In this manner, the radical oxidation method is used to form an oxide film (not shown) having a thickness of about 7 nm on the side surfaces of the fences 313p and 313n or the bottom of the trench.

Next, via the oxide film, the trench is embedded with, the insulating film, for example, SiO2, preferably, TEOS-SiO₂ layer 323. A so-called trench-type isolation layer (STI) is formed. For this purpose, after the TEOS-SiO₂ layer 323 is deposited and formed by using the CVD method at a film formation temperature of about 650° C., the TEOS-SiO₂ film 323 is subjected to densification of the CVD oxide film in the atmosphere of the radical oxidation, for example, at a temperature of 650° C. After this, the surface of the TEOS-SiO₂ layer 323 is planarized by using the CMP method. At this time, the TEOS-SiO₂ film 323 is embedded up to the surface of the SiN film 321. As a consequence, the trench is embedded in a planar manner with the TEOS-SiO₂ layer.

Next, as shown in FIG. 51, the TEOS SiO₂ layer 323 is etched back by using, for example, the RIE method with the result that a isolation insulating film 314 for isolation is formed which has a thickness of, for example, about 100 nm.

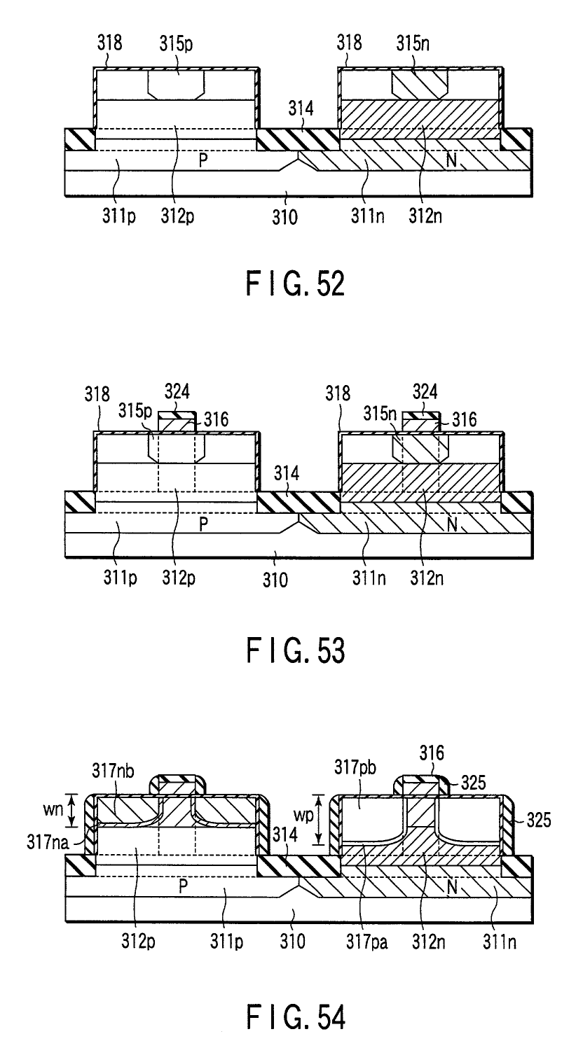

Next, as shown in FIG. 52, the mask layer (SiN) 321 is wet removed by using, for example, a hot phosphorus or the like. Next, the oxide film (not shown) formed on the side surface of the trench and the SiO₂ layer 320 are pealed off by using a fluoric acid or the like to expose the Si surface from the upper surface of the fences 313p and 313n and the side surfaces thereof. Next, a gate insulating film 318 is formed having a thickness of about 2.5 nm by using the radical oxidation method at a temperature of, for example, 700° C. Since the formation of the gate insulating film 318 using the radical oxidation method depends particularly on the plane direction of the side surface, and an oxide film with small unevenness can be realized with the result that a MOS transistor with a small reduction in channel mobility by the scattering of the interface scattering can be realized. Furthermore, there is a characteristic that since the radical oxidation can be formed only in a definite thickness at a certain temperature, a dispersion in the thickness of the oxide film in a wafer surface of the oxide film and between chips can be reduced. Needless to say, for the gate insulating film 318, a so-called “oxinitride film” gate insulating film may be used in which a normal oxide film is formed by using a heat oxidation method and the surface thereof is subjected to nitrization with gas including nitrogen.

Furthermore, as shown in FIG. 25, for example, the gate insulating film 18 is not limited to the SiO₂ film. A so-called dielectric insulating film (high-K film) such as a Ta₂O₅ (tantalum oxide) film, a HfO₂ film, a ZrO₂ film or the like may be used. Furthermore, in the case where the Ta₂O₅ film is used, in order to decrease the interface level density with the Si interface, a so-called laminated film gate insulating film structure may be used in which for example, a Si oxide film type film having a thickness of about, for example 1 nm is formed and then the Ta₂O₅ film is formed thereon.

Next, as shown in FIG. 53, a gate electrode 316 is provided. For example, a doped polycrystalline Si film (having a thickness of about 50 nm) doped with an N-type impurity is deposited and formed on a structure shown in FIG. 52, and a gate cap insulating film 324 is formed thereon. For example, the SiN film is deposited and formed to about 100 nm. Next, a resist film (not shown) is used as a mask to etch the gate cap insulating film (SiN) 324 followed by using the gate cap insulating film (SiN) 324 as a mask to pattern the doped polycrystalline Si film. As a consequence, a gate electrode 316 is formed. At this time, the gate electrode 316 is processed so as to stride over the step of the fence 313. Consequently, it is important to pattern the doped polycrystalline Si film by using a condition such that the ratio (selection ratio) of the etching rate of the gate electrode 316 and the etching rate of the gate insulating film 318 can be sufficiently taken, for example, on the order of 400. The etching damage caused to the fences 313p and 313n respectively can be prevented by using such etching condition. Furthermore, in order to lower the resistance of the gate electrode 316, it is possible to use a metal film (a TiN film, a W film, an Al film and the like, or a laminated film thereof), or a laminated gate electrode structure of a polycrystalline Si film with a metal film such as a W film, an TiN film, an Al film, and a Cu film and a silicide film such as TiSi₂ film. Furthermore, in the case where the gate electrode 316 is made of TiN or the like, the orientation thereof is adjusted so that the threshold voltage of the MOSFET can be adjusted by using a change in the work function of the gate electrode 16.

In the case of the CMOS structure as in this example, it is possible to use an N⁺ type polycrystalline Si layer gate electrode as an N channel and P⁺ type polycrystalline Si layer gate electrode as an electrode interface layer.

Furthermore, the length of the gate electrode 316 (so-called gate length) is set, for example, about 70 nm. In the present invention, since the short channel effect of the PMOSFET can be suppressed, it is possible to design the N channel and the PMOSFET to have the same channel length.

Next, as shown in FIG. 54, with the ion implantation method in which the resist film (not shown), the gate cap insulating film 324, and the gate lectrode 316 are used as a mask, a P-type source/drain region 317p and an N-type source/drain region 317n are respectively formed. At this time, in order to alleviate the concentration of electric field on the side-wall of the gate electrode 316 and at the corner of the bottom portion, the gate electrode 316 is oxidized by using, for example, the radical oxidation method, or the low temperature RTO method so that an oxide film (not shown) having a thickness of, for example, about 2 nm may be formed.

Furthermore, the depth (Xj) control of the source/drain regions 317p and 317n is an important step for determining the channel width of the transistor. In particular, it is necessary to pay attention to the temperature setting of the heat treatment including the activation of the impurity of the source/drain regions 317p and 317n.

In this example, for this purpose, after the N⁻ type diffusion layer 317na and a P⁻ type diffusion layer 317pa are formed by using the gate electrode 316 as a mask, the insulating film (a SiO2 film or an SiN film) is deposited on the entire surface by the CVD method. Furthermore, the ion implantation condition at the time of the formation of the N⁻ type diffusion layer 317n is such that, for example, the implantation of phosphorus ions (P⁺) is conducted at an acceleration voltage of 40 KeV and in a dose amount of 4×10¹³ cm⁻². Naturally, arsenic ions (As) ions or the like may be implanted. After this, the entire surface is subjected to the RIE, a side-wall insulating film 325 is formed on the side-wall of the pattern of the gate electrode 316, and on the side-wall of the fences 313p and 313n. After this, for example, arsenic (As⁺) ions are implanted at an acceleration voltage of 20 KeV, and in a dose amount of 5×10¹⁵ cm⁻² to form an N-type source/drain region (N⁺ type diffusion layer). Furthermore, boron fluoride (BF₂⁺) ions are implanted to form the P-type source/drain region (P⁺-type diffusion layer) 317nb. As a consequence, source/drain regions 317p and 317n having a so-called gate extension structure as shown in FIG. 29D can be provided respectively. Naturally, a single source/drain region structure can be also employed.

The depth (Win) of the N-type source/drain region 317n and a depth (We) of the P-type source/drain region 317p are controlled with the thermal activation and the heat treatment condition after the final formation of the ion implantation layer. For example, the respective ion implantation conditions (acceleration voltage and dose amount) and the thermal treatment condition can be controlled and realized so that, for example, the depth of the N-type junction (Win)=0.15 μm can be realized and, furthermore, the depth (We) of the P-type junction is set to about 0.20 μm.

Furthermore, in the case where it is required to lower the specific ratio of the source/drain regions 317n and 317p, a silicide layer (not shown) such as TiSi₂ and CoSi₂, PtSi, Pd₂Si, IrSi₃, RhSi or the like may be formed on the surface of the source/drain regions 317n and 317p if the resistance is lowered to, for example, about 50 μΩ or less. In particular, in the P-type source/drain region 317p, Pd₂Si is effective.

In this embodiment, an offset region is present which is offset with the gate electrode 316 on a lower portion of the N-type source/drain region 317n on the side surface of the fence 313p and on a lower portion of the P-type source/drain region 317p on the side surface of the fence 313n. This is because the source/drain regions 317n and 317a are formed with the ion implantation method from the surface and heat diffusion. It is so constituted that a punch-through in the lower portion region of the source/drain regions 317n and 317p can be prevented with the presence of the offset region and the ion implantation layer (punch-through stopper layer 312) for the prevention of the punch-through.

Furthermore, in this embodiment, since the respective side surfaces of the fences 313n and 313p are covered with the side-wall insulating film 325, a structure is provided in which ion implantation to the respective upper surfaces of the fences 313n and 313p at the time of ion implantation for the formation of the source/drain regions 317n and 317p is mainly conducted and ion implantation of impurity to the side surface can be prevented.

Next, as shown in FIGS. 48A through 48D, SiO₂ is deposited to about 500 nm on the structure shown in FIG. 54 to form an interlayer insulating film 326 by the CVD method. After this, the interlayer insulating film 326 is subjected to densification for, for example, about 30 minutes in the atmosphere of the radical oxidation, for example, at 700° C. This heat step may be also conducted also as the activation of the ion implantation layer of the source/drain region 317n and 317p. When it is desired that the depths (Win and We) of these source/drain regions 317n and 317p are controlled, the densification temperature is lowered. Alternatively, the RTA treatment on the order of msec (millisecond), for example, at 850° C. may be conducted. Furthermore, the ion implantation layer of the source/drain regions 317n and 317p may be activated by using together the above methods. After this, the interlayer insulating film 326 is planarized by using the CVP method and the surface of the device is planarized. Next, the resist film (not shown) and the RIE method are used to form a contact hole 327, and a W (tungsten) film, an Al (aluminum) film, a TiN film (titanium nitride) film/Ti (titanium) film and a laminated layer thereof are embedded in the contact hole 327 to form a contact plug 328. An Al wiring layer 329 is formed. Furthermore, a passivation film (not shown) is deposited on the entire surface so that a basic structure of a complementary MOSFET according to the eighteenth embodiment of this invention is completed.

In this manner, the present invention can be applied to the complementary MOSFET. As a consequence, various CMOS circuits can be constituted by changing an inverter circuit and a wiring.

Furthermore, in particular, as shown in FIGS. 48A through 48D, although the NMOSFET and PMOSFET have the same planar design area, the depth (Win) of the N-type source/drain region 317n and the depth (We) of the P-type source/drain region 317p are different from each other. This shows that the MOSFET can be realized which has different channel widths of the N channel and the P channel even though the planar design area is the same.

In the case where the conventional CMOS circuit is designed, the planar design area of the PMOSFET is designed to be approximately twice as large as that of the NMOSFET. This is intended to suppress a dispersion in the drive performance resulting from a difference between the electron mobility and a hole mobility.

However, when a CMOS having the fence of the present invention is used, a channel width can be changed by using a difference between the Win and We with the result that a difference between a planar area of the NMOSFET and a planar area of PMOSFET can be reduced. This is an important characteristic of the eighteenth embodiment of the present invention.

In the eighteenth embodiment,

(1) both the P-type LOCAL channel region 315p and the N-type LOCAL channel region 315n can be completely depleted with the gate electrode 316 formed on both side surfaces of these fences 313p and 313 by narrowing the width (Wg) of the fences 313p and 313n to, for example, 0.20 μm or less. An impurity concentration of these channel regions 315p and 315n can be lowered as compared with a case of the planar type channel. As a consequence, a reduction in the carrier mobility in these channel regions 315p and 315n can be suppressed. Furthermore, the embodiment is hardly affected by the fluctuation of the impurity concentration. Furthermore, a structure against a dispersion in the thickness of the gate insulating film 318 can be realized.

(2) A high concentration impurity layer (punch-through stopper layer) 312 is provided between the channel regions 315p and 315n of the fences 313p and 313n and the wells 311p and 311n (or the Si substrate 310) to prevent a punch-through of the MOSFET.

(3) In a lower portion region of the fences 313p and 313n, a configuration extremely different from the prior art is formed in which a part of the source/drain regions 317p and 317n is located outside of the gate electrode 316 in a self-aligning manner. A punch-through can be effectively prevented in a lower portion region of the fences 313p and 31n by providing an offset structure in which the gate electrode 316 and a part of the source/drain regions 317p and 317n are offset to each other,

(4) In the case where a contact is formed in the source/drain regions 317p and 317n in the fences 313p and 313n, a contact can be formed by using not only an upper surface of the fences 313p and 313n but also a part of the side surface thereof. That is because the fences 313p and 313n which serve as the source/drain regions 317p and 317n are many times deeper than the depth of the source/drain region of the MOSFET having the same gate length. A contact resistance with a finer MOSFET can be decreased with a contact structure to such source/drain.

(5) In the transistor having the fences 313p and 313n, source/drain regions 317a and 317n may be formed into a structure having so-called LDD-like high concentration source/drain regions 317pb and 317nb and low concentration source/drain regions 317pa and 317na, not limited to the single source/drain structure. By doing so, the electric field in the vicinity of the source/drain regions 317p and 317n can be alleviated and the reliability of the MOSFET can be improved.

(6) In the case where the CMOS circuit is formed by using the NMOSFET formed on the fence 313p and the PMOSFET formed on the fence 313n, the depth (Win) of the P-type source/drain region 317p and the depth (We) of the P-type source/drain region 317n are made different. It is possible to shorten a difference in a planar design size between the PMOSFET and the NMOSFET resulting from a difference between a mobility of electrons and a mobility of positive holes by making the depth (Win) and the depth (We) different.

Specifically, the depth (We) of the P-type source/drain region 317p is made deeper than the depth (Win) of the N-type source/drain region 317n. Therefore, the channel width of the PMOSFET can be larger than that of the NMOSFET even when the planar design sizes are the same wi the each other. As a consequence, when the CMOS circuit is designed, the area of the PMOSFET is decreased and the whole circuit area can be decreased.

(7) The depth of the P-type source/drain region 317p are mutually changed by using the MOSFET formed on the fences 313p and 313n. Furthermore, the depth of the N-type source/drain regions are mutually changed. Consequently, a MOSFET having a different channel width can be realized even when the planar design size is the same. By doing so, the area of the MOSFET can be reduced when the circuit is designed and the whole circuit area can be reduced.

(Nineteenth Embodiment)

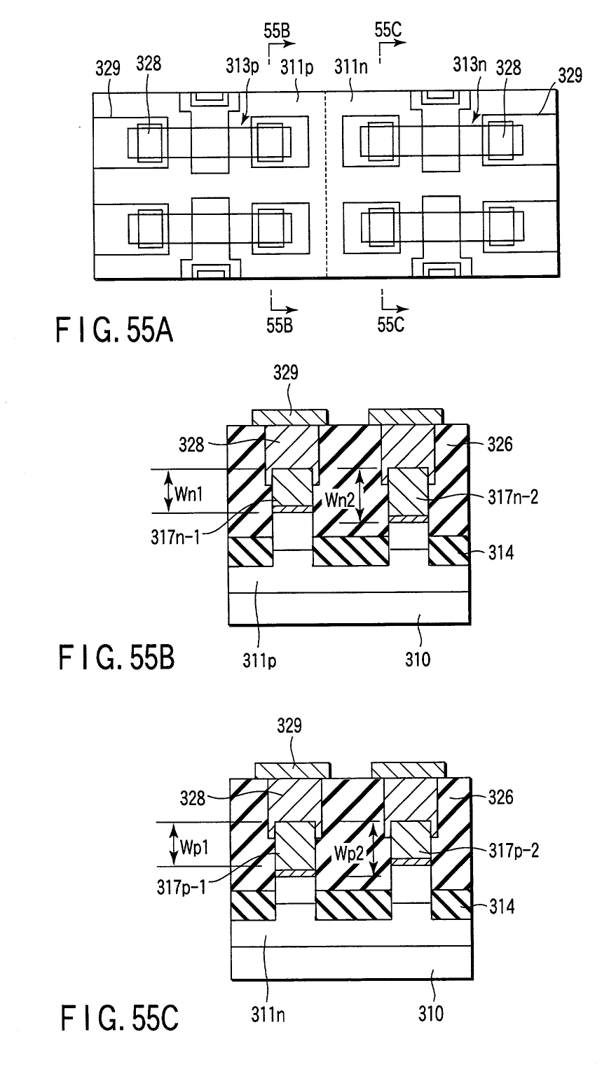

FIG. 55A is a plan view showing a complementary MOSFET according to a nineteenth embodiment of the present invention. FIG. 55B is a sectional view taken along the line 55B-55B of FIG. 55A. FIG. 55C is a sectional view taken along the line 55C-55C of FIG. 55A.

In the eighteenth embodiment, there is shown a case in which the depth (Win) of the N-type source/drain region 317n of the NMOSFET and the depth (We) of the P-type source/drain region 317p of the PMOSFET are made different from each other.

In the nineteenth embodiment, there is shown a case in which the depth Wn1, Wn2, . . . , Wnn of the N-type source/drain regions 317n-1, 317n-2, . . . , 317n-n and the depth Wp1, Wp2, . . . Wpn of the P-type source/drain region 317p-1, 317p-2, . . . 317p-n are made different from each other.

FIGS. 55A through 55C show a case of two mutually different source/drain regions (corresponding to the channel width). It is apparent that the invention can be applied to a case having a plurality of n depths.

In this manner, a degree of freedom increases for NMOSFET and PMOSFET having different channel width increases by realizing channel widths of a plurality of N channels and P channels. It becomes possible to select from a viewpoint of the design and the manufacture as to whether a plurality of channel widths are realized with the number of the fence 313n or 313p or with the a plurality of channel widths. This is a large characteristic of the embodiment.

(Twentieth Embodiment)

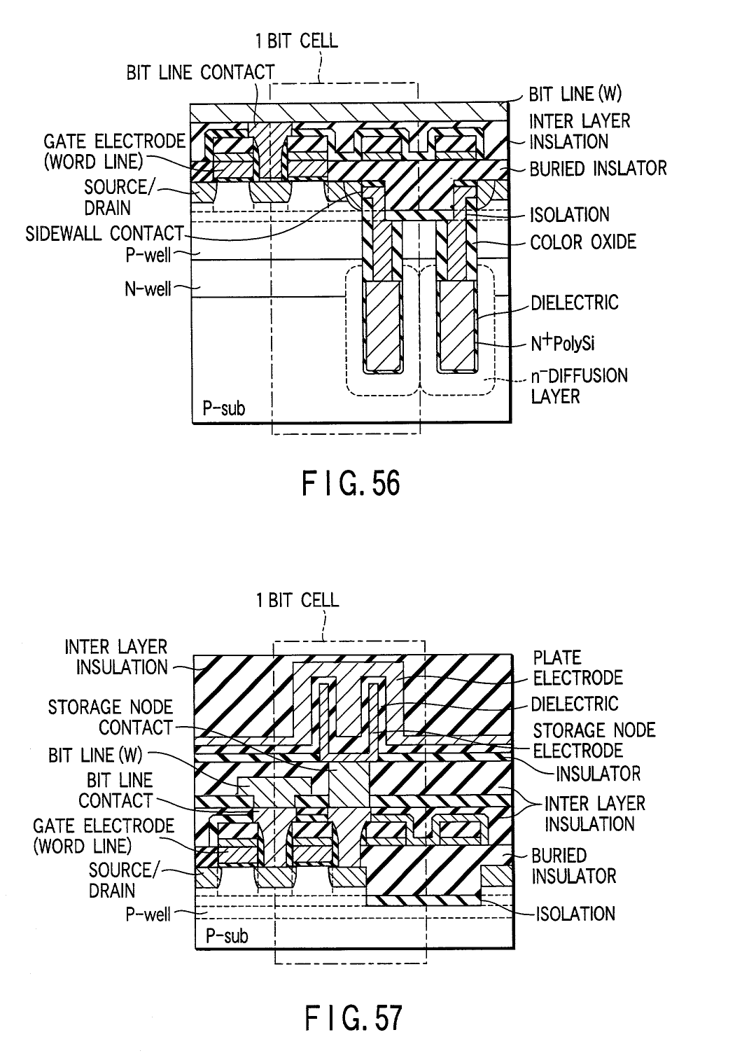

FIG. 56 is a sectional view showing a DRAM memory cell having a trench type capacitor structure according to a twentieth embodiment of the present invention. Incidentally, in FIG. 56, a region surrounded with a dot line corresponds to one bit DRAM memory cell.

The twentieth embodiment is an example in which the MOSFET explained, for example, in the first embodiment is used in a transfer transistor for mutually connecting a trench type capacitor and a bit line of the DRAM memory cell.

As shown in FIG. 56, the accumulation electrode of the capacitor on the upper side surface of the trench and the source/drain regions are electrically connected. In the conventional planar type MOSFET structure, this side-wall contact region becomes a vertically deep source/drain to hinder the thinning of the source/drain of the planar MOSFET source/drain.

When the MOSFET according to the present invention is used like the twentieth embodiment, even when a diffusion layer from the side-wall contact exerts an influence upon the source/drain region of the MOSFET, and the depth of the source and the drain becomes deeper, the influence can be sufficiently suppressed with the gate electrode formed on the side-wall of the fence. That is, there is provided a structure in which a short channel effect can be suppressed with the extension of the diffusion layer from the side-wall contact. At this time, in order to realize the pass word line, the first gate electrode including the normal side-wall is made of polysilicon Si layer, a structure is desirable in which the first gate electrode and a pass word line are connected with a different second gate electrode. Furthermore, a configuration is preferable in which the insulating film is embedded between the first gate electrodes. By doing so, a MOSFET structure using the fence can be applied to a DRAM transistor.

(Twenty-First Embodiment)

FIG. 57 is a sectional view showing a DRAM cell having a stacked type capacitor structure according to a twenty-first embodiment of the present invention. Incidentally, in FIG. 57 a region surrounded with a dot line corresponds to a one bit DRAM memory cell.

The twenty-first embodiment is an example in which a MOSFET explained in the first embodiment is used in a transfer transistor for mutually connecting the stacked type capacitor and the bit line of the DRAM memory cell.

As shown in FIG. 57, the embodiment is characterized in that the bit line contact and the accumulated electrode contact are raised to an upper portion of the gate electrode and formed by using polysilicon. In the conventional planar type MOSFET structure, it is difficult to sufficiently lower the contact resistance in a fine contact region. When the fence structure MOSFET according to the present invention is used, a contact resistance can be lowered because the contact can be formed by using a planar surface portion and a side surface portion. Furthermore, in the case of stacked capacitor in which a high dielectric insulating film such as a Ta₂O₅ film, a BST film, a STO film or the like is used, the MOSFET is formed followed by forming a capacitor. There is a problem that the source/drain region of the MOSFET is extended at a high temperature step (crystallization anneal at about 750° C.) at that time so that a short channel effect is generated.

In the MOSFET structure according to the twenty-first embodiment, the short channel effect can be sufficiently suppressed. That is, there is provided a structure in that the short channel effect by the extension of the source/drain region at the step of the formation of the capacitor can be suppressed. At this time, in order to realize a pass word line, a structure is desired in which the first gate electrode including the normal side-wall is formed of polysilicon layer, and the first gate electrode and the pass word line are connected with a different second gate electrode. Furthermore, it is more desired that the insulating film is embedded between the first gate electrode and the second gate electrode. Here, there has been described an example in which a capacitor is formed above a bit line. The bit line may be formed above the capacitor. By doing so, a MOSFET structure using the fence can be applied to a stacked capacitor DRAM transistor.

(Twenty-second Embodiment)

The twenty-second embodiment relates to a structure of a gate electrode in the case where a plurality of MOSFET each comprises a fence (showing a case of two MOSFETs).

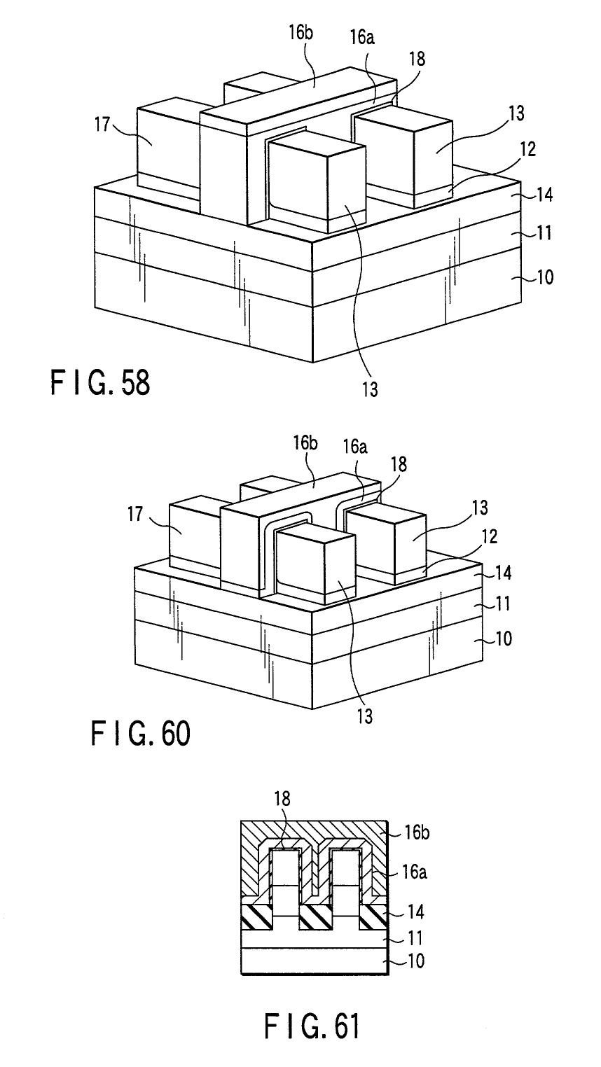

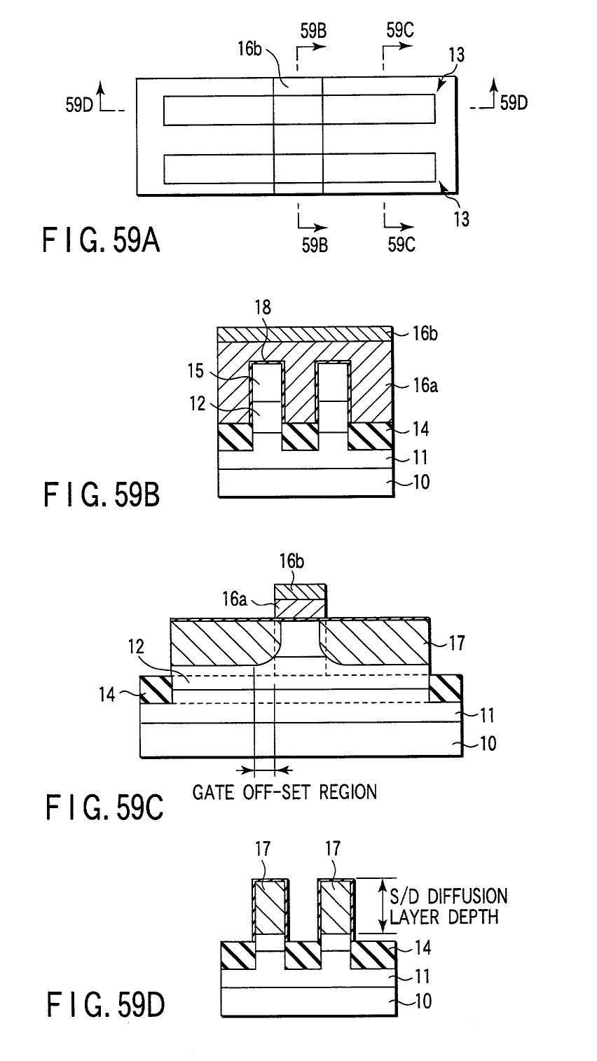

FIG. 58 is a perspective view showing a MOSFET according to a twenty-second embodiment of the present invention. FIG. 59A is a plan view thereof. FIG. 59B is a sectional view taken along the line 59B-59B of FIG. 59A. FIG. 59C is a sectional view taken along the line 59C-59C of FIG. 59A. FIG. 59D is a sectional view taken along the line 59D-59D of FIG. 59A. Incidentally, in FIG. 58 and FIGS. 59A through 59D, a contact, a wiring, and a side-wall insulating film shown in FIG. 2A of, for example, the first embodiment are omitted respectively.

As shown in FIG. 58 and FIGS. 59A through 59D, a plurality of fences 13 are arranged in a high density. For example, fences 13 are arranged in a minimum design rule.

In this case, there is provided a structure in which a polycrystal Si layer as the first gate electrode 16a is completely embedded between fences 13 so that a metal film (for example, a W film, an Al film, a TiN film) or a silicide film (for example, a TiSi2 film, a WSi2 film CoSi2 film) which are the second gate electrode 16b are formed on a surface of the first gate electrode which is planarized.

In this manner, there can be provided an advantage that the formation of the metal film or the silicide film which is a material of, for example, a second gate electrode 16b is facilitated by the formation of the second gate electrode 16b on a surface of the first gate electrode 16a which has become planarized, and the process of the gate electrode becomes easy.

Furthermore, since the surface of the second gate electrode 16b can be planarized, there can be provided an advantage that a manufacture step similar to the conventional planar-type MOSFET can be used after the gate electrode is processed.

(Twenty-third Embodiment)

The twenty-Third embodiment relates to a structure of a gate electrode in the case where a plurality of MOSFET each comprises a fence (showing a case of two MOSFETs).

FIG. 60 is a perspective view showing a MOSFET according to a twenty-third embodiment of the present invention. FIG. 61 is a sectional view thereof. The cross section of FIG. 60 corresponds to the cross section shown in FIG. 59B. Furthermore, in FIGS. 60 and 61, a contact, a wiring and a side-wall insulating film shown in FIG. 2A associated with, for example, the first embodiment are omitted respectively.

As shown in FIG. 60, a polycrystal Si layer which is the first gate electrode 16a is thinned down to, for example, about 20 nm. Then, the metal film or the silicide film which is the second gate electrode 16b can be embedded between the first gate electrodes 16a.

In the twenty-third embodiment, there can be provided an advantage that, for example, the surface of the second gate electrode can be planarized, and the manufacture process similar to the conventional planar type MOSFET can be used after the process of the gate electrode.

(Twenty-fourth Embodiment)

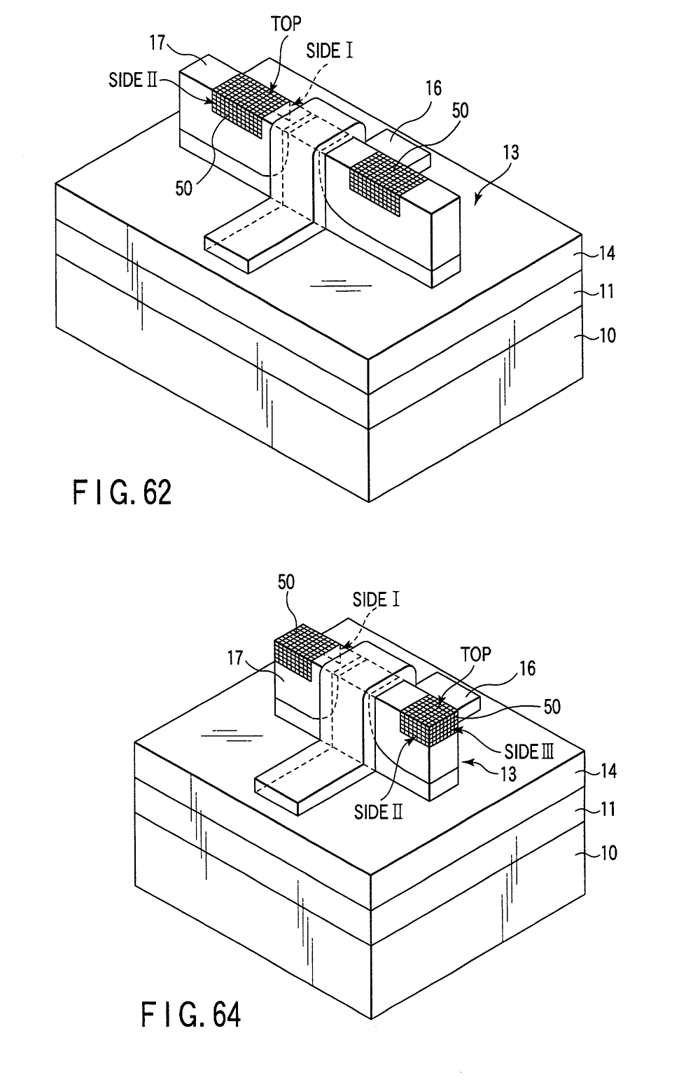

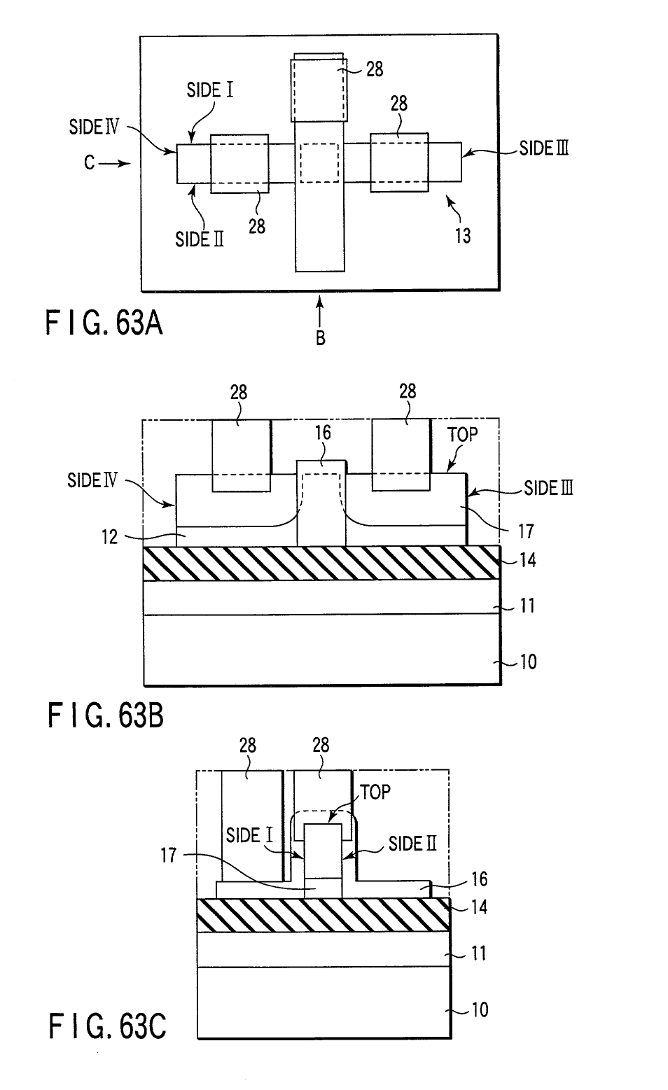

FIG. 62 is a perspective view showing a contact portion of the MOSFET according to the present invention. FIG. 63A is a plan view showing a contact portion of the MOSFET according to the present invention. FIG. 63B is a side view as seen from a direction of an arrow B shown in FIG. 63A. FIG. 63C is a side view as seen from a direction of an arrow C shown in FIG. 63A. Incidentally, in FIG. 62, FIGS. 63A through 63C, the contact, the wiring, and the side-wall insulating film shown in FIG. 2S of, for example, the first embodiment are omitted respectively.

As shown in FIGS. 62, 63A through 63C, in the MOSFET according to the present invention, a portion of the source/drain region 17 to which, for example, the contact plug 28 is connected (an electric contact portion hereinafter) strides over a portion of the upper surface (TOP) of the fence 13, and two side surfaces (SIDE I and SIDE II) located opposite to each other.

In this structure, an electric contact portion 50 can be widened in a downward direction along a side surface of the fence 13. As a consequence, there can be provided an advantage that the area of the electric contact portion 50 can be enlarged and an increase in a contact resistance with, for example, the contact plug 28 and the source/drain region 17 can be suppressed without increasing the width of the source/drain region 17, specifically the width of the fence 13.

The twenty-fourth embodiment is intended to provide a structure which enables further reduction of an area of a planar surface of the MOSFET without damaging the above advantage.

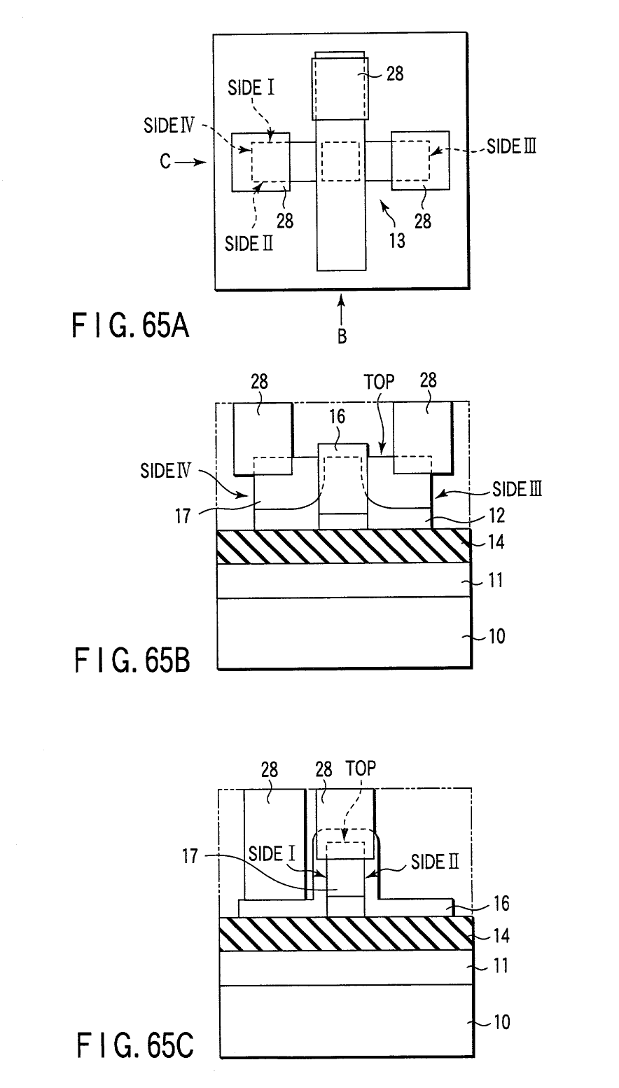

FIG. 64 is a perspective view showing a MOSFET according to the twenty-fourth embodiment of the present invention. FIG. 65A is a plan view thereof. FIG. 65B is a side view as seen from a direction of an arrow B shown in FIG. 65A. FIG. 65C is a side view as seen from a direction of an arrow C shown in FIG. 65A.

As shown in FIG. 64 and FIGS. 65A through 65C, in the MOSFET according to the twenty-fourth embodiment, the electric contact portion 50 strides over the upper surface (TOP) of the fence 13, a part of two side surfaces (SIDE I and SIDE II) and a part of two other side surfaces (SIDE III and SIDE IV) which respectively come into contact with two side surfaces (SIDE I and SIDE II).

Also in this structure, the electric contact portion 50 can be widened in a downward direction along a side surface of the fence 13. Furthermore, in the twenty-fourth embodiment, the electric contact portion 50 is allowed to be stridden over two other side surfaces (SIDE III and SIDE IV) so that a reduction of an area of the electric contact portion 50 can be suppressed while the length of the fence 13, for example, the length along the channel length direction can be shortened.

Consequently, it is possible to further reduction an area of the planar surface of the MOSFET without damaging an advantage explained by referring to FIG. 62 and FIGS. 63A through 63C.

(Twenty-fifth Embodiment)

The twenty-fifth embodiment relates to a structure which can alleviate the concentration of a gate electric field.

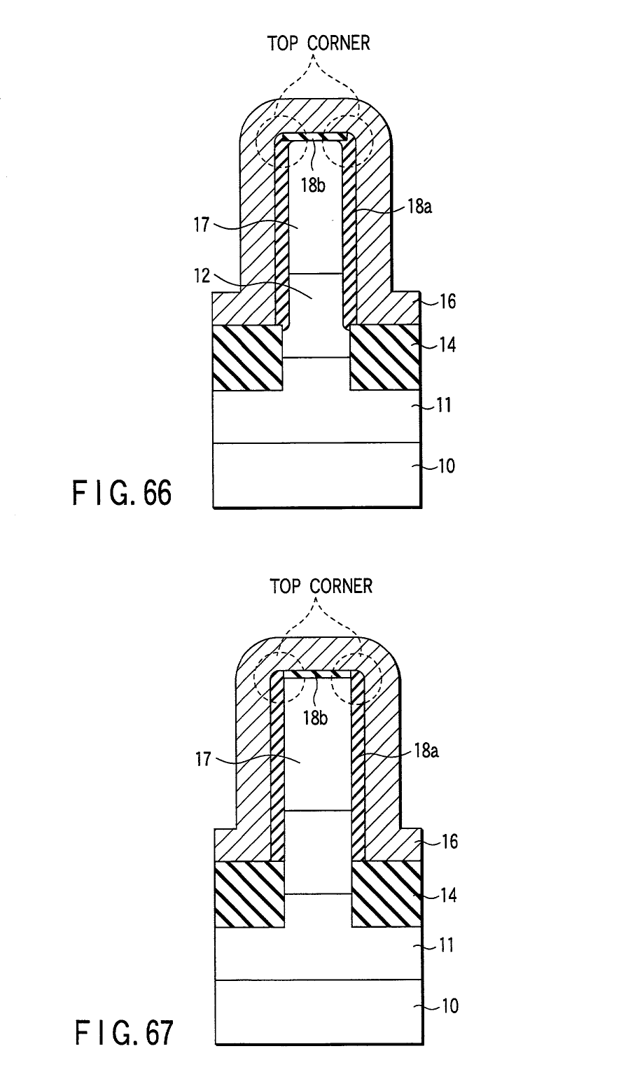

FIG. 66 is a sectional view showing a MOSFET according to a twenty-fifth embodiment of the present invention. A cross section shown in FIG. 66 corresponds to a cross section shown in FIG. 2B associated with the first embodiment.

For example, in the second embodiment, the gate insulating film 18b formed on the upper surface of the fence 13 is made thicker than the gate insulating film 18a formed on a side surface of the fence 13. As a consequence, it has been explained that the concentration of the gate electric field at an upper part corner of the channel region 15 can be alleviated, and a change in the threshold voltage and a change in the substrate bias characteristic which result from the concentration of the gate electric field can be suppressed.

In the MOSFET according to the twenty-fifth embodiment, as shown in FIG. 66, contrary to the second embodiment, the gate insulating film 18b formed on an upper surface of the fence 13 is made thinner than the gate insulating film 18a formed on the side surface of the fence 13.

Such a structure can be obtained by oxidizing the side surface of the fence 13 so that the side surface becomes thicker than the insulating film formed on an upper surface at the step explained by referring to FIGS. 7A and 7B.

In such a structure, the concentration of the gate electric field at an top corner can be alleviated as a result of a round configuration shown in a broken line circle. In the same manner as in the second embodiment, it is possible to suppress a change in the threshold voltage and a change in the substrate bias resulting from the concentration of the gate electric field.

(Twenty-sixth Embodiment)

The twenty-sixth embodiment of the invention relates to a structure which enables to alleviate the concentration of the gate electric field in the same manner as in the twenty-fifth embodiment.

FIG. 67 is a sectional view showing a MOSFET according to a twenty-sixth embodiment of the present invention. incidentally, the cross section shown in FIG. 67 corresponds to the cross section shown in FIG. 2B associated with the first embodiment.

As shown in FIG. 67, the twenty-sixth embodiment is different from the twenty-fifth embodiment in that the gate insulating film 18a formed on the side surface of the fence 13 is formed with the deposition of the insulator.

Such a structure can be obtained by depositing and forming an insulating film, preferably a high dielectric film on the entire surface after the step explained by referring to FIGS. 6A and 6B, followed by etching the high dielectric film by using the RIE to be remained on the side surface of the fence 13.

In this structure, an upper part corner shown in a broken line circle can be formed into a round configuration so that the concentration of the gate electric field at the upper part corner can be alleviated and in the same manner as in the second embodiment, a change in the threshold voltage and a substrate bias characteristic resulting from the concentration of the gate electric field can be suppressed.

(Twenty-Seventh Embodiment)

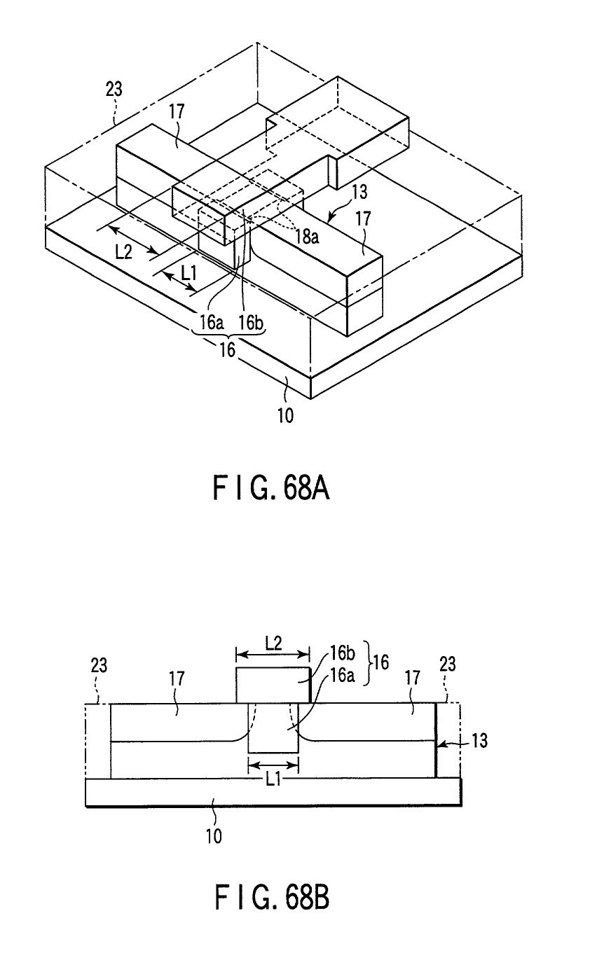

FIG. 68A is a perspective view showing a MOSFET according to a twenty-seventh embodiment. FIG. 68B is a side view thereof.

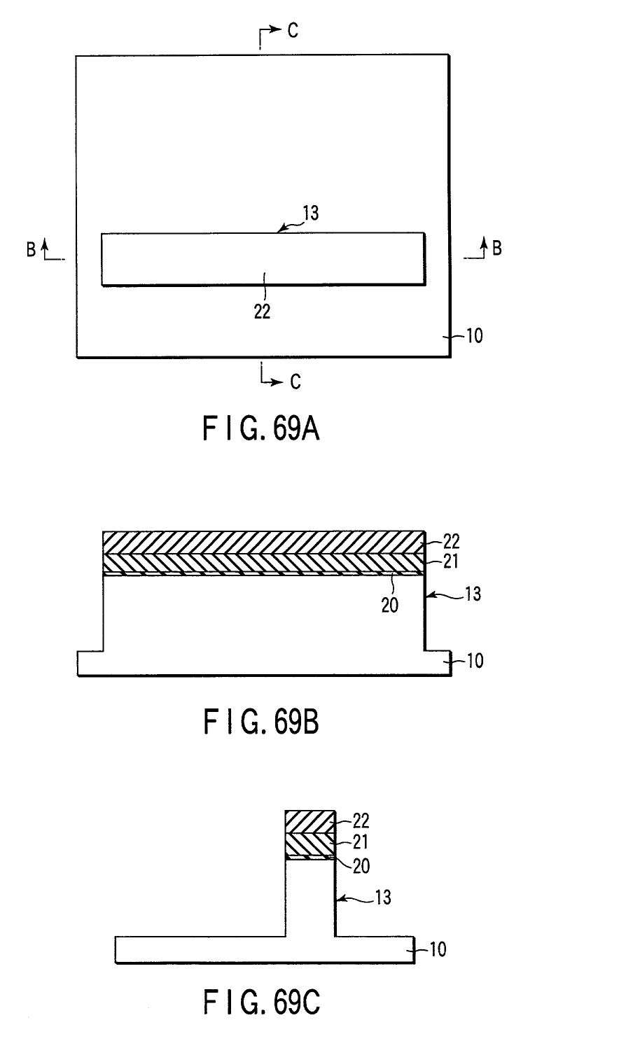

As shown in FIGS. 68A and 68B, the gate electrode 16 of the MOSFET according to the twenty-seventh embodiment is constituted with a side-wall gate portion 16a and an upper gate portion 16b. The side-wall gate portion 16a is formed on the gate insulating film 18a formed on a side surface of the fence 13. Furthermore, the upper gate portion 16b is formed on the gate insulating film 18b (omitted in FIGS. 68A and 69B) formed on the upper surface of the fence 13. Then, the gate length L1 of the side-wall gate portion 16a is shorter than the gate length L2 of the upper gate portion 16b.

Next, an example of the method of manufacturing the MOSFET according to the twenty-seventh embodiment will be explained by using FIGS. 69 through 78. Incidentally, FIGS. 69A through 78A are respectively plan views. FIGS. 69B through 78B are sectional views taken along the line B-B of FIGS. 69A through 78A respectively. FIGS. 69C through 78C are sectional views taken along the line C-C of FIGS. 69A through 78A respectively.

In the beginning, as shown in FIGS. 69A through 69C, with the manufacturing method similar to the manufacturing method explained in the first embodiment, a SiO2 layer 20 having a thickness of about 5 nm, a mask layer (SiN) 21 having a thickness of about 100 nm, and a mask layer (SiO₂) having a thickness of about 100 nm are subsequently formed on the P-type Si substrate 10. After this, the P-type Si substrate 10 is etched by about 150 nm to form a trench while forming a fence 13 having a width of about 100 nm.

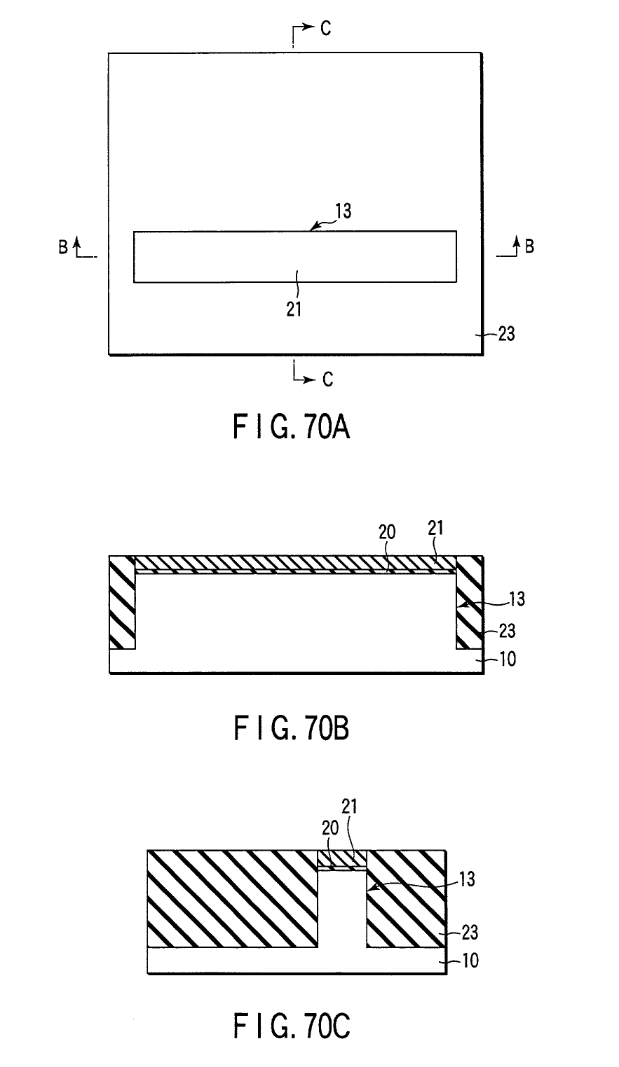

Next, as shown in FIGS. 70A through 70C, a trench formed on the Si substrate is filled with an insulator (SiO₂) 23 with the same manufacturing method as the manufacturing method explained, for example, in the first embodiment. As a consequence, a shallow trench isolation is formed in the Si substrate 10. In this example, a mask layer (SiN) 21 is left on the fence 13.

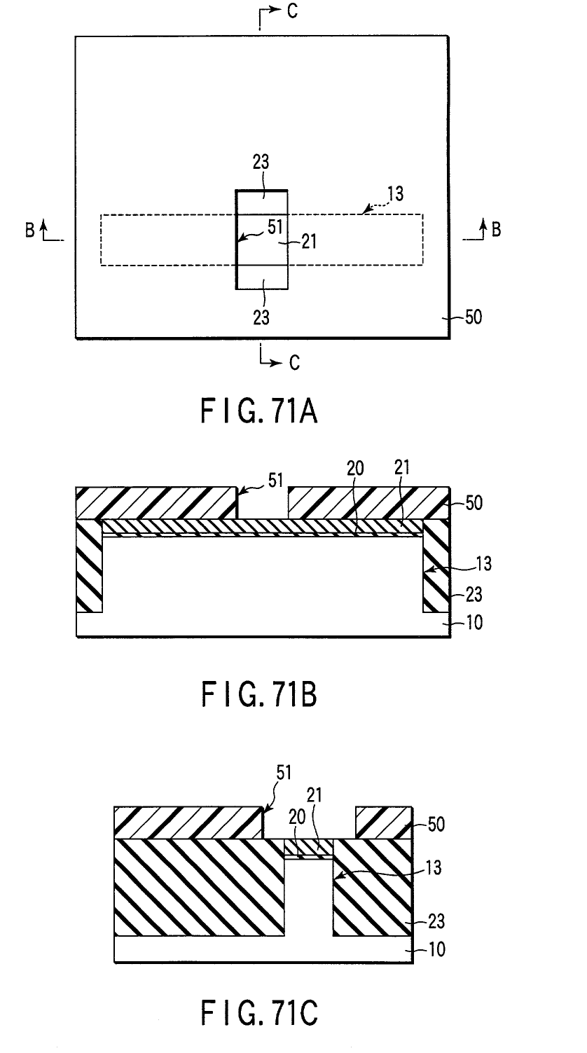

Next, as shown in FIGS. 71A through 71C, a photoresist is applied on a structure shown in FIGS. 70A through 70C to form a photoresist film 50. Next, the lithography method is used to form a window 51 corresponding to a side-wall gate portion formation pattern at the photoresist film 50. In this example, a portion corresponding to a side-wall gate portion formation region of an insulator (SiO₂) 23 and the mask layer (SiN) 21 are exposed respectively from the window 51.

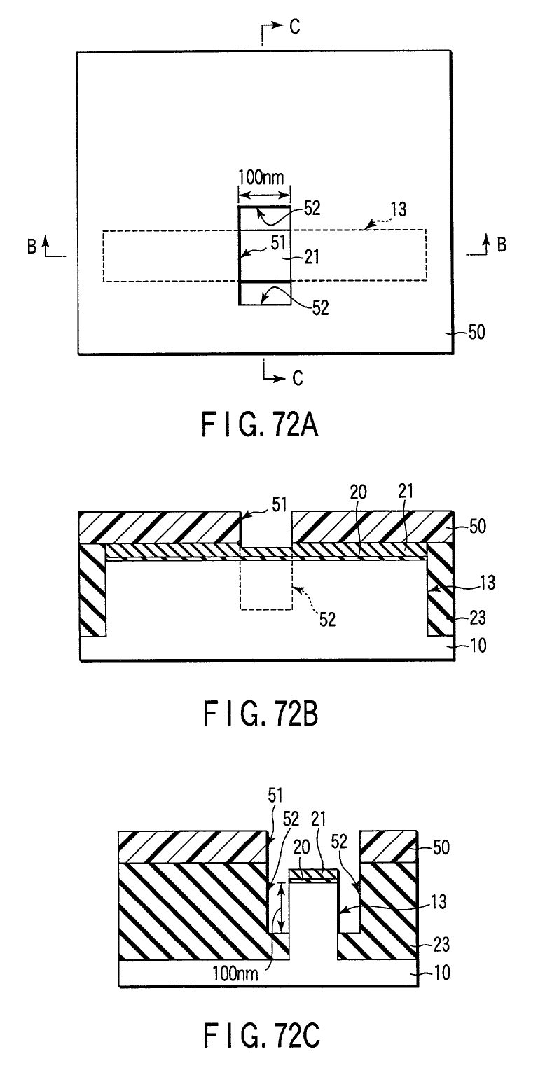

Next, as shown in FIGS. 72A through 72C, the photoresist film 50 and the mask layer (SiN) 21 are used as a mask to etch the insulator (SiO₂) 23 to etch by about 100 nm, for example, from an interface between the fence 13 and the SiO₂ layer 20. As a consequence, a trench 52 for embedding the side-wall gate portion having, for example, a depth of about 100 nm and a width of about 100 nm is formed on the insulator (SiO₂) 23.

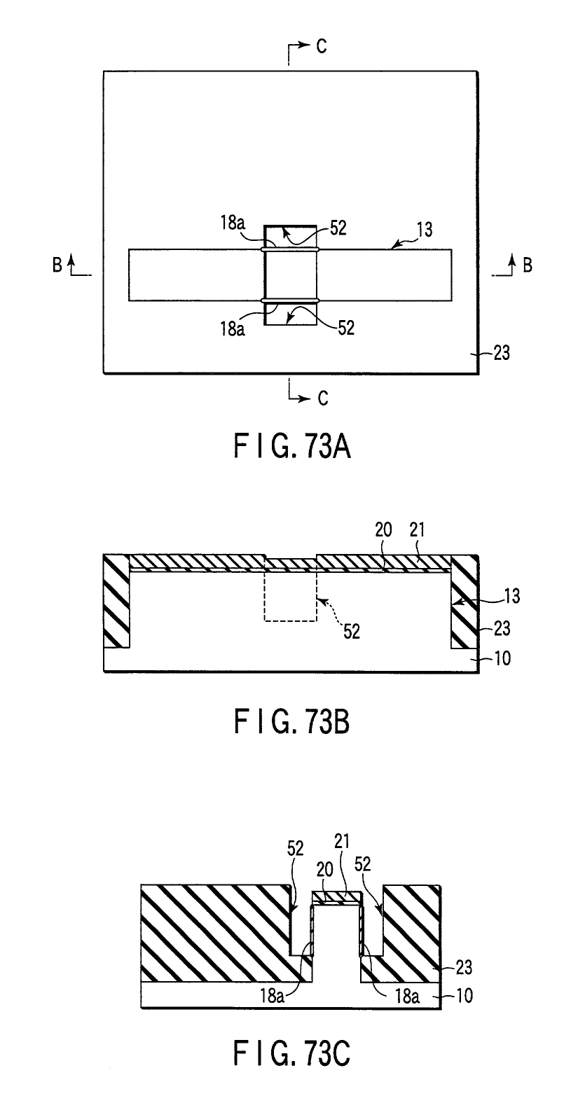

Next, as shown in FIGS. 73A through 73C, the photoresist film 50 is removed. Next, a gate insulating film 18a comprising, for example, SiO₂ is formed on the side surface of the fence 13 exposed from the trench 52.

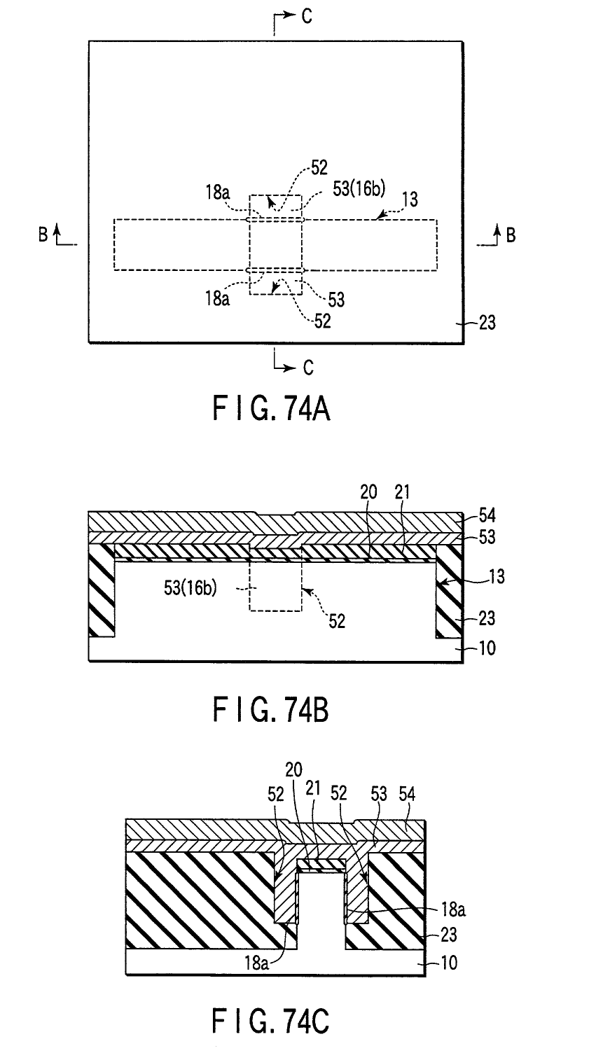

Next, as shown in FIGS. 74A through 74C, for example, a doped polycrystal Si film 53 doped with an N-type impurity is formed on a structure shown in FIGS. 73A through 73C. As a consequence, the trench 52 is embedded with the doped polycrystal Si film 53, and a side-wall gate portion 16b out of the gate electrode 16b is formed. Next, a metal film 54 is formed on the doped polycrystal Si film 53. As one example of the metal film 54, a W film can be given.

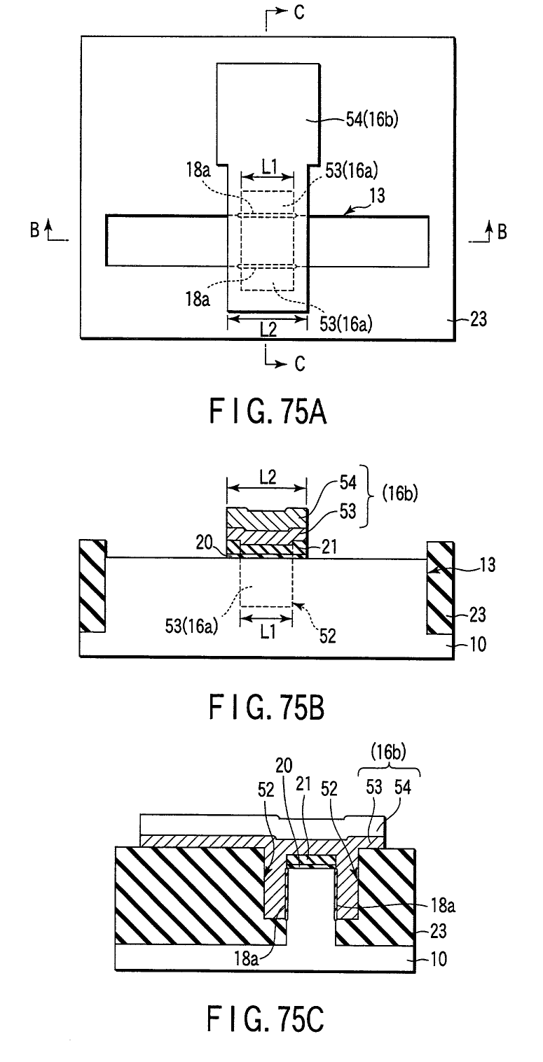

Next, as shown in FIGS. 75A through 75C, a resist film (not shown) is used as a mask to etch the metal film 54, the doped polycrystal Si film 53, the mask layer (SiN) 21 and the SiO₂ layer 20. As a consequence, out of the gate electrode 16, an upper gate portion 16b is formed while an upper surface of the fence 13 is exposed. An upper surface of the fence 13 corresponds to the planar pattern of the active area of the MOSFET. In this example, the gate length L2 of the upper gate portion 16b is set to be longer than the gate length L1 of the side-wall gate portion 16b. One example of the numeric value is that the gate length L1 has a length of about 140 nm and the gate length L2 has a length of about 100 nm.

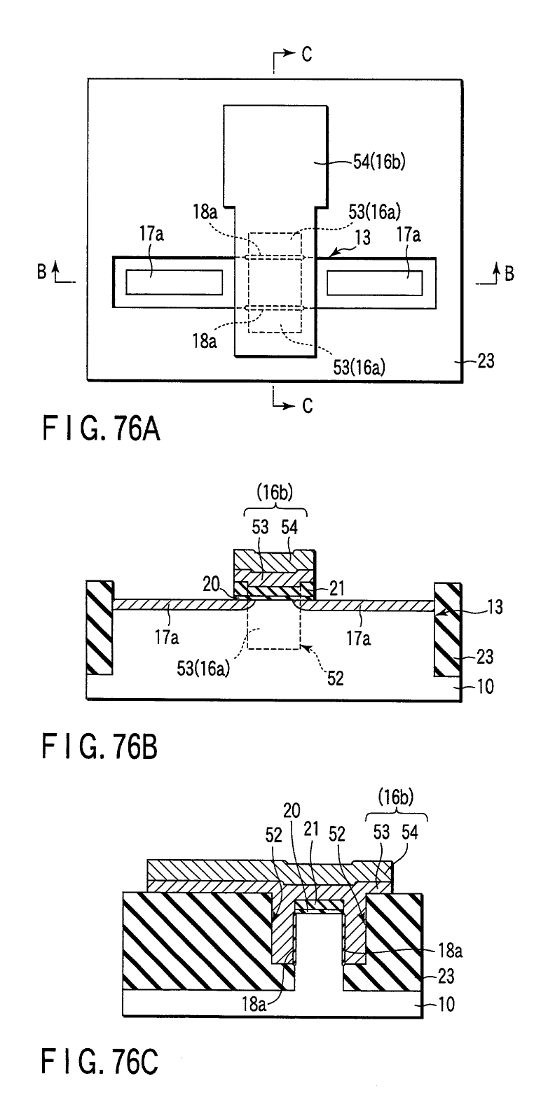

Next, as shown in FIGS. 76A through 76C, an N-type impurity ions, for example, phosphorus ions are implanted into the fence 13 by using the upper gate portion 16b and the insulator 23 as a mask. As a consequence, an N⁻-type diffusion layer 17a is formed into the fence 13. Incidentally, this N⁻-type diffusion layer 17a functions as, for example, an extension layer and is formed when needed. Consequently, the layer may be omitted.

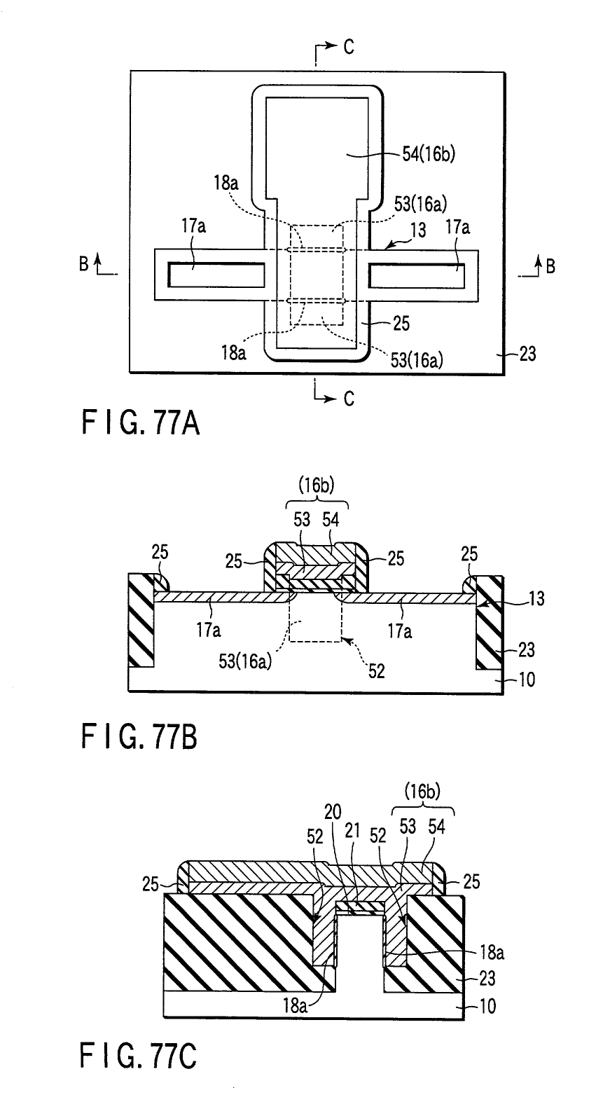

Next, as shown in FIGS. 77A through 77C, an insulator, for example, SiO2 and SiN are deposited on the structure shown in FIGS. 76A through 76C by using the CVD method. Next, the deposited insulator is subjected to RIE, and this insulator is left on the side-wall of the gate electrode 16. As a consequence, the side-wall insulating film 25 is formed. Furthermore, in this example, as shown in FIGS. 75A through 75C, a step is generated between the insulator 23 and the upper surface of the fence 13 by removing the mask layer (SiN) 21 from an upper surface of the fence 13. Consequently, the insulator also remains on the side-wall of the insulator 23. As a consequence, a side-wall insulating film 25 is also formed on the side-wall of the insulating film 23.

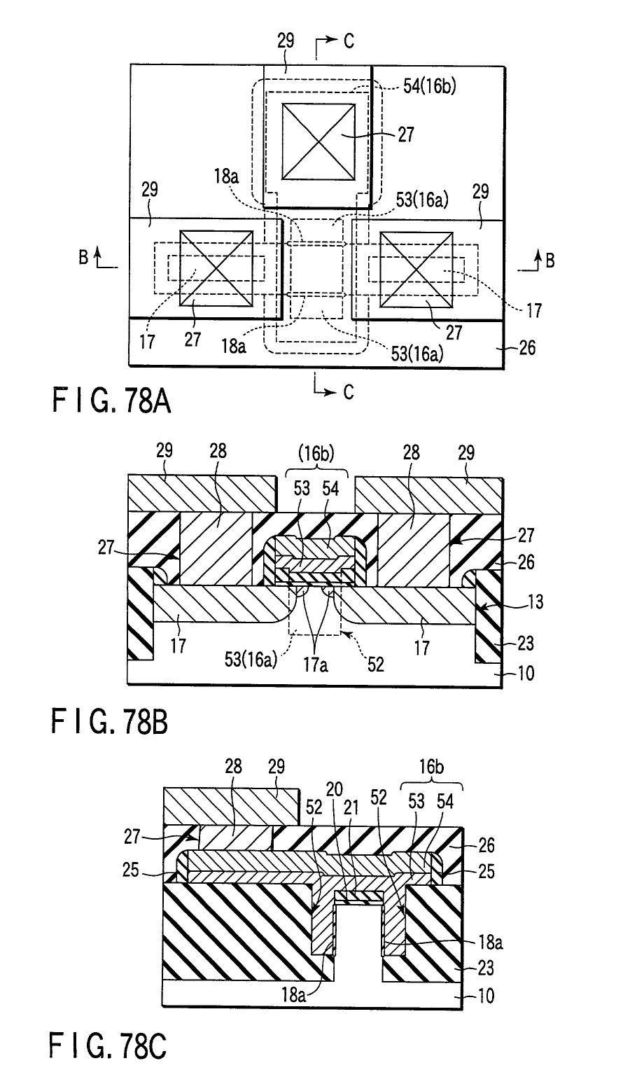

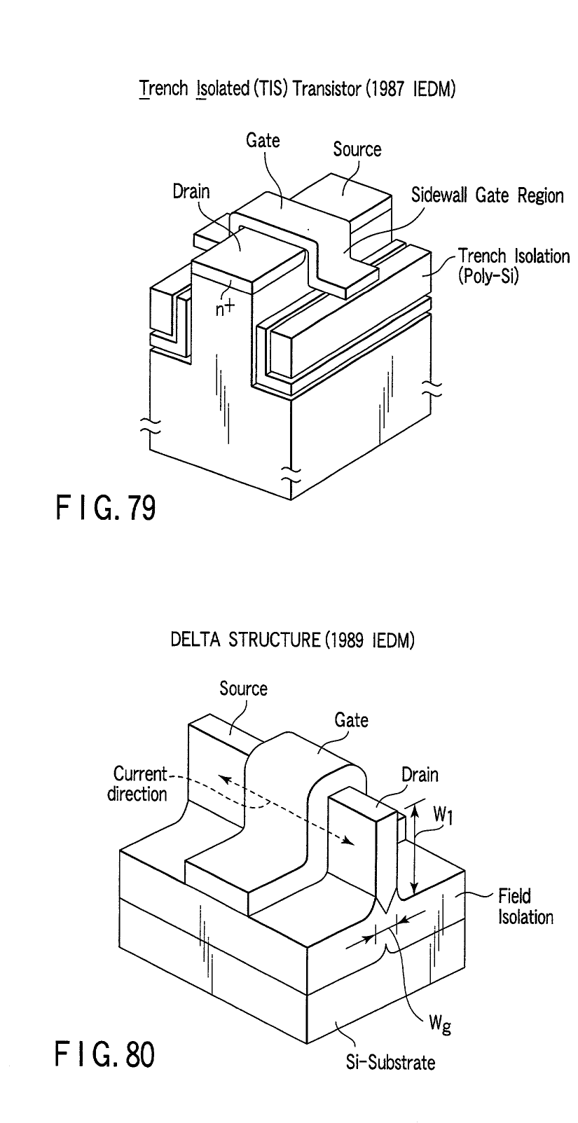

Next, as shown in FIGS. 78A through 78C, the upper gate portion 16b, the insulator 23 and the side-wall insulating film 25 are used as a mask to implant N-type impurity ions, for example, arsenic ions into the fence 13. As a consequence, the N⁺-type diffusion layer 17 is formed into the fence 13. The N⁺-type diffusion layer 17 functions as a source/drain region of the NMOS. Next, an interlayer insulating film 26 is formed on an upper gate portion 16b, N⁺-type diffusion layer 17, the insulator 23 and the side-wall insulating film 25. Next, in the interlayer insulating film 25, a contact hole 27 is formed which reaches the N⁺-type diffusion layer 17 and the upper gate portion 16b. Next, a conductor such as a tungsten film or the like is filled in the contact hole 27 to form a contact plug 28. Next, a wiring layer 29 is formed on the interlayer insulating film 26, the layer being electrically connected to the contact plug 28.

In this manner, a MOSFET according to the twenty-seventh embodiment can be formed.

In the MOSFET according to the twenty-seventh embodiment, in addition to the effect obtained from the above embodiments, for example, the following effects can be obtained.

(1) The gate length L1 of the side-wall gate portion 16a is made shorter than the gate length L2 of the upper gate portion 16b. Thus, the effective gate length of the MOSFET is shorter than the gate length L1 of the upper gate portion 16b. As a consequence, as compared with the planar type MOSFET having the same planar pattern as the MOSFET according to the twenty-seventh embodiment, the performance is heightened. For example, a response speed of the MOSFET is heightened with the shortening of the effective gate length. Needless to say, since the side-wall gate portion 16b is provided with the result that a channel width increases as compared with the planar type MOSFET having the same planar pattern, for example, a current drive performance is also enlarged.

(2) As a long channel length L1 of the upper gate portion 16b, namely as the gate wiring, the cross section area can be enlarged. When the cross section area of the gate wiring is enlarged, a resistance value of the gate wiring is decreased. When the resistance value of the gate wiring is decreased, the state of a signal delay in the gate wiring is alleviated and a performance as an integrated circuit is heightened as well.

(3) Furthermore, according to the manufacturing method, a trench 52 for the embedding of the side-wall gate portion is formed on the insulator 23. This trench 52 is filled with the conductor which constitutes the side-wall gate portion 16a. Such manufacturing method facilitates the manufacture as compared with the case in which the conductor which constitutes the gate electrode 16 is patterned over the fence 13.

(4) Furthermore, at the step of filling the conductor which constitutes the side-wall gate portion 16a in the trench 52, the current shallow trench technology or the like can be applied. Then, after the conductor which constitutes the side-wall gate portion 16a is filled in the trench 52, the MOSFET can be formed by using the normal planar type MOSFET manufacture technique. From these viewpoints, in the manufacturing method introduced in the twenty-seventh embodiment, the MOSFET according to the present invention can be formed, an the practicality is high as well.

Incidentally, such manufacturing method is used not only in the case of manufacturing the MOSFET according to the twenty-seventh embodiment but also in the case of manufacturing the MOSFET according to the first to the twenty-seventh embodiments.

Hereinafter, according to the present invention explained in the first to the twenty-seventh embodiments,

(1) the source/drain region formed in the fence Si layer is separated from the isolation insulating film formed in a lower portion region of the fence.

According to this structure, the channel width of the MOSFET can be controlled with the depth of the source/drain region and the MOSFET having various channel width can be concentrated on one chip while suppressing an increase in the planar surface area.

(2) The width (Wg) of the fence is made narrower than, for example, 0.20 μm.

According to this structure, the channel region can be completely depleted with the gate electrode formed on the side surface of the fence. With the complete depletion of the channel region, the impurity concentration of the channel region can be lowered as compared with the impurity concentration of the planar type MOSFET channel region. Then, the reduction in the carrier mobility in the channel region can be suppressed with a reduction in the impurity concentration of the channel region. As a consequence, a structure can be realized which is hardly affected by the fluctuation in the impurity concentration and which is strong against a dispersion in the thickness of the gate insulating film.

(3) At least a part of the thickness of the gate insulating film between the upper surface of the fence and the gate electrode is made larger or smaller than the thickness of the gate insulating film between the side surface of the fence and the gate electrode.

According to the structure, the concentration in the gate electric field in the top corner of the fence can be alleviated, which facilitates to control the threshold voltage.

(4) A high concentration impurity layer is provided between the channel region of the fence and a well or a substrate.

According to the structure, a punch-through of the MOSFET can be prevented.

(5) A distance between the source and the drain is made shorter on the upper portion region wider toward the lower portion on the side surface of the fence.

According to this structure, a punch-through of the MOSFET can be prevented.

(6) The source/drain region and the gate electrode can be offset to each other on the side surface of the fence.

According to the structure, a punch-through can be prevented.

(7) A plurality of fences are provided and the gate electrode is commonly formed on these side surfaces.

According to the structure, a larger channel width can be realized in a smaller planar surface area.

(8) A fence for the gate contact can be realized in addition to the fence.

According to this structure, the depth of the contact hole can be approximately aligned with the source/drain region and the gate electrode respectively, so that a yield in the manufacture can be improved.

(9) In the case where a contact is formed on the source/drain region of the fence, the contact can be formed not only on the upper surface of the fence but also at least on a part of the side surface.

According to the structure, a contact resistance can be decreased without damaging an increase in the planar surface area.

(10) An inclination of the fence (taper angle) is formed into a forward taper having an angle of about 85 degrees instead of approximately a right angle.

According to this structure, the process of the gate electrode at the side surface of the fence can be easily conducted.

(11) The gate electrode formed along the side surface of the fence is made of, for example, a polycrystal Si layer, and a second gate electrode comprising, for example, a metal film or a silicide film is connected to the gate electrode.

According to this structure, the resistance of the gate electrode can be decreased while the height of the adjacent gate electrode can be lowered. Consequently, the gate electrode characteristic can be adjusted while the parasitic capacity between gate electrodes can be lowered.

(12) The gate insulating film formed at least on the side surface of the fence is made of, for example, a high dielectric insulating film such as Ta₂O₅ film.

According to this structure, the capacity between the gate electrode and the channel region can be increased while the cut-off characteristic of the MOSFET can be more effectively improved.

(13) An angle of the top corner of at least the channel region of the fence is set to approximately 90 degrees to about 45 degrees, or formed into a round configuration which is approximated to a semi-circle having a radius of 30 nm.

According to this structure, the concentration of the gate electric field at the top corner of the fence can be alleviated and the control of the threshold value becomes easy.

(14) The source/drain region formed on the fence is formed in a structure including a LDD-like high concentration source/drain region and a low concentration source/drain region instead of a single source/drain structure.

According to this structure, an electric field in the vicinity of the source/drain region can be alleviated, and the reliability of the transistor can be improved.

(15) A plurality of fences are provided, and the gate electrode is commonly formed on these side surfaces while parts of the region including at least the source/drain region of the plurality of fences are connected to each other.

According to the structure, a larger channel width can be realized with a small plan area while the number of contacts with respect to the source/drain region can be decreased.

(16) A conductive impurity layer is provided which has a different conductivity type from the source/drain region between the bottom portion of the source/drain region formed on the fence and the insulating film formed below the fence.

According to the present structure, when the fence is formed, for example, on the SOI substrate, a dispersion in the thickness of the SOI layer can be absorbed into the dispersion in the depth of the source/drain region.

(17) Even in the case where the fence is formed by using amorphous Si formed on the glass substrate, the above effects can be obtained by adopting the structures (1) through (16).

(18) A fence is formed with an epitaxial Si layer which is epitaxially grown in the trench.

According to this structure, the isolation insulating film formed on the periphery of the fence can be stably formed with the result that a yield in the manufacture of the semiconductor integrated circuit device can be improved.

(19) In the case where a CMOS circuit is formed with a NMOSFET formed on the fence and a PMOSFET formed on the other fence, the depth of the P-type source/drain region and the depth of the N type source/drain region are made different from each other. Specifically, the depth of the P-type source/drain region is made deeper than the depth of the N-type source/drain region.

According to this structure, a difference in the planar design size of the NMOSFET and the PMOSFET resulting from a difference in a mobility of electrons and a mobility of holes can be decreased. In particular, the CMOS circuit is designed, the area of the PMOSFET can be decreased, and the whole circuit area can be decreased.

(20) In the case where the CMOS circuit is formed with the NMOSFET (or PMOSFET) formed on the fence, and the NMOSFET (or PMOSFET) formed on the fence, the depth of the source/drain region of the NMOSFET (or PMOSFET) is made different.

According to the structure, the NMOSFET (or PMOSFET) can be realized which has mutually different channel width. When the circuit is designed, the area of the NMOSFET (or the PMOSFET) having a large channel width can be realized, and the whole circuit area can be realized.

The first to twenty-seventh embodiments have been explained. According to the present invention, the embodiments are not restricted thereto. It is possible to modify the embodiments in various manners within the scope of the invention without departing from the spirit of the invention.

For example, it is possible to allow the MOSFET according to the present invention, and a planar type MOSFET to coexist on the same Si wafer substrate. In this case, the characteristics of the MOSFET according to the present invention and the planar type MOSFET can be well used.

Furthermore, there has been explained primarily a case of a single MOSFET device according to the embodiments. This MOSFET can be applied to a flash memory, a SDRAM, a DRAM, various logic circuits, a CPU and the like. The embodiments can be applied as a new MOSFET device structure which replaces a conventional planar type MOSFET device on the entire surface of the LSI circuit by making use of the following characteristic; the device structure can suppress a short channel effect to be effective for the miniaturization of the P-channel and N-channel MOSFET, the cut-off characteristic of the device is improved with the complete depletion of the channel, the current drive performance of the MOSFET is improved with the double gate structure, the channel width of the N-channel and the P-channel can be realized with an adjustment of the depth of the source/drain without increase in the planar surface design area, and a large current MOSFET device can be realized with a small area by dividing the device into a plurality of fence.

Furthermore, each of the above embodiments can be practiced alone or in an appropriate combination.

Furthermore, each of the above embodiments includes various stages of the invention. It is possible to extract various stages of the invention with an appropriate combination of the plurality of constituent elements disclosed in each of the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a convex semiconductor layer provided on a semiconductor substrate;
a source region and a drain region provided in the convex semiconductor layer; and
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer,
wherein a distance between the source region and the drain region changes on the side surface of the convex semiconductor layer.

2. A semiconductor device comprising:
a convex semiconductor layer provided on a substrate;
a source region and a drain region provided in the convex semiconductor layer;
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer; and
a side-wall insulating film provided on a side surface of the gate electrode and the side surface of the convex semiconductor layer.

3. A semiconductor device comprising:
a convex semiconductor layer provided on a substrate;
a isolation film provided on a periphery of a lower portion region of the convex semiconductor layer, the position of the upper surface of the isolation film being lower than an upper surface of the convex semiconductor layer;
a source region and a drain region provided in the convex semiconductor layer, the position of the deepest portion of the source region and the position of the deepest portion of the drain region being equal to or lower than the position of the upper surface of the isolation film; and
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer.

4. The device according to claim 3, wherein the source and drain regions are overlapped with the side-wall gate portion.

5. A semiconductor device comprising:
a first convex semiconductor layer provided on a substrate, the first convex semiconductor layer electrically connected to the substrate;
a second convex semiconductor layer provided on the substrate, the second convex semiconductor layer electrically connected to the substrate, the second convex semiconductor layer having the same width as the first semiconductor layer;
a first source region and a first drain region provided in the first convex semiconductor layer;
a second source region and a second drain region provided in the second convex semiconductor layer; and
a gate electrode having a side-wall gate portion provided over a side surface of the first convex semiconductor layer and a side surface of the second convex semiconductor layer, in an insulated state with respect to the first and second convex semiconductor layers respectively, the gate electrode applying an electric field effect to a first channel region between the first source and drain regions and a second channel region between the second source and drain regions, via at least the side surfaces of the first and second convex semiconductor layer.

6. A semiconductor device comprising:
a first convex semiconductor layer provided on a substrate, the first convex semiconductor layer electrically connected to the substrate;
a second convex semiconductor layer provided on the substrate, the second convex semiconductor layer electrically connected to the substrate;
a first source region and a first drain region provided in the first convex semiconductor layer;
a second source region and a second drain region provided in the second convex semiconductor layer;
a first gate electrode having a first side-wall gate portion provided over a side surface of the first convex semiconductor layer, in an insulated state with respect to the first convex semiconductor layer, the first gate electrode applying an electric field effect to a first channel region between the first source and drain regions, via at least the side surface of the first convex semiconductor layer;
a second gate electrode having a second side-wall gate portion provided over a side surface of the second convex semiconductor layer, in an insulated state with respect to the second convex semiconductor layer, the second gate electrode applying an electric field effect to a second channel region between the second source and drain regions, via at least the side surface of the second convex semiconductor layer;
a first wiring electrically connected to the first source region and the second source region;
a second wiring electrically connected to the first drain region and the second drain region; and
a third wiring electrically connected to the first gate electrode and the second gate electrode.

7. A semiconductor device comprising:
a first convex semiconductor layer provided on a substrate;
a second convex semiconductor layer provided on the substrate;
a source region and a drain region provided in the first convex semiconductor layer; and
a gate electrode having a side-wall gate portion provided over a side surface of the first convex semiconductor layer, in an insulated state with respect to the first convex semiconductor layer, and a gate contact portion provided over an upper surface of the second convex semiconductor layer, in an insulated state with respect to the second convex semiconductor layer, the gate electrode applying an electric field effect to a channel region between the source and drain regions, via at least the side surface of the first convex semiconductor layer.

8. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applying an electric field effect to a channel region between the source and drain regions, via at least the side surface of the convex semiconductor layer,
wherein a conductive material of the side-wall gate is different from a conductive material of the upper gate portion.

9. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applying an electric field effect to a channel region between the source and drain regions, via at least the side surface of the convex semiconductor layer; and
a wiring being electrically connected to the upper gate portion above the upper surface of the convex semiconductor layer.

10. A semiconductor device comprising:
a first convex semiconductor layer provided on a substrate;
a second convex semiconductor layer provided on the substrate;
a first source region and a first drain region provided in the first convex semiconductor layer;
a second source region and a second drain region provided in the second convex semiconductor layer;
a gate electrode having a side-wall gate portion provided over a side surface of the first convex semiconductor layer and a side surface of the second convex semiconductor layer, in an insulated state with respect to the first and second convex semiconductor layers respectively, the gate electrode applying an electric field effect to a first channel region between the first source and drain regions and a second channel region between the second source and drain regions, via at least the side surfaces of the first and second convex semiconductor layer; and
at least one third convex semiconductor layer electrically connected to at least either the first and the second source regions, or the first and the second drain regions.

11. A semiconductor device comprising:
a first convex semiconductor layer provided on a substrate;
a second semiconductor layer provided on the substrate;
a first source region and a first drain region of a first conductive type provided in the first semiconductor layer;
a second source region and a second drain region of a second conductive type provided in the second convex semiconductor layer, a depth of the second source region and a second drain region being deeper than the depth of the first source region and the second drain region;
a first gate electrode having a first side-wall gate portion provided over a side surface of the first convex semiconductor layer, in an insulated state with respect to the first convex semiconductor layer, the first gate electrode applying an electric field effect to a first channel region between the first source and drain regions, via at least the side surface of the first convex semiconductor layer; and
a second gate electrode having a second side-wall gate portion provided over a side surface of the second convex semiconductor layer, in an insulated state with respect to the second convex semiconductor layer, the second gate electrode applying an electric field effect to a second channel region between the second source and drain regions, via at least the side surface of the second convex semiconductor layer.

12. A semiconductor device comprising:
a first convex semiconductor layer provided on a substrate;
a second convex semiconductor layer provided on the substrate;
a first source region and a first drain region provided in the first convex semiconductor layer;
a second source region and a second drain region having the same conductive type as the first source region and the first drain region provided in the second convex semiconductor layer, a depth of the first source region and a depth of the second drain region being deeper than the first source region and the second drain region;
a first gate electrode having a first side-wall gate portion provided over a side surface of the first convex semiconductor layer, in an insulated state with respect to the first convex semiconductor layer, the first gate electrode applying an electric field effect to a first channel region between the first source and drain regions, via at least the side surface of the first convex semiconductor layer; and
a second gate electrode having a second side-wall gate portion provided over a side surface of the second convex semiconductor layer, in an insulated state with respect to the second convex semiconductor layer, the second gate electrode applying an electric field effect to a second channel region between the second source and drain regions, via at least the side surface of the second convex semiconductor layer.

13. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer, the gate electrode including at least a first layer and a second layer,
wherein the gate electrode uses a word line of a semiconductor memory device.

14. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer, the gate electrode including at least a first layer and a second layer,
wherein an upper surface of the first layer is planar and the second layer is provided on the upper surface of the first layer.

15. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer, the gate electrode including at least a first layer and a second layer,
wherein an upper surface of the first layer has a step, the second layer is provided on the upper surface of the first layer, and an upper surface of the second layer is planar.

16. A semiconductor device comprising:
a convex semiconductor layer provided on a substrate, the convex semiconductor having a first side surface, a second side surface opposite to the first side surface, a third side surface located between the first and second side surface, a forth side surface opposite to the third surface, and a upper surface;
a source region and a drain region provided in the convex semiconductor layer, the source region and the drain region including an electric contact portion respectively, the electric contact portion extending over a part of the first side surface, a part of the upper surface, a part of the second side surface and either of parts of the third and fourth side surfaces;
a gate electrode having a side-wall gate portion provided over a side surface of the convex semiconductor layer, in an insulated state with respect to the convex semiconductor layer, the gate electrode applying an electric field effect to a channel region between the source and drain regions, via at least the side surface of the convex semiconductor layer.

17. A semiconductor device comprising:
a convex semiconductor layer provided on a substrate;
a source region and a drain region provided in the convex semiconductor layer; and
a gate electrode having a side-wall gate portion provided over a side surface of the convex semiconductor layer, in an insulated state with respect to the convex semiconductor layer, and a upper gate portion provided over an upper surface of the convex semiconductor layer, in an insulated state with respect to the convex semiconductor layer, the gate electrode applying an electric field effect to a channel region between the source and drain regions, via at least the side surface of the convex semiconductor layer,
wherein a gate length of the side-wall gate portion is shorter than the gate length of the upper gate portion.

18. A method of manufacturing a semiconductor device comprising:
etching a semiconductor substrate to form a convex semiconductor layer on the semiconductor substrate;
forming a gate insulating film at least on a side surface of the convex semiconductor layer;
forming a gate electrode on the gate insulating film;
forming a side-wall insulating film on a side surface of the gate electrode and on the side surface of the convex semiconductor layer; and
introducing impurity into the convex semiconductor layer by using at least the gate electrode and the side-wall insulating film as a mask to form a source region and a drain region in the convex semiconductor layer.

19. A method of manufacturing a semiconductor device comprising:
forming an insulating film having an open hole on a semiconductor substrate;
forming a convex semiconductor layer on a semiconductor substrate exposed from the open hole;
forming a gate insulating film on at least a side surface of the convex semiconductor layer;
forming a gate electrode on the gate insulating film; and
introducing impurity into the convex semiconductor layer by using at least the gate electrode as a mask to form a source region and a drain region in the convex semiconductor layer.

20. The method according to claim 32, wherein the convex semiconductor layer is formed with the epitaxial growth method.

21. A method of manufacturing a semiconductor device comprising:
forming a convex semiconductor layer on a substrate;
forming an insulator at a periphery of the convex semiconductor layer;
forming a trench to form a side-wall gate portion in the insulator;
forming a gate insulating film on a side surface of the convex semiconductor layer exposed at least from the trench;
forming a gate electrode having a side-wall gate portion formed in the trench; and
introducing impurity into the convex semiconductor layer by using at least the gate electrode as a mask to form a source region and a drain region in the convex semiconductor layer.

22. The device according to claim 1, wherein the side-wall gate portion is offset with respect to a part of the source region and the drain region.

23. The device according to claim 1, further comprising:
a semiconductor region having a impurity concentration higher than that of the channel region, the semiconductor region provided between the substrate and the source region, between the substrate and the drain region and between the substrate and the channel region, respectively.

24. The device according to claim 1, further comprising:
a first gate insulating film provided between the side surface of the semiconductor layer and the side-wall gate portion; and
a second gate insulating film provided between an upper surface of the convex semiconductor layer and the gate electrode except for the side-wall gate portion, the second gate insulating film being thicker than the first gate insulating film.

25. The device according to claim 1, wherein the convex semiconductor layer has a tapered shape toward an upper surface of the convex semiconductor layer from the substrate.

26. The device according to claim 1, wherein a lower portion of the convex semiconductor layer has a tapered shape toward an upper surface of the convex semiconductor layer from the substrate.

27. The device according to claim 1, wherein a bottom corner of the convex semiconductor layer has a round shape.

28. The device according to claim 1, wherein a top corner of the convex semiconductor layer has a round shape.

29. The device according to claim 1, wherein an angle of a top corner of the convex semiconductor layer is larger than 90 degrees.

30. The semiconductor layer according to claim 1, further comprising:
an insulator provided between the substrate and the convex semiconductor layer; and
a semiconductor region provided between a bottom portion of the source region and the insulator, a bottom portion of the drain region and the insulator and the channel region and the insulator, the semiconductor region having the same conductive type as the channel region.

31. The device according to claim 30, wherein the convex semiconductor layer is amorphous silicon.

32. The semiconductor device according to claim 1, wherein the source region and the drain region includes an electric contact portion respectively, the electric contact portion extends over a part of the side surface of the convex semiconductor layer, an upper surface of the convex semiconductor layer and a part of another side surface of the convex semiconductor layer opposite to the side surface.

33. The device according to claim 1, further comprising:
a first gate insulating film provided between the side surface of the semiconductor layer and the side-wall gate portion; and
a second gate insulating film provided between an upper surface of the convex semiconductor layer and the gate electrode except for the side-wall gate portion, the second gate insulating film being thinner than the first gate insulating film.

34. The device according to claim 1, further comprising:
a first gate insulating film provided between the side surface of the semiconductor layer and the side-wall gate portion; and
a second gate insulating film provided between an upper surface of the convex semiconductor layer and the gate electrode except for the side-wall gate portion, and a top corner of the second gate insulating film having a round shape.

35. The device according to claim 1, wherein a distance between the source region and the drain region becomes longer toward a lower portion from an upper portion of the convex semiconductor layer.

36. The device according to claim 1, wherein an impurity concentration of the source region and the impurity concentration of the drain region become lower toward a lower portion from an upper portion of the convex semiconductor layer.

37. The device according to claim 1, wherein the side-wall gate portion is formed to a portion under the source region and the drain region along the side surface of the convex semiconductor layer.

38. The device according to claim 1, wherein a width of the convex semiconductor layer is smaller than 0.2 μm.

39. The device according to claim 1, wherein a width of the convex semiconductor layer is smaller than the depth of the source region and the depth of the drain region.

40. The device according to claim 1, wherein at least one of the source region and the drain region includes at least two kinds of diffusion layers, a high concentration diffusion layer having a dense impurity concentration and a low concentration diffusion layer having an impurity concentration lower than the high concentration diffusion layer.

41. The device according to claim 1, wherein the convex semiconductor layer is electrically connected to the substrate.

42. The device according to claim 1, wherein the substrate is conductive.

43. The device according to claim 1, further comprising:
a gate insulating film provided between the side-wall gate portion and the side surface of the convex semiconductor layer,
wherein the gate insulating film is made of an oxide including at least one of Ta, Sr, Al, Si, Zr, Hf, La and Ti.
